(19) United States
(12) Patent Application Publication
(10) Pub. No.: US 2010/0127988 A1
(43) Pub. Date: May 27, 2010

(54) KEY INPUT DEVICE AND CHARACTER INPUT METHOD USING CENTER KEY

(76) Inventors: Young-Soo Park, Kangwondo (KR); Ayako Yoshida, Kangwondo (KR)

Correspondence Address: LRK Patent Law Firm, 1952 Gallows Rd, Suite 200, Vienna, VA, 22182, US

(21) Appl. No.: 12/374,658

(22) PCT Filed: Jul. 20, 2007
(86) PCT No.: PCT/KR2007/003515

§ 371 Date: Dec. 11, 2009

(30) Foreign Application Priority Data
Jul. 20, 2006 (KR) 10-2006-0067758
Apr. 10, 2007 (KR) 10-2007-0034874

(51) Int. Cl. G06F 3/02; H03M 11/00

(52) U.S. Cl. 345/168; 341/23; 341/28

(57) ABSTRACT

The present invention relates to a character input device and method using a plurality of center keys and a plurality of space keys. The present invention provides a character input device and method having a center key located at its central part and a plurality of peripheral keys located at a peripheral part of the center key, comprising a basic value of a basic key generated by pressing the peripheral key one time, a double-value of the basic key generated by pressing the peripheral key two times, a basic value of a center key generated by pressing the center key one time after pressing the peripheral key, and a double-value of the center key generated by pressing the center key two times after pressing the peripheral key.

### TECHNICAL FIELD

The present invention relates to a character input device and method having a plurality of center keys or a plurality of space keys in which characters can be inputted more rapidly with fewer keys.

### BACKGROUND ART

Generally, the small keypads typically used for portable electronic devices, e.g., cellular phones, miniature computer devices and so on, make it difficult to input characters, numbers, or signs with high speed in that the respective keys have several input values, and that the inputting operation of characters are performed by pressing the keys two or three times or for a long time while toggling between letter keys and number keys in order to complete one character syllable or word.

As technology improves, portable electronic devices such as cellular phones, PNPs(Plug and Play) and PMPs(Portable Multimedia Player) become smaller in size. Thus, the keypads of such devices become miniaturized so that the keypads become very difficult to manage. For this reason, the character input speed becomes very slow.

Korean publication No. 10-2007-0012265 as the related prior art discloses the character input device and the method thereof, wherein the device comprises direction keys having right, left, up, down, and center keys; a code table for storing letter codes of cardinal constants and vowels assigned to the corresponding direction keys so that the letter codes can be selected by inputting the relevant direction keys two times; and control means in which, when a direction key is inputted two times, the corresponding letter key is first selected from the code table, and then, in case that the selected letter code is a cardinal consonant, and subsequently when the dual consonant manipulation is inputted from the direction keys, the selected letter code may be converted into the dual consonant code, in case that the selected letter code is a cardinal vowel, and subsequently when the same cardinal vowel manipulation is inputted from the direction keys, the selected letter code may be converted into the dual vowel code, and in case that the selected letter code is a cardinal vowel or a dual vowel, and subsequently when another vowel manipulation is inputted from the direction keys, the selected letter code may be converted into a diphthong code compounded of them. According to the above-mentioned character input device, the character, for example, “□” can be made up by pressing the up key two times to input “□” and pressing the up key and the center key to input “□”. That is to say, the input operation of characters can be performed only by right, left, up, down, and center keys, and therefore it is cumbersome and needs a long time to input the characters.

As a result, a character input device and method are desirable, in which the keys can be fewer in number and thus can be larger in size so that characters can be inputted with high speed.

### DISCLOSURE OF INVENTION

### Technical Problem

It is an object of the present invention, to provide a character input device and method having a plurality of center keys and a plurality of space keys that are easy to control.

It is another object of the present invention, to provide a character input device and method having a center key which comprises a basic value, a double value, and a triple value of a basic key and a basic value, a double value and a triple value of a center key.

It is another object of the present invention, to provide a character input device and method having two center keys or more which comprises a basic value, a double value, a successive value, a successive-double value, a successive-triple value, a triple value, a double-successive value, a double-successive-double value of a center key, and a basic value, a double value, a successive value, a successive-double value, a successive-triple value, a triple value, a double-successive value, a double-successive-double value of a distant center key.

It is another object of the present invention, to provide a character input device and method having four center keys or more which comprise a value 1 of the center key, a value 2 of the center key, a value 3 of the center key, a value 4 of the center key, a value 11 of the center key, a value 12 of the center key, a value 123 of the center key, a value 1234 of the center key, a value 13 of the center key, a value 133 of the center key, a value 22 of the center key, a value 24 of the center key, a value 244 of the center key, and a value 44 of the center key.

It is another object of the present invention, to provide a character input device and method having five center keys or more which comprise a value 1 of the center key, a value 2 of the center key, a value 3 of the center key, a value 4 of the center key, and a value 5 of the center key, a value 11 of the center key, a value 12 of the center key, a value 123 of the center key, a value 1234 of the center key, a value 12345 of the center key, a value 21 of the center key, a value 22 of the center key, a value 23 of the center key, a value 211 of the center key, a value 32 of the center key, a value 33 of the center key, a value 44 of the center key, and a value 45 of the center key, a value 445 of the center key, a value 455 of the center key, a value 4455 of the center key, and a value 54 of the center key.

It is another object of the present invention, to provide a character input device and method having a space key, wherein exciting a key arranged around the space key and the space key generates the same result as exciting the excited key and a key arranged symmetrically with the excited key with respect to the space key.

It is another object of the present invention, to provide a character input device and method having one center key or more and one space key or more in which characters can be inputted with higher speed while using smaller keys in number.

### Technical Solution

To achieve the above-mentioned object, the invention provides a character-input method, which is performed by a character input device having a center key arranged at a central part and a plurality of peripheral keys arranged at a peripheral part of the center key, which comprises a basic value of a basic key generated by pressing the peripheral key one time, a double value of the basic key generated by pressing the peripheral key two times, a triple value of the basic key generated by pressing the peripheral key three times, a basic value of a center key generated by pressing the center key one time after pressing the peripheral key, a double value of the center key generated by pressing the center key two times after pressing the peripheral key, and a triple value of the center key generated by pressing the center key three times after pressing the peripheral key.

The character input device further comprises a distant center key arranged around the center key so that both a distant center key and the center key are surrounded by the peripheral keys.

The character-input method further comprises a successive value of the center key generated by pressing the peripheral key, the center key and the distant center key in order, a successive-double value of the center key generated by pressing the distant center key two times after pressing the peripheral key and the center key in order, a successive-triple value of the center key generated by pressing the distant center key three times after pressing the peripheral key and the center key in order, a double-successive value of the center key generated by pressing the center key two times and the distant center key one time in order after pressing the peripheral key, and a double-successive-double value of the center key generated by pressing the center key two times and the distant center key two times in order after pressing the peripheral key.

Furthermore, the character-input method further comprises a basic value of a distant center key generated by pressing the distant center key one time after pressing the peripheral key, a double value of the distant center key generated by pressing the distant center key two times after pressing the peripheral key, a successive value of the distant center key generated by pressing the peripheral key, the distant center key and the center key in order, a successive-double value of the distant center key generated by pressing the center key two times after pressing the peripheral key and the distant center key in order, a successive-triple value of the distant center key generated by pressing the center key three times after pressing the peripheral key and the distant center key in order, a triple value of the distant center key generated by pressing the distant center key three times after pressing the peripheral key, a double-successive value of the distant center key generated by pressing the peripheral key, the distant center key two times, and the center key one time in order, and a double-successive-double value of the distant center key generated by pressing the peripheral key, the distant center key two times, and the center key two times in order.

The above-mentioned center key can comprise at least a 1st center key, a 2nd center key, a 3rd center key, and a 4th center key. In this case, the character-input method comprises a value 1 of the center key generated by pressing the peripheral key and the first center key in order, a value 2 of the center key generated by pressing the peripheral key and the 2nd center key in order, a value 3 of the center key generated by pressing the peripheral key and the 3rd center key in order, and a value 4 of the center key generated by pressing the peripheral key and the 4th center key in order.

The above-mentioned character-input method further comprises a value 11 of the center key generated by pressing the peripheral key and the 1st center key two times in order, a value 12 of the center key generated by pressing the peripheral key, the 1st center key and the 2nd center key in order, a value 123 of the center key generated by pressing the peripheral key, the 1st center key, the 2nd center key and the 3rd center key in order, a value 1234 of the center key generated by pressing the peripheral key, the 1st center key, the 2nd center key, the 3rd center key and the 4th center key in order, a value 13 of the center key generated by pressing the peripheral key, the 1st center key and the 3rd center key in order, a value 133 of the center key generated by pressing the peripheral key, the 1st center key and the 3rd center key two times in order, a value 22 of the center key generated by pressing the peripheral key and the 2nd center key two times in order, a value 24 of the center key generated by pressing the peripheral key, the 2nd center key and the 4th center key in order, a value 244 of the center key generated by pressing the peripheral key, the 2nd center key and the 4th center key two times in order, and a value 44 of the center key generated by pressing the peripheral key and the 4th center key two times in order.

Moreover, the above-mentioned center key can further comprise a 5th center key. In this case, the above-mentioned character-input method further comprises a value 5 of the center key generated by pressing the peripheral key and the 5th center key in order, a value 12345 of the center key generated by pressing the peripheral key, the 1st center key, the 2nd center key, the 3rd center key, the 4th center key and the 5th center key in order, a value 23 of the center key generated by pressing the peripheral key, the 2nd center key and the 3rd center key in order, a value 32 of the center key generated by pressing the peripheral key, the 3rd center key and the 2nd center key in order, a value 33 of the center key generated by pressing the peripheral key and the 3rd center key two times in order, a value 45 of the center key generated by pressing the peripheral key, the 4th center key and the 5th center key in order, a value 445 of the center key generated by pressing the peripheral key, the 4th center key two times and the 5th center key one time in order, a value 455 of the center key generated by pressing the peripheral key, the 4th center key, and the 5th center key two times in order, a value 4455 of the center key generated by pressing the peripheral key, the 4th center key two times, and the 5th center key two times in order, and a value 54 of the center key generated by pressing the peripheral key, the 5th center key and the 4th center key in order.

The device further comprises a space key located at a central part of four keys which consist of two upper keys and two lower keys and the space key adjoins all of the four keys, and wherein a value generated by exciting the space key after exciting one of two keys arranged symmetrically to each other with respect to the space key is equivalent to a value generated by exciting the excited key and its symmetrical key in order.

### ADVANTAGEOUS EFFECTS

The present invention provides a character input device and method having a plurality of center keys and a plurality of space keys easy to control, so that characters can be inputted at a high speed while using a fewer keys.

The present invention provides character input device and input methods thereof having a center key, in which, when the device is applied to portable electronic devices, for example a cellular phone, PNP(Plug and Play) and PMP(Portable Multimedia Player), characters can be generated with less finger's movements and therefore with the higher speed. Moreover, using a fewer keys causes the keys become larger in a relative size and thus become easy to control, which results in miniaturization of portable electronic devices.

To achieve the advantage, the present invention provides character-input device and method having a center key which comprises a basic value of a basic key, a double value of the basic key, a triple value of the basic key, a basic value of a center key, a double value of the center key, and a triple value of the center key.

Furthermore, the present invention provides character-input device and method having two or more center keys which comprise a basic value of a center key, a double value of the center key, a successive value of a center key, a successive-double value of the center key, a successive-triple value of the center key, a triple value of the center key, a double-successive value of the center key, a double-successive-double value of the center key, a basic value of a distant center key, a double value of the distant center key, a successive value of a distant center key, a successive-double value of the distant center key, a successive-triple value of the distant center key, a triple value of the distant center key, a double-successive value of the distant center key, and a double-successive-double value of the distant center key.

Furthermore, the present invention provides character input device and method having four or more center keys which comprise a value 1 of the center key, a value 2 of the center key, a value 3 of the center key, a value 4 of the center key, a value 11 of the center key, a value 12 of the center key, a value 123 of the center key, a value 1234 of the center key, a value 13 of the center key, a value 133 of the center key, a value 22 of the center key, a value 24 of the center key, a value 244 of the center key, and a value 44 of the center key.

Furthermore, the present invention provides character input device and method having five or more center keys which comprise a value 1 of the center key, a value 2 of the center key, a value 3 of the center key, a value 4 of the center key, a value 5 of the center key, a value 11 of the center key, a value 12 of the center key, a value 123 of the center key, a value 1234 of the center key, a value 12345 of the center key, a value 21 of the center key, a value 22 of the center key, a value 23 of the center key, a value 211 of the center key, a value 32 of the center key, a value 33 of the center key, a value 44 of the center key, a value 45 of the center key, a value 445 of the center key, a value 455 of the center key, a value 4455 of the center key, and a value 54 of the center key.

Moreover, the present invention provides character input device and method having a space key wherein exciting a key arranged around the space key and the space key generates the same result as exciting the excited key and the other key arranged symmetrically with the excited key with respect to the space key.

### BRIEF DESCRIPTION OF THE DRAWINGS

FIG. 1 is a view for illustrating a character input device of the 1st central type according to an embodiment of the present invention;

FIG. 2 is a view for illustrating a character input device of the 1st central type with ten peripheral keys according to an embodiment of the present invention;

FIG. 3 is a view for illustrating a character input device of the 2nd central type according to an embodiment of the present invention;

FIG. 4 is a view for illustrating a character input device of the 4th central type according to an embodiment of the present invention;

FIG. 5 is a view for illustrating a character input device of the 5th central type according to an embodiment of the present invention;

FIG. 6 is a view for illustrating a character input device of the 2nd central type with space keys according to an embodiment of the present invention;

FIG. 7 is a table for indicating methods for inputting values of the basic keys and the center keys in the character input device of the 1st central type as shown in FIG. 1;

FIG. 8 is a table for indicating methods for inputting values of the basic keys and the center keys in the character input device of the 1st central type with ten peripheral keys of FIG. 2;

FIG. 9 is a table for indicating methods for inputting values of the basic keys and the center keys in the character input device of the 2nd central type of FIG. 3;

FIG. 10 is a table for indicating methods for inputting values of the distant center keys in the character input device of the 2nd central type of FIG. 3;

FIG. 11 is a table for partially indicating methods for inputting key-values in the character input device of the 4th central type of FIG. 4;

FIG. 12 is a table for partially indicating methods for inputting key-values in the character input device of the 5th central type of FIG. 5;

FIG. 13 is a table for indicating methods for inputting key-values in the character input device of the 2nd central type with space keys of FIG. 6;

FIG. 14 is a view for illustrating a character input device of the 1st central type for moving a cursor according to another embodiment of the present invention;

FIG. 15 is a view for illustrating a character input device of the 1st central type for a record player according to another embodiment of the present invention;

FIG. 16 is a view for illustrating a character input device of the 1st central type for a numerical calculation according to another embodiment of the present invention;

FIG. 17 is a view for illustrating a character input device of the 1st central type for numerical calculation/clock according to another embodiment of the present invention;

FIG. 18 is a view for illustrating a character input device of the 2nd central type for a numerical calculation according to another embodiment of the present invention;

FIG. 19 is a view for illustrating a character input device of the 2nd central type for Korean according to another embodiment of the present invention;

FIG. 20 is a view for illustrating a character input device of the 2nd central type for Roman according to another embodiment of the present invention;

FIG. 21 is a view for illustrating a character input device of the integrated type for Korean and Roman characters according to another embodiment of the present invention;

FIG. 22 is a view for illustrating a character input device of the 2nd central type for numerical calculation/clock according to another embodiment of the present invention;

FIG. 23 is a view for illustrating a character input device of the separated type for Korean according to another embodiment of the present invention;

FIG. 24 is a view for illustrating a character input device of the separated type for Roman according to another embodiment of the present invention;

FIG. 25 is a view for illustrating a character input device for the Japanese according to another embodiment of the present invention;

FIG. 26 is a view for illustrating a character input device for Roman and Japanese characters according to another embodiment of the present invention;

FIG. 27 is a view for illustrating a character input device for Chinese using Chinese phonetic symbols according to another embodiment of the present invention;

FIG. 28 is a view for illustrating a character input device for Roman and Chinese characters according to another embodiment of the present invention;

FIG. 29 is a view for illustrating a character input device for Roman and German characters according to another embodiment of the present invention;

FIG. 30 is a view for illustrating a character input device for Roman and French characters according to another embodiment of the present invention;

FIG. 31 is a view for illustrating a character input device for Roman and Vietnamese characters according to another embodiment of the present invention;

FIG. 32 is a view for illustrating a character input device for Russian according to another embodiment of the present invention;

FIG. 33 is a view for illustrating phonetic symbols corresponding to characters of FIG. 32;

FIG. 34 is a view for illustrating a character input device for Hindi according to another embodiment of the present invention;

FIG. 35 is a view for illustrating a character input device for Roman and Hindi characters romanizing Hindi in the device of FIG. 34 according to another embodiment of the present invention;

FIG. 36 is a view for illustrating a character input device for Arab according to another embodiment of the present invention;

FIG. 37 is a view for illustrating a character input device for adjustment according to another embodiment of the present invention;

FIG. 38 is a view for illustrating a character input device for controlling a camera according to another embodiment of the present invention;

FIG. 39 is a view for illustrating a character input device for inherent functions according to another embodiment of the present invention;

FIG. 40 is a view for illustrating a character input device for Roman character central-4 space type according to another embodiment of the present invention; and

FIG. 41 is a view for illustrating a character input device for Korean-Roman central-5-space type according to another embodiment of the present invention.

### BEST MODE FOR CARRYING OUT THE INVENTION

The above-mentioned advantages and characteristics of the present invention, and the method of obtaining them, will become more apparent by reference to the following description of the invention taken in conjunction with the accompanying drawings. The present invention is not limited by the embodiments of the invention described below, but can be realized in various forms. The present invention is fully disclosed by the embodiments so that others skilled in the art can completely understand the spirit and scope of the present invention. The scope of the present invention is defined only by the claims. Corresponding reference symbols indicates corresponding parts throughout the disclosure.

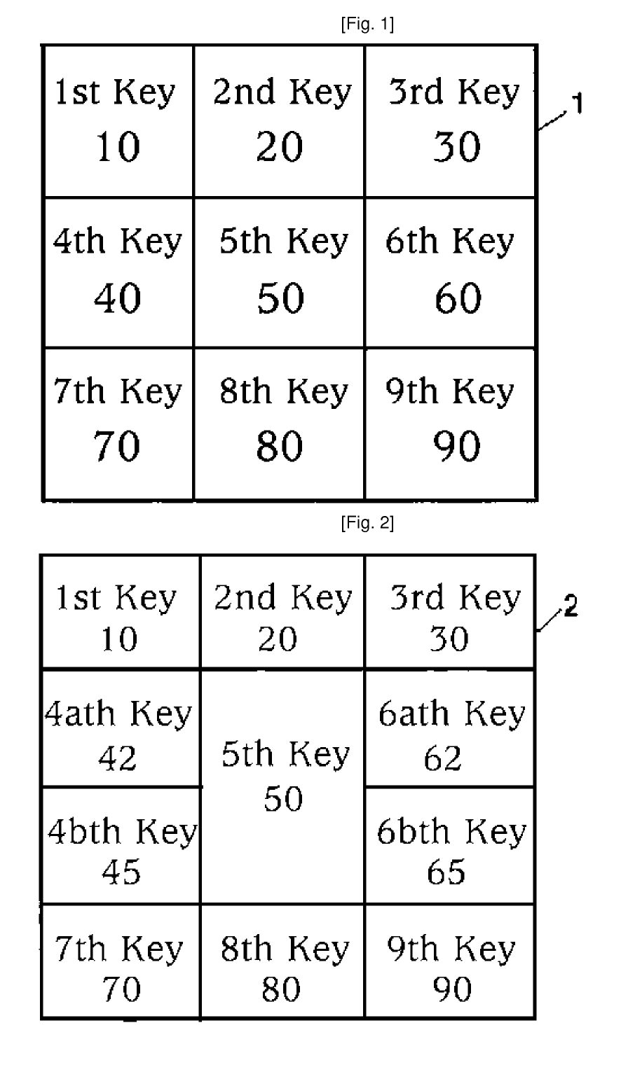

FIG. 1 illustrates a character input device of the 1st central type according to an embodiment of the present invention. The character input device(1) of the 1st central type has a 3×3 arrangement, and consists of a 1st key(10), a 2nd key(20), a 3rd key(30), a 4th key(40), a 5th key(50), a 6th key(60), a 7th key(70), a 8th key(80), and a 9th key(90).

The 1st key(10) is located on 1st row and 1st column of the 3×3 arrangement of the character input device(1) of 1st central type.

The 2nd key(20) is located on 1st row and 2nd column of the 3×3 arrangement of the character input device(1) of 1st central type.

The 3rd key(30) is located on 1st row and 3rd column of the 3×3 arrangement of the character input device(1) of 1st central type.

The 4th key(40) is located on 2nd row and 1st column of the 3×3 arrangement of the character input device(1) of 1st central type.

The 5th key(50) is located on 2nd row and 2nd column of the 3×3 arrangement of the character input device(1) of 1st central type.

The 6th key(60) is located on 2nd row and 3rd column of the 3×3 arrangement of the character input device(1) of 1st central type.

The 7th key(70) is located on 3rd row and 1st column of the 3×3 arrangement of the character input device(1) of 1st central type.

The 8th key(80) is located on 3rd row and 2nd column of the 3×3 arrangement of the character input device(1) of 1st central type.

The 9th key(90) is located on 3rd row and 3rd column of the 3×3 arrangement of the character input device(1) of 1st central type.

FIG. 2 illustrates a character input device of the 1st central type with ten peripheral keys according to an embodiment of the present invention. The character input device(2) of the 1st central type with ten peripheral keys has keys corresponding to the 4th and 6th keys of FIG. 1 formed by dividing the 4th and 6th keys to two upper and lower keys, respectively, and consists of a 1st key(10), a 2nd key(20), a 3rd key(30), a 4ath key(42), a 4bth key(45), a 5th key(50), a 6ath key(62), a 6bth key(65), a 7th key(70), a 8th key(80), and a 9th key(90). The arrangement of the 1st key(10), the 2nd key(20), the 3rd key(30), the 5th key(50), the 7th key(70), the 8th key(80), and the 9th key(90) is similar to that of FIG. 1.

The 4ath key(42) is located on the upper portion of the 4th key(40) and thus located on the upper part of the 4bth key(45).

The 4bth key(45) is located below the 4ath key(42).

The 6ath key(62) is located on the upper portion of the 6th key(60) and thus located on the upper part of the 6bth key(65).

The 6bth key(65) is located below the 6ath key(62).

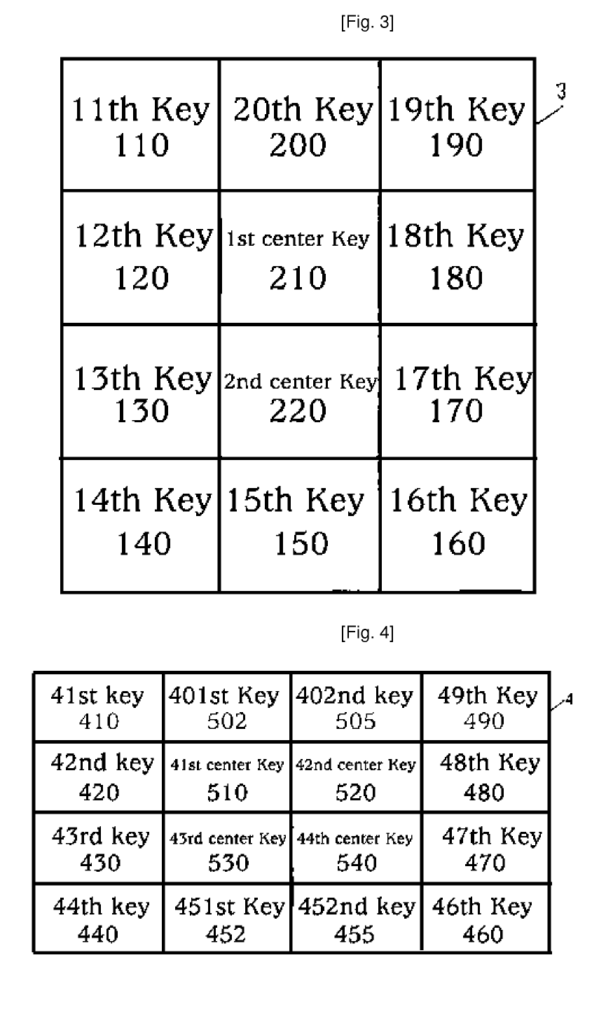

FIG. 3 illustrates a character input device of the 2nd central type according to an embodiment of the present invention. The character input device(3) of the 2nd central type has a 3×4 arrangement, and consists of an 11th key(110), a 12th key(120), a 13th key(130), a 14th key(140), a 15th key(150), a 16th key(160), a 17th key(170), an 18th key(180), a 19th key(190), a 20th key(200), a 1st center key(210), and a 2nd center key(220).

The 11th key(110) is located on 1st row and 1st column of the 3×4 arrangement of the character input device(3) of 2nd central type.

The 12th key(120) is located on 2nd row and 1st column of the 3×4 arrangement of the character input device(3) of 2nd central type.

The 13th key(130) is located on 3rd row and 1st column of the 3×4 arrangement of the character input device(3) of 2nd central type.

The 14th key(140) is located on 4th row and 1st column of the 3×4 arrangement of the character input device(3) of 2nd central type.

The 15th key(150) is located on 4th row and 2nd column of the 3×4 arrangement of the character input device(3) of 2nd central type.

The 16th key(160) is located on 4th row and 3rd column of the 3×4 arrangement of the character input device(3) of 2nd central type.

The 17th key(170) is located on 3rd row and 3rd column of the 3×4 arrangement of the character input device(3) of 2nd central type.

The 18th key(180) is located on 2nd row and 3rd column of the 3×4 arrangement of the character input device(3) of 2nd central type.

The 19th key(190) is located on 1st row and 3rd column of the 3×4 arrangement of the character input device(3) of 2nd central type.

The 20th key(200) is located on 1st row and 2nd column of the 3×4 arrangement of the character input device(3) of 2nd central type.

The 1st center key(210) is located on 2nd row and 2nd column of the 3×4 arrangement of the character input device(3) of 2nd central type.

The 2nd center key(220) is located on 3rd row and 2nd column of the 3×4 arrangement of the character input device(3) of 2nd central type.

FIG. 4 illustrates a character input device of the 4th central type according to an embodiment of the present invention. The character input device(4) of the 4th central type has a 4×4 arrangement, and consists of a 41st key(410), a 42nd key(420), a 43rd key(430), a 44th key(440), a 451st key(452), a 452nd key(455), a 46th key(460), a 47th key(470), a 48th key(480), a 49th key(490), a 401st key(502), a 402nd key(505), a 41st center key(510), a 42nd center key(520), a 43rd center key(530) and a 44th center key(540).

The 41st key(410) is located on 1st row and 1st column of the 4×4 arrangement of the character input device(4) of 4th central type.

The 42nd key(420) is located on 2nd row and 1st column of the 4×4 arrangement of the character input device(4) of 4th central type.

The 43rd key(430) is located on 3rd row and 1st column of the 4×4 arrangement of the character input device(4) of 4th central type.

The 44th key(440) is located on 4th row and 1st column of the 4×4 arrangement of the character input device(4) of 4th central type.

The 451st key(452) is located on 4th row and 2nd column of the 4×4 arrangement of the character input device(4) of 4th central type.

The 452nd key(455) is located on 4th row and 3rd column of the 4×4 arrangement of the character input device(4) of 4th central type.

The 46th key(460) is located on 4th row and 4th column of the 4×4 arrangement of the character input device(4) of 4th central type.

The 47th key(470) is located on 3rd row and 4th column of the 4×4 arrangement of the character input device(4) of 4th central type.

The 48th key(480) is located on 2nd row and 4th column of the 4×4 arrangement of the character input device(4) of 4th central type.

The 49th key(490) is located on 1st row and 4th column of the 4×4 arrangement of the character input device(4) of 4th central type.

The 401st key(502) is located on 1st row and 2nd column of the 4×4 arrangement of the character input device(4) of 4th central type.

The 402nd key(505) is located on 1st row and 3rd column of the 4×4 arrangement of the character input device(4) of 4th central type.

The 41st center key(510) is located on 2nd row and 2nd column of the 4×4 arrangement of the character input device(4) of 4th central type.

The 42nd center key(520) is located on 2nd row and 3rd column of the 4×4 arrangement of the character input device(4) of 4th central type.

The 43rd center key(530) is located on 3rd row and 2nd column of the 4×4 arrangement of the character input device(4) of 4th central type.

The 44th center key(540) is located on 3rd row and 3rd column of the 4×4 arrangement of the character input device(4) of 4th central type.

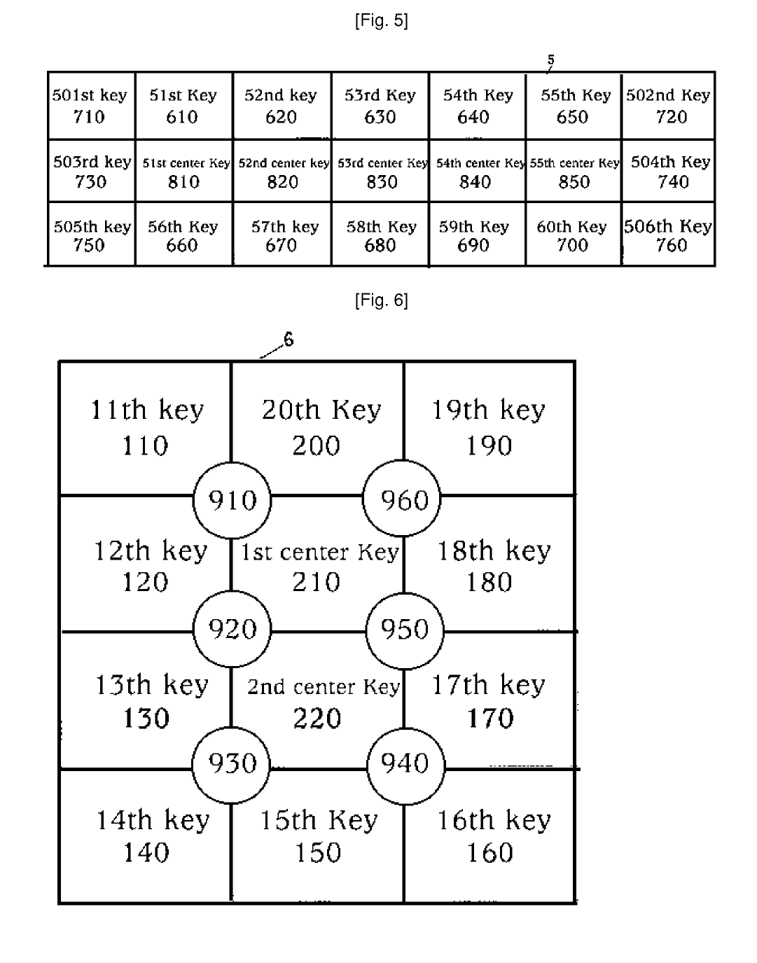

FIG. 5 illustrates a character input device of the 5th central type according to an embodiment of the present invention. The character input device(5) of the 5th central type has a 3×7 arrangement, and consists of a 51st key(610), a 52nd key(620), a 53rd key(630), a 54th key(640), a 55th key(650), a 56th key(660), a 57th key(670), a 58th key(680), a 59th key(690), a 60th key(700), a 501st key(710), a 502nd key(720), a 503rd key(730), a 504th key(740), a 505th key(750), a 506th key(760), a 51st center key(810), a 52nd center key(820), a 53rd center key(830), a 54th center key(840) and a 55th center key(850).

The 51st key(610) is located on 1st row and 2nd column of the 3×7 arrangement of the character input device(5) of 5th central type.

The 52nd key(620) is located on 1st row and 3rd column of the 3×7 arrangement of the character input device(5) of 5th central type.

The 53rd key(630) is located on 1st row and 4th column of the 3×7 arrangement of the character input device(5) of 5th central type.

The 54th key(640) is located on 1st row and 5th column of the 3×7 arrangement of the character input device(5) of 5th central type.

The 55th key(650) is located on 1st row and 6th column of the 3×7 arrangement of the character input device(5) of 5th central type.

The 56th key(660) is located on 3rd row and 2nd column of the 3×7 arrangement of the character input device(5) of 5th central type.

The 57th key(670) is located on 3rd row and 3rd column of the 3×7 arrangement of the character input device(5) of 5th central type.

The 58th key(680) is located on 3rd row and 4th column of the 3×7 arrangement of the character input device(5) of 5th central type.

The 59th key(690) is located on 3rd row and 5th column of the 3×7 arrangement of the character input device(5) of 5th central type.

The 60th key(700) is located on 3rd row and 6th column of the 3×7 arrangement of the character input device(5) of 5th central type.

The 501st key(710) is located on 1st row and 1st column of the 3×7 arrangement of the character input device(5) of 5th central type.

The 502nd key(720) is located on 1st row and 7th column of the 3×7 arrangement of the character input device(5) of 5th central type.

The 503rd key(730) is located on 2nd row and 1st column of the 3×7 arrangement of the character input device(5) of 5th central type.

The 504th key(740) is located on 2nd row and 7th column of the 3×7 arrangement of the character input device(5) of 5th central type.

The 505th key(750) is located on 3nd row and 1st column of the 3×7 arrangement of the character input device(5) of 5th central type.

The 506th key(760) is located on 3nd row and 7th column of the 3×7 arrangement of the character input device(5) of 5th central type.

The 51st center key(810) is located on 2nd row and 2nd column of the 3×7 arrangement of the character input device(5) of 5th central type.

The 52nd center key(820) is located on 2nd row and 3rd column of the 3×7 arrangement of the character input device(5) of 5th central type.

The 53rd center key(830) is located on 2nd row and 4th column of the 3×7 arrangement of the character input device(5) of 5th central type.

The 54th center key(840) is located on 2nd row and 5th column of the 3×7 arrangement of the character input device(5) of 5th central type.

The 55th center key(850) is located on 2nd row and 6th column of the 3×7 arrangement of the character input device(5) of 5th central type.

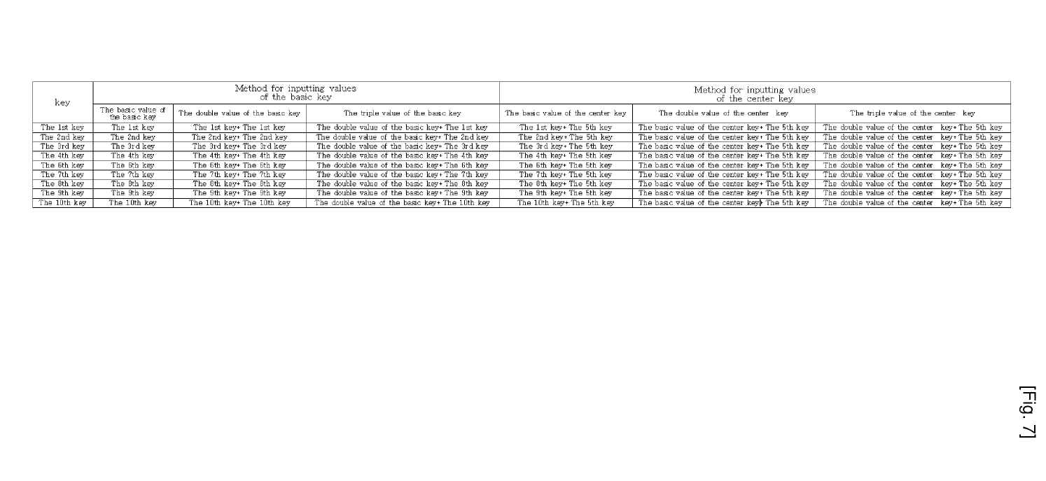

FIG. 6 illustrates a character input device(6) of the 2nd central type with space keys according to an embodiment of the present invention. The character input device of the 2nd central type having space keys has a construction that a 1st space key(910), a 2nd space key(920), a 3rd space key(930), a 4th space key(940), a 5th space key(950), and a 6th space key(960) are added to the 3×4 arrangement of the character input device(3) of the 2nd central type of FIG. 3.

The 1st space key(910) is located at a space surrounded by the 11th key(110), the 12th key(120), the 20th key(200) and the 1st center key(210).

The 2nd space key(920) is located at a space surrounded by the 12th key(120), the 13th key(130), the 1st center key(210) and the 2nd center key(220).

The 3rd space key(930) is located at a space surrounded by the 13th key(130), the 14th key(140), the 15th key(150) and the 2nd center key(220).

The 4th space key(940) is located at a space surrounded by the 15th key(150), the 16th key(160), the 17th key(170) and the 2nd center key(220).

The 5th space key(950) is located at a space surrounded by the 17th key(170), the 18th key(180), the 1st center key(210) and the 2nd center key(220).

The 6th space key(960) is located at a space surrounded by the 18th key(180), the 19th key(190), the 20th key(200) and the 1st center key(210).

The respective space keys are arranged to have plenty of space between them so that they do not contact each other.

FIG. 7 is a table for indicating methods for inputting values of the basic keys and the center key in the character input device(1) of the 1st central type as shown in FIG. 1, wherein the input values of the basic keys have a basic value, a double value and a triple value of the basic key, and the input values of the center key has a basic value, a double value and a triple value of the center key.

The basic value is a value generated by pressing the corresponding key one time.

The double value of the basic key is a value generated by pressing the same key once more after the basic value is generated. That is, the value can be generated by pressing the corresponding key two times.

The triple value of the basic key is a value generated by pressing the same key once more after the double value is generated. That is, the value can be generated by pressing the corresponding key three times.

A center key of the 1st key(10), the 2nd key(20), the 3rd key(30), the 4th key(40), the 6th key(60), the 7th key(70), the 8th key(80), and the 9th key(90) is the 5th key(50), and the respective basic values of the center key are generated by pressing the 5th key(50) after pressing the respective key. That is, the basic values of the center key of the respective keys are generated by pressing the center key after pressing the respective keys.

Double values of the center key of the respective keys are generated by pressing the 5th key(50) after respectively generating the basic values of the center key of the 1st key(10), the 2nd key(20), the 3rd key(30), the 4th key(40), the 6th key(60), the 7th key(70), the 8th key(80), and the 9th key(90). That is, the double values of the center key of the respective keys are generated by pressing the center key two times after pressing the respective keys.

Triple values of the center key of the respective keys are generated by pressing the 5th key(50) after respectively generating the double values of the center key of the 1st key(10), the 2nd key(20), the 3rd key(30), the 4th key(40), the 6th key(60), the 7th key(70), the 8th key(80), and the 9th key(90). That is, the triple values of the center key of the respective keys are generated by pressing the center key three times after pressing the respective keys.

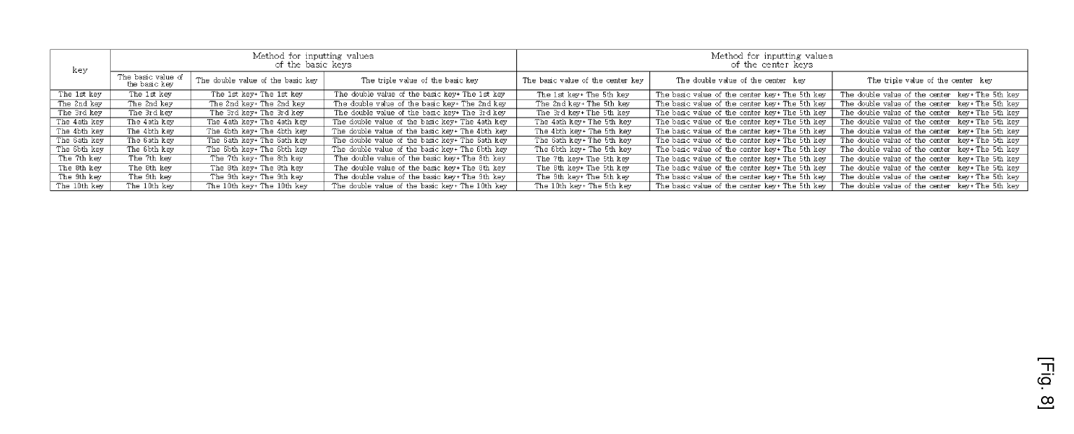

FIG. 8 is a table for indicating methods for inputting values of the basic keys and the center key in the character input device(2) of the 1st central type with ten peripheral keys of FIG. 2, wherein the input values of the basic keys have basic values, double values and triple values of the basic keys, and the input values of the center keys have basic values, double values and triple values of the center keys.

The method of inputting the input values of the basic keys is similar to that of the character input device(1) of the 1st central type of FIG. 7.

The center key of the 1st key(10), the 2nd key(20), the 3rd key(30), the 4ath key(42), the 4bth key(45), the 6ath key(62), the 6bth key(65), the 7th key(70), the 8th key(80), and the 9th key(90) is the 5th key(50), and the basic values of the center key of the respective keys are generated by pressing the 5th key(50) after pressing the respective keys. The method of inputting the input values of the center key of the respective keys is also similar to that in the character input device(1) of the 1st central type of FIG. 7.

For example, the basic values of the center key of the 4ath key(42) in FIG. 2 are generated by pressing the 5th key(50) of the center key after pressing the 4ath key(42). The double value of the center key of the 4ath key(42) is generated by pressing the 5th key(50) again after generating the basic values of the center key of the 4ath key(42), and the triple value of the center key of the 4ath key(42) is generated by pressing the 5th key(50) again after generating the double values of the center key of the 4ath key(42).

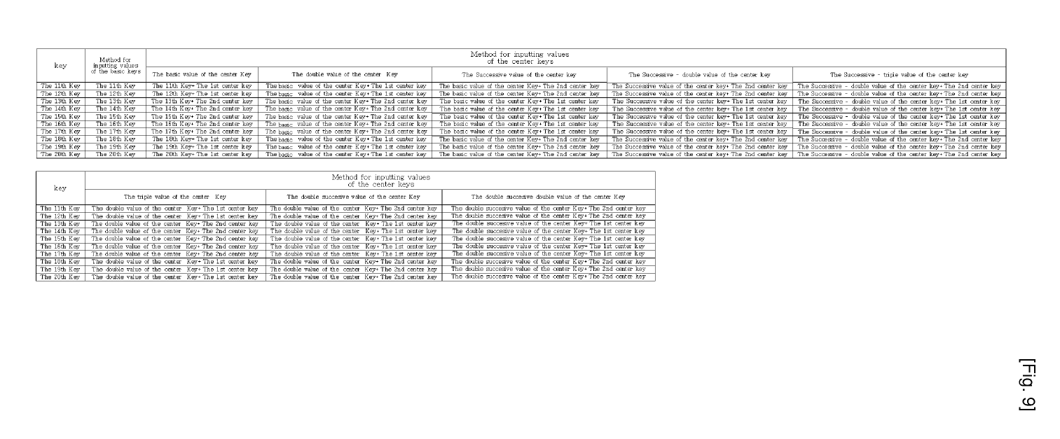

FIG. 9 is a table for indicating methods for inputting values of the basic keys and the center keys in the character input device of the 2nd central type of FIG. 3, wherein the input values of the basic keys have basic values, double values and triple values of the basic keys, and the input values of the center keys have basic value, double value, successive values, successive double values, successive triple values, triple values, double successive values, and double successive double values of the center keys.

The basic value is a value generated by pressing the corresponding key one time.

The double value of the basic key is a value generated by pressing the basic key once more after the basic value is generated. That is, the value can be generated by pressing the corresponding key two times.

The triple value of the basic key is a value generated by pressing the basic key once more after the double value is generated. That is, the value can be generated by pressing the corresponding key three times.

The center key of the 11th key(110), the 12th key(120), the 18th key(180), the 19th key(190) and the 20th key(200) is the 1st center key(210), and the basic values of the center key of the respective keys are generated by pressing the 1st center key(210) after pressing the respective keys.

The center key of the 13th key(130), the 14th key(140), the 15th key(150), the 16th key(160) and the 17th key(170) is the 2nd center key(220), and the basic values of the center key of the respective keys are generated by pressing the 2nd center key(220) after pressing the respective keys.

The double values of the center key of the 11th key(110), the 12th key(120), the 18th key(180), the 19th key(190) and the 20th key(200) are generated by pressing the 1st center key(210) once more, that has been pressed last, after generating the basic value of the center key of the respective keys. That is, the values are generated by pressing the center key, i.e., the 1st center key(210) two times after pressing the respective keys.

The double values of the center key of the 13th key(130), the 14th key(140), the 15th key(150), the 16th key(160) and the 17th key(170) are generated by pressing the 2nd center key(220) once more, that has been pressed last, after generating the basic value of the center key of the respective keys. That is, the values are generated by pressing the 2nd center key(220) two times after pressing the respective keys.

The successive values of the center key of the 11th key(110), the 12th key(120), the 18th key(180), the 19th key(190) and the 20th key(200) are generated by pressing the distant center key, i.e. the 2nd center key(220), after generating the basic value of the center key of the respective keys. That is, the values are generated by pressing the 1st center key(210) and the 2nd center key(220) in order after pressing the 11th key(110), the 12th key(120), the 18th key(180), the 19th key(190) and the 20th key(200), respectively.

The successive values of the center key of the 13th key(130), the 14th key(140), the 15th key(150), the 16th key(160) and the 17th key(170) are generated by pressing the distant center key, i.e. the 1st center key(210), after generating the basic value of the center key of the respective keys. That is, the values are generated by pressing the 2nd center key(220) and the 1st center key(210) in order after pressing the 13th key(130), the 14th key(140), the 15th key(150), the 16th key(160) and the 17th key(170), respectively.

The successive-double values of the center key of the 11th key(110), the 12th key(120), the 18th key(180), the 19th key(190) and the 20th key(200) are generated by pressing the distant center key, i.e. the 2nd center key(220) once more after generating the successive value of the center key of the respective keys. That is, the values are generated by pressing the 1st center key(210) one time and the 2nd center key(220) two times in order after pressing the 11th key(110), the 12th key(120), the 18th key(180), the 19th key(190) and the 20th key(200), respectively.

The successive-double values of the center key of the 13th key(130), the 14th key(140), the 15th key(150), the 16th key(160) and the 17th key(170) are generated by pressing the distant center key, i.e. the 1st center key(210) once more after generating the successive value of the center key of the respective keys. That is, the values are generated by pressing the 2nd center key(220) one time and the 1st center key(210) two times in order after pressing the 13th key(130), the 14th key(140), the 15th key(150), the 16th key(160) and the 17th key(170), respectively.

The successive-triple values of the center key of the 11th key(110), the 12th key(120), the 18th key(180), the 19th key(190) and the 20th key(200) are generated by pressing the distant center key, i.e. the 2nd center key(220) once more after generating the successive-double value of the center key of the respective keys. That is, the values are generated by pressing the 1st center key(210) one time and the 2nd center key(220) three times in order after pressing the 11th key(110), the 12th key(120), the 18th key(180), the 19th key(190) and the 20th key(200), respectively.

The successive-triple values of the center key of the 13th key(130), the 14th key(140), the 15th key(150), the 16th key(160) and the 17th key(170) are generated by pressing the distant center key, i.e. the 1st center key(210) once more after generating the successive-double value of the center key of the respective keys. That is, the values are generated by pressing the 2nd center key(220) one time and the 1st center key(210) three times in order after pressing the 13th key(130), the 14th key(140), the 15th key(150), the 16th key(160) and the 17th key(170), respectively.

The triple values of the center key of the 11th key(110), the 12th key(120), the 18th key(180), the 19th key(190) and the 20th key(200) are generated by pressing the 1st center key(210) once more, that has been pressed last, after generating the double value of the center key of the respective keys. That is, the values are generated by pressing the 1st center key(210) three times after pressing the 11th key(110), the 12th key(120), the 18th key(180), the 19th key(190) and the 20th key(200), respectively.

The triple values of the center key of the 13th key(130), the 14th key(140), the 15th key(150), the 16th key(160) and the 17th key(170) are generated by pressing the 2nd center key(220) once more, that has been pressed last, after generating the double value of the center key of the respective keys. That is, the values are generated by pressing the 2nd center key(220) three times after pressing the 13th key(130), the 14th key(140), the 15th key(150), the 16th key(160) and the 17th key(170), respectively.

The double-successive values of the center key of the 11th key(110), the 12th key(120), the 18th key(180), the 19th key(190) and the 20th key(200) are generated by pressing the distant center key, i.e. the 2nd center key(220) once more after generating the double value of the center key of the respective keys. That is, the values are generated by pressing the 1st center key(210) two times and the 2nd center key(220) one time in order after pressing the 11th key(110), the 12th key(120), the 18th key(180), the 19th key(190) and the 20th key(200), respectively.

The double-successive values of the center key of the 13th key(130), the 14th key(140), the 15th key(150), the 16th key(160) and the 17th key(170) are generated by pressing the distant center key, i.e. the 1st center key(210) once more after generating the double value of the center key of the respective keys. That is, the values are generated by pressing the 2nd center key(220) two times and the 1st center key(210) one time in order after pressing the 13th key(130), the 14th key(140), the 15th key(150), the 16th key(160) and the 17th key(170), respectively.

The double-successive-double values of the center key of the 11th key(110), the 12th key(120), the 18th key(180), the 19th key(190) and the 20th key(200) are generated by pressing the 2nd center key(220), which has been pressed last, after generating the double-successive value of the center key of the respective keys. That is, the values are generated by pressing the 1st center key(210) two times and the 2nd center key(220) two times in order after pressing the 11th key(110), the 12th key(120), the 18th key(180), the 19th key(190) and the 20th key(200), respectively.

The double-successive-double values of the center key of the 13th key(130), the 14th key(140), the 15th key(150), the 16th key(160) and the 17th key(170) are generated by pressing the 1st center key(210), which has been pressed last, after generating the double-successive value of the center key of the respective keys. That is, the values are generated by pressing the 2nd center key(220) two times and the 1st center key(210) two times in order after pressing the 13th key(130), the 14th key(140), the 15th key(150), the 16th key(160) and the 17th key(170), respectively.

FIG. 10 is a table for indicating methods for inputting values of the distant center keys in the character input device(3) of the 2nd central type of FIG. 3, wherein the input values of the distant center keys have basic values, double values, successive values, successive-double values, successive-triple values, triple values, double-successive values, and double-successive-double values.

The distant center key of the 11th key(110), the 12th key(120), the 18th key(180), the 19th key(190) and the 20th key(200) is the 2nd center key(220), and the basic values of the distant center key of the respective keys are generated by pressing the 2nd center key(220) after pressing the respective keys.

The distant center key of the 13th key(130), the 14th key(140), the 15th key(150), the 16th key(160) and the 17th key(170) is the 1st center key(210), and the basic values of the distant center key of the respective keys are generated by pressing the 1st center key(210) after pressing the respective keys.

The double values of the distant center key of the 11th key(110), the 12th key(120), the 18th key(180), the 19th key(190) and the 20th key(200) are generated by pressing the 2nd center key(220) once more, that has been pressed last, after generating the basic value of the distant center key of the respective keys. That is, the values are generated by pressing the distant center key, i.e. the 2nd center key(220) two times after pressing the respective keys.

The double values of the distant center key of the 13th key(130), the 14th key(140), the 15th key(150), the 16th key(160) and the 17th key(170) are generated by pressing the 1st center key(210) once more, that has been pressed last, after generating the basic value of the distant center key of the respective keys. That is, the values are generated by pressing the distant center key, i.e. the 1st center key(210) two times after pressing the respective keys.

The successive values of the distant center key of the 11th key(110), the 12th key(120), the 18th key(180), the 19th key(190) and the 20th key(200) are generated by pressing the center key, i.e. the 1st center key(210), after generating the basic value of the distant center key of the respective keys. That is, the values are generated by pressing the 2nd center key(220) and the 1st center key(210) in order after pressing the respective keys.

The successive values of the distant center key of the 13th key(130), the 14th key(140), the 15th key(150), the 16th key(160) and the 17th key(170) are generated by pressing the center key, i.e. the 2nd center key(220), after generating the basic value of the distant center key of the respective keys. That is, the values are generated by pressing the 1st center key(210) and the 2nd center key(220) in order after pressing the respective keys.

The successive-double values of the distant center key of the 11th key(110), the 12th key(120), the 18th key(180), the 19th key(190) and the 20th key(200) are generated by pressing the center key, i.e. the 1st center key(210) once more after generating the successive values of the distant center key of the respective keys. That is, the values are generated by pressing the 2nd center key(220) one time and the 1st center key(210) two times in order after pressing the respective keys.

The successive-double values of the distant center key of the 13th key(130), the 14th key(140), the 15th key(150), the 16th key(160) and the 17th key(170) are generated by pressing the center key, i.e., the 2nd center key(220) once more after generating the successive value of the distant center key of the respective keys. That is, the values are generated by pressing the 1st center key(210) one time and the 2nd center key(220) two times in order after pressing the respective keys.

The successive-triple values of the distant center key of the 11th key(110), the 12th key(120), the 18th key(180), the 19th key(190) and the 20th key(200) are generated by pressing the 1st center key(210), which has been pressed last, once more, after generating the successive-double value of the distant center key of the respective keys. That is, the values are generated by pressing the 2nd center key(220) one time and the 1st center key(210) three times in order after pressing the respective keys.

The successive-triple values of the distant center key of the 13th key(130), the 14th key(140), the 15th key(150), the 16th key(160) and the 17th key(170) are generated by pressing the 2nd center key(220), which has been pressed last, once more, after generating the successive-double value of the distant center key of the respective keys. That is, the values are generated by pressing the 1st center key(210) one time and the 2nd center key(220) three times in order after pressing the respective keys.

The triple values of the distant center key of the 11th key(110), the 12th key(120), the 18th key(180), the 19th key(190) and the 20th key(200) are generated by pressing the 2nd center key(220) once more, which has been pressed last, once more, after generating the double value of the distant center key of the respective keys. That is, the values are generated by pressing the 2nd center key(220) three times after pressing the respective keys.

The triple values of the distant center key of the 13th key(130), the 14th key(140), the 15th key(150), the 16th key(160) and the 17th key(170) are generated by pressing the 1st center key(210), which has been pressed last, once more, after generating the double value of the distant center key of the respective keys. That is, the values are generated by pressing the 1st center key(210) three times after pressing the respective keys.

The double-successive values of the distant center key of the 11th key(110), the 12th key(120), the 18th key(180), the 19th key(190) and the 20th key(200) are generated by pressing the 1st center key(210) one time, after generating the double value of the distant center key of the respective keys. That is, the values are generated by pressing the distant center key, i.e. the 2nd center key(220) two times and the center key, i.e. the 1st center key(210) one time in order after pressing the respective keys.

The double-successive values of the distant center key of the 13th key(130), the 14th key(140), the 15th key(150), the 16th key(160) and the 17th key(170) are generated by pressing the 2nd center key(220) one time, after generating the double value of the distant center key of the respective keys. That is, the values are generated by pressing the distant center key, i.e. the 1st center key(210) two times and the center key, i.e. the 2nd center key(220) one time in order after pressing the respective keys.

The double-successive-double values of the distant center key of the 11th key(110), the 12th key(120), the 18th key(180), the 19th key(190) and the 20th key(200) are generated by pressing the 1st center key(210) one time after generating the double-successive value of the distant center key of the respective keys. That is, the values are generated by pressing the distant center key, i.e. the 2nd center key(220) two times and the center key, i.e. the 1st center key(210) two times in order after pressing the respective keys.

The double-successive-double values of the distant center key of the 13th key(130), the 14th key(140), the 15th key(150), the 16th key(160) and the 17th key(170) are generated by pressing the 2nd center key(220) one time after generating the double-successive value of the distant center key of the respective keys. That is, the values are generated by pressing the distant center key, i.e. the 1st center key(210) two times and the center key, i.e. the 2nd center key(220) two times in order after pressing the respective keys.

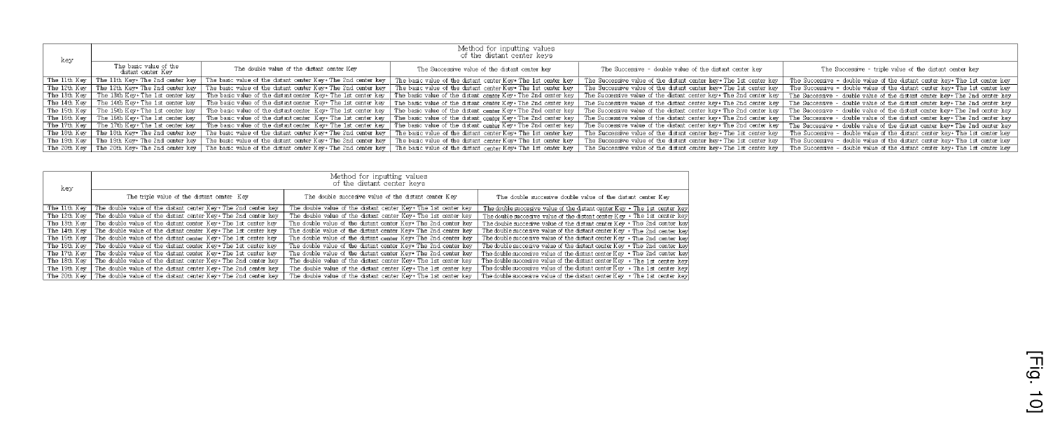

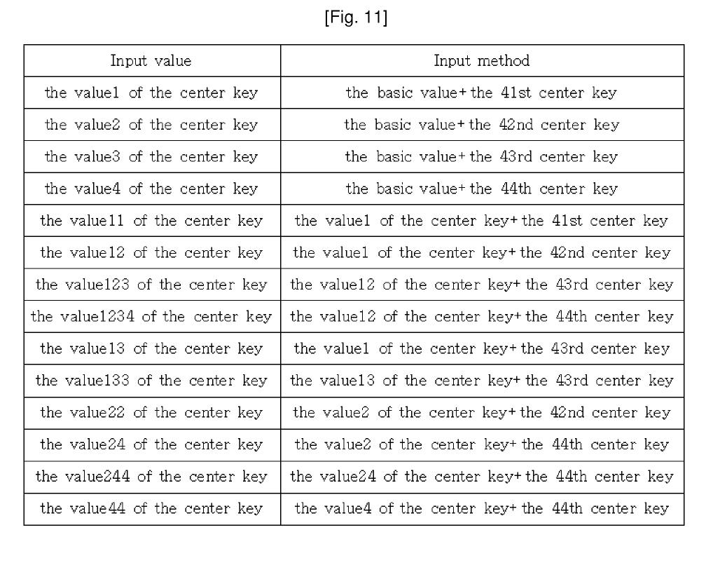

FIG. 11 is a table for partially indicating methods for inputting key-values in the character input device(4) of the 4th central type of FIG. 4. A value 1 of the center key, a value 2 of the center key, a value 3 of the center key, a value 4 of the center key, a value 11 of the center key, a value 12 of the center key, a value 123 of the center key, a value 1234 of the center key, a value 13 of the center key, a value 133 of the center key, a value 22 of the center key, a value 24 of the center key, a value 244 of the center key, and a value 44 of the center key will be described hereinafter.

In the character input device(4) of the 4th central type, the basic values of the basic key of the respective keys are generated by pressing the corresponding keys one time, the double values of the basic key are generated by pressing the corresponding keys two times, and the triple values of the basic key are generated by pressing the corresponding keys three times.

The value 1 of the center key is generated by pressing the 41st center key(510) after generating the basic value of the respective keys.

The value 2 of the center key is generated by pressing the 42nd center key(520) after generating the basic value of the respective keys.

The value 3 of the center key is generated by pressing the 43rd center key(530) after generating the basic value of the respective keys.

The value 4 of the center key is generated by pressing the 44th center key(540) after generating the basic value of the respective keys.

The value 11 of the center key is generated by pressing the 41st center key(510) after generating the value 1 of the center key of the respective keys. That is, The value 11 of the center key is generated by pressing the 41st center key(510) two times after pressing the respective keys.

The value 12 of the center key is generated by pressing the 42nd center key(520) after generating the value 1 of the center key of the respective keys. That is, the value 12 is generated by pressing the 41st center key(510) and the 42nd center key(520) in order after pressing the respective keys.

The value 123 of the center key is generated by pressing the 43rd center key(530) after generating the value 12 of the center key of the respective keys. That is, the value 123 of the center key is generated by pressing the 41st center key(510), the 42nd center key(520) and the 43rd center key(530) in order after pressing the respective keys.

The value 1234 of the center key is generated by pressing the 44th center key(540) after generating the value 123 of the center key of the respective keys. That is, the value 1234 of the center key is generated by pressing the 41st center key(510), the 42nd center key(520), the 43rd center key(530) and the 44th center key(540) in order after pressing the respective keys.

The value 13 of the center key is generated by pressing the 43rd center key(530) after generating the value 1 of the center key of the respective keys. That is, the value 13 of the center key is generated by pressing the 41st center key(510) and the 43rd center key(530) in order after pressing the respective keys.

The value 133 of the center key is generated by pressing the 43rd center key(530) after generating the value 13 of the center key of the respective keys.

The value 22 of the center key is generated by pressing the 42nd center key(520) after generating the value 2 of the center key of the respective keys. That is, the value 22 of the center key is generated by pressing the 42nd center key(520) two times after pressing the respective keys.

The value 24 of the center key is generated by pressing the 44th center key(540) after generating the value 2 of the center key of the respective keys. That is, the value 24 of the center key is generated by pressing the 42nd center key(520) and the 44th center key(540) in order after pressing the respective keys.

The value 244 of the center key is generated by pressing the 44th center key(540) after generating the value 24 of the center key of the respective keys.

The value 44 of the center key is generated by pressing the 44th center key(540) after generating the value 4 of the center key of the respective keys. That is, the value 44 of the center key is generated by pressing the 44th center key(540) two times after pressing the respective keys.

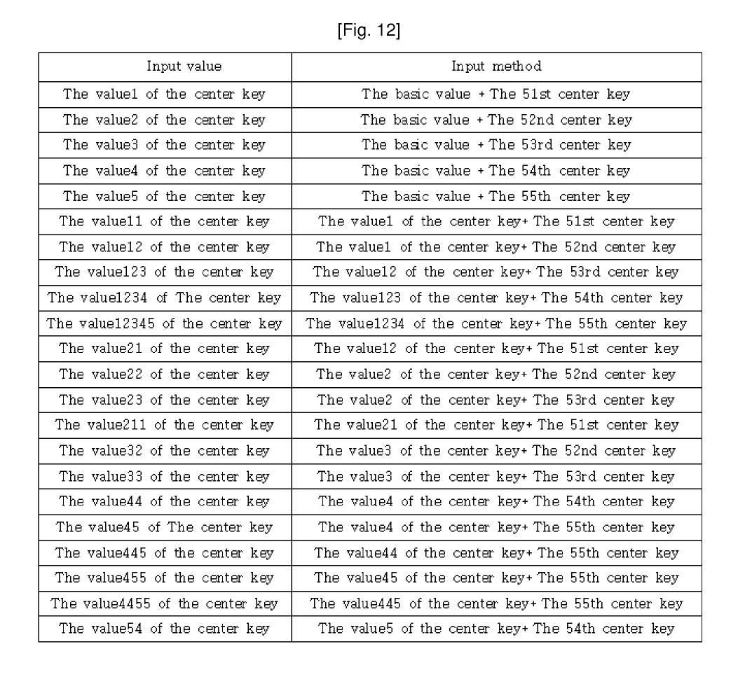

FIG. 12 is a table for partially indicating methods for inputting key-values in the character input device(5) of the 5th central type of FIG. 5, and a value 1 of the center key, a value 2 of the center key, a value 3 of the center key, a value 4 of the center key, a value 5 of the center key, a value 11 of the center key, a value 12 of the center key, a value 123 of the center key, a value 1234 of the center key, a value 12345 of the center key, a value 21 of the center key, a value 22 of the center key, a value 23 of the center key, a value 211 of the center key, a value 32 of the center key, a value 33 of the center key, a value 44 of the center key, a value 45 of the center key, a value 445 of the center key, a value 455 of the center key, a value 4455 of the center key, and a value 54 of the center key will be described hereinafter.

In the character input device(5) of the 5th central type, the basic values of the basic key of the respective keys are generated by pressing the corresponding keys one time, the double values of the basic key are generated by pressing the corresponding keys two times, and the triple values of the basic key are generated by pressing the corresponding keys three times.

The value 1 of the center key is generated by pressing the 51st center key(810) after generating the basic value of the respective keys.

The value 2 of the center key is generated by pressing the 52nd center key(820) after generating the basic value of the respective keys.

The value 3 of the center key is generated by pressing the 53rd center key(830) after generating the basic value of the respective keys.

The value 4 of the center key is generated by pressing the 54th center key(840) after generating the basic value of the respective keys.

The value 11 of the center key is generated by pressing the 51st center key(810) after generating the value 1 of the center key of the respective keys. That is, The value 11 of the center key is generated by pressing the 51st center key(810) two times after pressing the respective keys one time.

The value 12 of the center key is generated by pressing the 52nd center key(820) after generating the value 1 of the center key of the respective keys. That is, the value 12 of the center key is generated by pressing the 51st center key(810) and the 52nd center key(820) in order after pressing the respective keys one time.

The value 123 of the center key is generated by pressing the 53rd center key(830) after generating the value 12 of the center key of the respective keys.

The value 1234 of the center key is generated by pressing the 54th center key(840) after generating the value 123 of the center key of the respective keys.

The value 12345 of the center key is generated by pressing the 55th center key(850) after generating the value 1234 of the center key of the respective keys.

The value 21 of the center key is generated by pressing the 51st center key(810) after generating the 2nd value of the center key of the respective keys. That is, the value 21 of the center key is generated by pressing the 52nd center key(820) and the 51st center key(810) in order after pressing the respective keys one time.

The value 22 of the center key is generated by pressing the 52nd center key(820) after generating the 2nd value of the center key of the respective keys. That is, The value 22 of the center key is generated by pressing the 52nd center key(820) two times after pressing the respective keys one time.

The value 23 of the center key is generated by pressing the 53rd center key(830) after generating the value 2 of the center key of the respective keys.

The value 211 of the center key is generated by pressing the 51st center key(810) after generating the value 21 of the center key of the respective keys.

The value 32 of the center key is generated by pressing the 52nd center key(820) after generating the value 3 of the center key of the respective keys.

The value 33 of the center key is generated by pressing the 53rd center key(830) after generating the value 3 of the center key of the respective keys.

The value 44 of the center key is generated by pressing the 54th center key(840) after generating the value 4 of the center key of the respective keys.

The value 45 of the center key is generated by pressing the 55th center key(850) after generating the value 4 of the center key of the respective keys.

The value 445 of the center key is generated by pressing the 55th center key(850) after generating the value 44 of the center key of the respective keys.

The value 455 of the center key is generated by pressing the 55th center key(850) after generating the value 45 of the center key of the respective keys.

The value 4455 of the center key is generated by pressing the 55th center key(850) after generating the value 445 of the center key of the respective keys.

The value 54 of the center key is generated by pressing the 54th center key(840) after generating the value 5 of the center key of the respective keys.

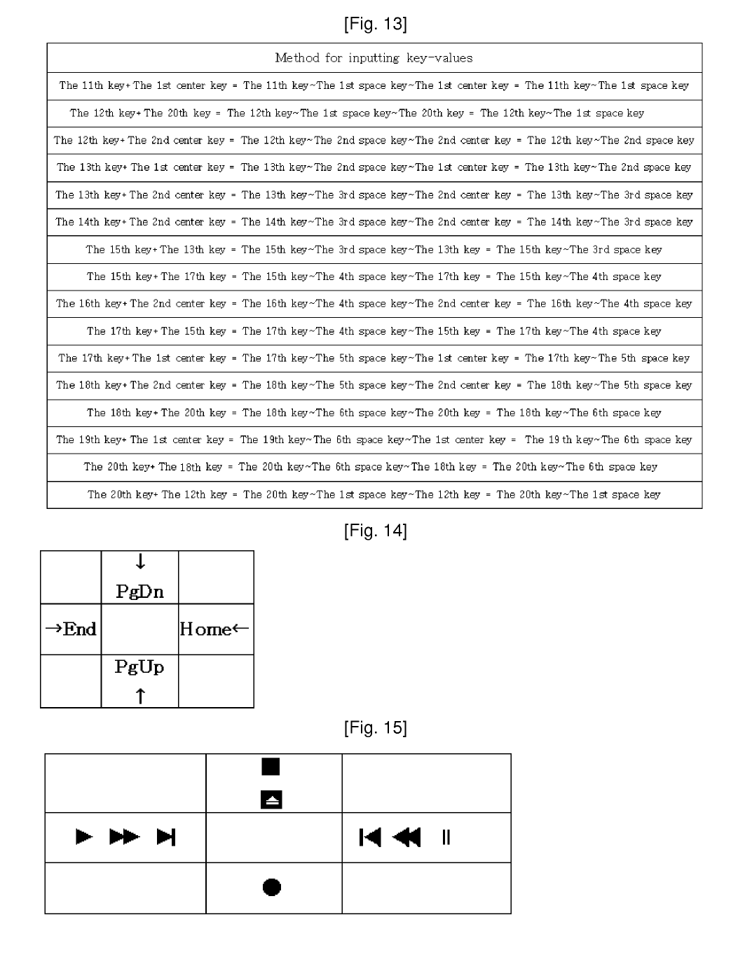

FIG. 13 is a table for indicating methods for inputting key values in the character input device of the 2nd central type with space keys of FIG. 6. Here, ‘to excite a key’ referred below means ‘to press a key’, ‘to touch a key’, and so on.

Referring to FIG. 13, to excite the space key after exciting one of two keys located on a diagonal line with respect to the space key reaches substantially the same result as to press the two keys located on the diagonal line in order. That is to say, when the space key is excited after exciting one of keys surrounding the space key, the space key and a key arranged symmetrically to the excited key with respect to the space key are unified, and thereby exciting the space key reaches substantially the same result as exciting the key arranged symmetrically to the excited key with respect to the space key. Accordingly, the two keys arranged symmetrically to each other with respect to the space key can be excited by the user at one try, for example, by an operation in which the user draws a line through them through the space key.

An 11th key(110), a 12th key(120), a 20th key(200), and 1st center key(210) are located about the 1st space key(910), in which the 11th key(110) and 1st center key(210), and the 12th key(120) and a 20th key(200) are diagonally symmetrical to each other with respect to the 1st space key(910), respectively.

The basic value of the center key of the 11th key(910) is a value generated by exciting the 11th key(110) and 1st center key(210), in which the exciting can be performed by drawing a line in sequence along the 11th key(110), the 1st space key(910) and the 1st center key(210), or by drawing a line along the 11th key(110) and the 1st space key(910), which is because the basic value can be generated by only exciting the 1st space key(910) after exciting of the 11th key(110), due to unification of the 1st space key(910) and the 1st center key(210).

To generate the basic value of the 20th key(200) after generating the basic value of the 12th key(120), the 12th key(120) and the 20th key(200) can be excited in order. Otherwise, the values can be generated by drawing a line through the 12th key(120), the 1st space key(910) and the 20th key(200), or by exciting the 12th key(120) and the 1st space key(910) in sequence.

On the contrary, to generate the basic value of the 12th key(120) after generating the basic value of the 20th key(200), the 20th key(200) and the 12th key(120) can be excited in order. Otherwise, the values can be generated by drawing a line through the 20th key(200), the 1st space key(910) and the 12th key(120) in order, or by drawing a line through the 20th key(200) and the 1st space key(910).

The 2nd space key(920), the 3rd space key(930), the 4th space key(940), the 5th space key(950), and the 6th space key(960) are similar to the 1st space key(910) in that the keys diagonally symmetrical to each other with respect to the corresponding space key can be excited together through the space key. When one of keys surrounding the space key is excited, the space key is automatically unified with a key arranged symmetrically to the excited key with respect to the space key, and thus, although only the space key is excited after the key is excited, the result is substantially the same as the case where the key arranged symmetrically to the excited key with respect to the space key is excited.

FIG. 14 illustrates a character input device of the 1st central type for moving a cursor according to another embodiment of the present invention. The character input device of the 1st central type for moving the cursor has a 3×3 arrangement as shown in FIG. 1, and consists of a 1st key(10), a 2nd key(20), a 3rd key(30), a 4th key(40), a 5th key(50), a 6th key(60), a 7th key(70), a 8th key(80), and a 9th key(90). Among these, the 1st key(10), the 3rd key(30), the 7th key(70) and the 9th key(90) are not used and only the others are used.

In the character input device of the 1st central type for moving the cursor, the basic value of the 2nd key(20) is “↓” to move the cursor down, and a basic value of the center key is “PgDn” to move the cursor to the bottom of the page. That is, the value becomes “↓” when the 2nd key(20) is pressed once, and “PgDn” when the center key, i.e., the 5th key(50) is pressed after the 2nd key(20) is pressed.

In the character input device of the 1st central type for moving the cursor, the basic value of the 4th key(40) is “→” to move the cursor to the right, and a basic value of the center key is “End” to move the cursor to the end of the line on which the cursor is present.

In the character input device of the 1st central type for moving the cursor, the basic value of the 6th key(60) is “←” to move the cursor to the left, and a basic value of the center key is “Home” to move the cursor to the front of the line on which the cursor is present.

In the character input device(1) of the 1st central type for moving the cursor, the basic value of the 8th key is “↑” to move the cursor up, and a basic value of the center key is “PgUp” to move the cursor to the top of the page.

FIG. 15 illustrates a character input device of the 1st central type for a record player according to another embodiment of the present invention. The character input device(1) of the 1st central type for the record player has a 3×3 arrangement as shown in FIG. 1, and consists of a 1st key(10), a 2nd key(20), a 3rd key(30), a 4th key(40), a 5th key(50), a 6th key(60), a 7th key(70), a 8th key(80), and a 9th key(90). Among these, the 1st key(10), the 3rd key(30), a 7th key(70) and a 9th key(90) are not used and only the others are used as shown in FIG. 15.

In the character input device of the 1st central type for the record player, a basic value of the 2nd key is “▪” to function as a stop of a record player, and a basic value of the center key is “ [symbol] ” to eject out a playback medium from the player. That is, “▪” is generated by pressing the 2nd key(20) once, and “ [symbol] ” is generated by pressing the center key, i.e. the 5th key(50) after pressing the 2nd key(20).

In the character input device of the 1st central type for the record player, a basic value of the 4th key(40) is [symbol] to play the record player, a basic value of the center key is [symbol] to perform a fast-forward winding operation, and a double value of the center key is “ [symbol] ” to jump the cursor to the next section. That is to say, [symbol] is generated by pressing the 4th key(40) once, [symbol] by pressing the center key, i.e. the 5th key(50) after pressing the 4th key(40), and “ [symbol] ” by pressing the center key, i.e. the 5th key(50) two times after pressing the 4th key(40).

In the character input device of the 1st central type for the record player, a basic value of the 6th key(60) is “ [symbol] ” to make a pause, a basic value of the center key is [symbol] to perform a rewinding, and a double value of the center key is “ [symbol] ” to jump the cursor to the previous section.

In the character input device of the 1st central type for the record player, a basic value of the 8th key(80) is “” to perform a recording operation.

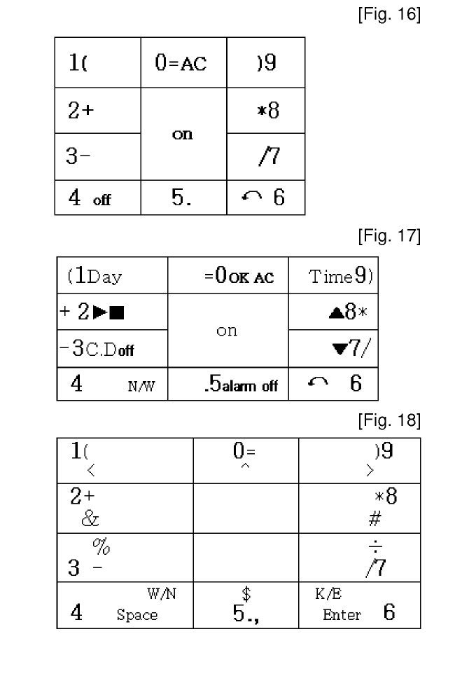

FIG. 16 illustrates a character input device of the 1st central type for numerical calculation according to another embodiment of the present invention. The character input device of the 1st central type for numerical calculation has an arrangement with ten peripheral keys of the character input device(2) of the 1st central type in FIG. 2, and consists of a 1st key(10), a 2nd key(20), a 3rd key(30), a 4ath key(42), a 4bth key(45), a 5th key(50), a 6ath key(62), a 6bth key(65), a 7th key(70), a 8th key(80), and a 9th key(90).

In the character input device of the 1st central type for numerical calculation, a basic value of the 1st key(10) is “1”, and a basic value of the center key is “(”. That is, the value becomes “1” when the 1st key(10) is pressed once, and “(” when the center key, i.e. the 5th key(50) is pressed after the 1st key(10) is pressed.

In the character input device of the 1st central type for numerical calculation, a basic value of the 2nd key(20) is “0”, a basic value of the center key is “=” to display a value resulting from a desired calculation, and a double value of the center key is “AC” to delete all values to start new calculation. That is, the value becomes “0” when the 2nd key(20) is pressed once, “=” when the 2nd key(20) is pressed and then the center key, i.e. the 5th key(50) is pressed, and “AC” when the 2nd key(20) is pressed and then the center key, i.e. the 5th key(50) is pressed two times.

In the character input device of the 1st central type for numerical calculation, a basic value of the 3rd key(30) is “9” and a basic value of the center key is “)”.

In the character input device of the 1st central type for numerical calculation, a basic value of the 4ath key(42) is “2” and a basic value of the center key is “+”.

In the character input device of the 1st central type for numerical calculation, a basic value of the 4bth key(45) is “3” and a basic value of the center key is “−”.

In the character input device of the 1st central type for numerical calculation, a basic value of the 5th key(50) is “on” to turn power on.

In the character input device of the 1st central type for numerical calculation, a basic value of the 6ath key(62) is “8” and a basic value of the center key is “*”.

In the character input device of the 1st central type for numerical calculation, a basic value of the 6bth key(65) is “7” and a basic value of the center key is “/”.

In the character input device of the 1st central type for numerical calculation, a basic value of the 7th key(70) is “4” and a basic value of the center key is “off” to turn power off.

In the character input device of the 1st central type for numerical calculation, a basic value of the 8th key(80) is “5” and a basic value of the center key is “.”.

In the character input device of the 1st central type for numerical calculation, a basic value of the 9th key(90) is “6”, and a basic value of the center key is “ [symbol] ” to delete a previous all values to start any calculation.

FIG. 17 illustrates a character input device of the 1st central type for numerical calculation/clock according to another embodiment of the present invention. The character input device of the 1st central type for numerical calculation/clock has an arrangement with ten peripheral keys of the character input device(2) of the 1st central type in FIG. 2, and consists of a 1st key(10), a 2nd key(20), a 3rd key(30), a 4ath key(42), a 4bth key(45), a 5th key(50), a 6ath key(62), a 6bth key(65), a 7th key(70), a 8th key(80), and a 9th key(90).

When the character input device of the 1st central type for numerical calculation/clock of FIG. 17 is in numerical calculation mode, the construction and input method are similar to those of the device of FIG. 16 except that a basic value of the center key of the 7th key(70) is “N/W” to toggle between the numerical calculation mode and the clock mode.

The case that the character input device of the 1st central type for numerical calculation/clock of FIG. 17 is changed into the clock mode by “N/W” will be described hereinafter.

When the character input device of the 1st central type for numerical calculation/clock is in the clock mode, a basic value of the 1st key(10) is “1”, and a basic value of the center key is “Day” as a mode for setting a date. That is, “1” is generated by pressing the 1st key(10) once, and “Day” of the setting mode of a date is generated by pressing the 1st key(10) and then pressing the center key, i.e. the 5th key(50).

When the character input device of the 1st central type for numerical calculation/clock is in the clock mode, a basic value of the 2nd key(20) is “0”, a basic value of the center key is “OK” to accept the inputted value, and a double value of the center key is “AC” to delete all values to start any new input operation. That is, “0” is generated by pressing the 2nd key(20) once, “OK” is generated by pressing the 2nd key(20) and then by pressing the center key, i.e. the 5th key(50), and “AC” is generated by pressing the 2nd key(20) and then by pressing the center key, i.e. the 5th key(50) two times.

When the character input device of the 1st central type for numerical calculation/clock is in the clock mode, a basic value of the 3rd key is “9” and a basic value of the center key is “Time” to display a time.

When the character input device of the 1st central type for numerical calculation/clock is in the clock mode, a basic value of the 4ath key is “2”, a basic value of the center key is [symbol] to start a stopwatch, and a double value of the center key is “▪” to stop a stopwatch.

When the character input device of the 1st central type for numerical calculation/clock is in the clock mode, a basic value of the 4bth key is “3”, a basic value of the center key is “C.D” as a mode for setting a countdown-time, and a double value of the center key is “off” to cancel the setting of countdown-time.

When the character input device of the 1st central type for numerical calculation/clock is in the clock mode, a basic value of the 5th key(50) is “on” to turn power on.

When the character input device of the 1st central type for numerical calculation/clock is in the clock mode, a basic value of the 6ath key(62) is “8” and a basic value of the center key is “▴” to raise a volume.

When the character input device of the 1st central type for numerical calculation/clock is in the clock mode, a basic value of the 6bth key(65) is “7” and a basic value of the center key is “▾” to lower the volume.

When the character input device of the 1st central type for numerical calculation/clock is in the clock mode, a basic value of the 7th key is “4” and a basic value of the center key is “N/W” to toggle between the numerical calculation mode and the clock mode.

When the character input device of the 1st central type for numerical calculation/clock is in the clock mode, a basic value of the 8th key is “5”, a basic value of the center key is “alarm” of a mode for setting an alarm time, and a double value of the center key is “off” to cancel the alarm time setting.

When the character input device of the 1st central type for numerical calculation/clock is in the clock mode, a basic value of the 9th key is “6”, and a basic value of the center key is “ [symbol] ” to return to the previous input state.

FIG. 18 illustrates a character input device of the 2nd central type for a numerical calculation according to another preferred embodiment of the present invention.

The character input device of the 2nd central type for numerical calculation of FIG. 18 has a 3×4 arrangement of the character input device(3) of the 2nd central type of FIG. 3, and can be used when the character input device(3) of the 2nd central type for languages is in the numerical calculation mode. The character input device of the 2nd central type for a numerical calculation consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220).

In the character input device of the 2nd central type for numerical calculation of FIG. 18, a basic value of the 11th key(110) is “1”, a basic value of the center key is “(”, and a basic value of the distant center key is “<”. That is, That is, “1” is generated by pressing the 11th key(110) once, “(” is generated by pressing the 11th key(110) and then by pressing the center key, i.e. the 1st center key(210), and “<” is generated by pressing the 11th key(110) and then by pressing the distant center key, i.e. the 2nd center key(220).

In the character input device of the 2nd central type for numerical calculation, a basic value of the 12th key(120) is “2”, a basic value of the center key is “+”, and a basic value of the distant center key is “&”.

In the character input device of the 2nd central type for numerical calculation, a basic value of the 13th key(130) is “3”, a basic value of the center key is “−”, and a basic value of the distant center key is “%”.

In the character input device of the 2nd central type for numerical calculation, a basic value of the 14th key(140) is “4”, a basic value of the center key is “W/N” to toggle between a language-writing mode and a numerical calculation mode, and a basic value of the distant center key is “Space” to leave a space.

In the character input device of the 2nd central type for numerical calculation, a basic value of the 15th key(150) is “5”, a basic value of the center key is “.”, and a basic value of the distant center key is “$”,

In the character input device of the 2nd central type for numerical calculation, a basic value of the 16th key(160) is “6”, a basic value of the center key is “K/E” to toggle among language modes in the language-writing mode, and a basic value of the distant center key is “Enter”. Here, a basic value of the center key of the 16th key(160) is a toggle switch to change one language in use into another language and “K/E” is especially to toggle between Korean and English. Therefore, the basic value of the center key of the 16th key(160) is not fixed but can be changed in name according to languages to use.

In the character input device of the 2nd central type for numerical calculation, a basic value of the 17th key(170) is “7”, a basic value of the center key is “/”, and a basic value of the distant center key is “÷”.

In the character input device of the 2nd central type for numerical calculation, a basic value of the 18th key(180) is “8”, a basic value of the center key is “*”, and a basic value of the distant center key is “#”.

In the character input device of the 2nd central type for numerical calculation, a basic value of the 19th key(190) is “9”, a basic value of the center key is “)”, and a basic value of the distant center key is “>”.

In the character input device of the 2nd central type for numerical calculation, a basic value of the 20th key(200) is “0”, a basic value of the center key is “=”, and a basic value of the distant center key is “̂”.

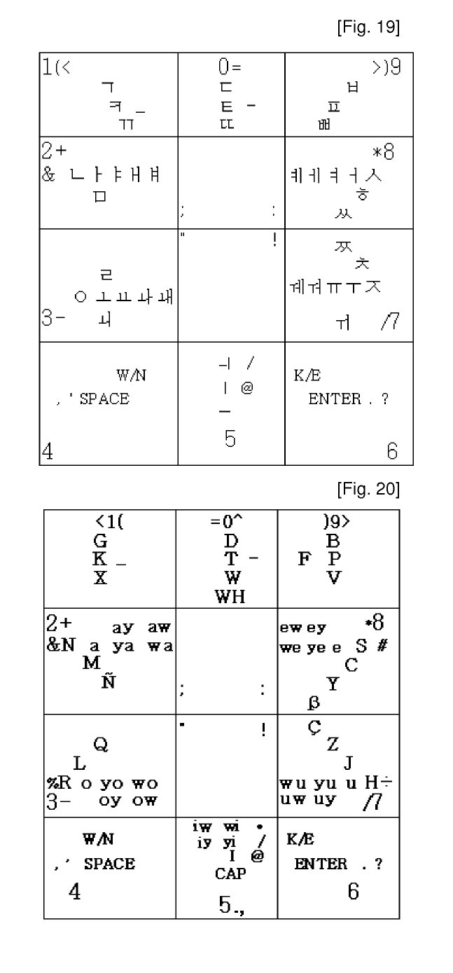

FIG. 19 illustrates a character input device(3) of the 2nd central type for Korean according to another embodiment of the present invention. The character input device of the 2nd central type for Korean has a 3×4 arrangement of the character input device of the 2nd central type of FIG. 3, and consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220).

In the character input device of the 2nd central type for Korean of FIG. 19, when the device is in Korean-writing mode, a basic value of the 11th key(110) is “□”, a basic value of the center key is “□”, a double value of the center key is “□”, and a basic value of the distant center key is “_”. Other values shown in the 11th key(110), e.g., “1, (, <” are values feasible in numerical calculation mode. That is, “□” is generated by pressing the 11th key(110) once, “□” by pressing the 11th key(110) and then pressing the center key, i.e. the 1st center key(210), “□” by pressing the 11th key(110) and then pressing the 1st center key(210) two times, and “_” by pressing the 11th key(110) and then the distant center key, i.e. the 2nd center key(220).

In the character input device of the 2nd central type for Korean, when the device is in Korean-writing mode, a basic value of the 12th key(120) is “□”, a basic value of the center key is “□”, a double value of the center key is “□”, a successive value of the center key is “□”, a successive double value of the center key is “□”, and a basic value of the distant center key is “□”. Other values shown in the 12th key(120), e.g., “2, +, &” are values feasible in numerical calculation mode. Here, the successive value of the center key of the 12th key is generated by pressing the 12th key(120), pressing the center key, i.e. the 1st center key(210), and pressing the distant center key, i.e. the 2nd center key(220) in order, which is “□”. The successive double value of the center key of the 12th key is generated by pressing the 12th key(120), pressing the center key, i.e. the 1st center key(210) two times, and pressing the distant center key, i.e. the 2nd center key(220) in order, which is “□”.

In the character input device of the 2nd central type for Korean, when the device is in Korean-writing mode, a basic value of the 13th key(130) is “□”, a basic value of the center key is “□”, a double value of the center key is “□”, a successive value of the center key is “□”, a successive double value of the center key is “□”, and a basic value of the distant center key is “□”. “□” is generated by pressing the 15th key(150) after generating “□” of the basic value of the center key. Other values shown in the 13th key(130), e.g., “3, −” are values feasible in numerical calculation mode. Here, the center key of the 13th key(130) is the 2nd center key(220), and the distant center key of the 13th key(130) is the 1st center key(210). “□”, i.e., the double value of the distant center key can be generated.

In the character input device of the 2nd central type for Korean, when the device is in Korean-writing mode, a basic value of the 14th key(140) is “Space”, a basic value of the center key is “W/N”, a basic value of the distant center key is “,”, a double value of the distant center key is “;”, a successive value of the distant center key is “′”, and a successive double value of the distant center key is “′”. Other value shown in the 14th key(140), e.g., “4” is a value feasible in numerical calculation mode. “Space”, the basic value of the 14th key(140), is used to leave a space, in which a space is left whenever the key is pressed once. “W/N”, the basic value of the center key, is used to toggle between Korean-writing mode and numerical calculation mode, which changes Korean-writing mode into numerical calculation mode and vice versa.

In the character input device of the 2nd central type for Korean, when the device is in Korean-writing mode, a basic value of the 15th key(150) is “□”, a double value of the basic key is “□”, a basic value of the center key is “□”, a basic value of the distant center key is “@”, a double value of the distant center key is “/”, a successive value of the distant center key is “˜”, and a successive double value of the distant center key is “□”.

In the character input device of the 2nd central type for Korean, when the device is in Korean-writing mode, a basic value of the 16th key(160) is “ENTER”, a basic value of the center key is “K/E”, a basic value of the distant center key is “.”, a double value of the distant center key is “:”, a successive value of the distant center key is “?”, a successive double value of the distant center key is “!”, a double successive value of the distant center key is “ [symbol] ”, and a double successive double value of the distant center key is “ [symbol] ”. Other value shown in the 16th key(160), e.g., “6” is a value feasible in numerical calculation mode. “ENTER”, the basic value of the 16th key(160), is used to make a line, in which one line is made when the key is pressed once. “K/E”, the basic value of the center key, is used to toggle between Korean-writing mode and English-writing mode, which changes Korean-writing mode into English-writing mode and vice versa.

In the character input device of the 2nd central type for Korean, when the device is in Korean-writing mode, a basic value of the 17th key(170) is “□”, a basic value of the center key is “□”, a double value of the center key is “□”, a successive value of the center key is “□”, a successive double value of the center key is “□”, a basic value of the distant center key is “□”, and a double value of the distant center key is “□”. Other values shown in the 17th key(170), e.g., “/, 7” are values feasible in numerical calculation mode.

In the character input device of the 2nd central type for Korean, when the device is in Korean-writing mode, a basic value of the 18th key(180) is “□”, a basic value of the center key is “□”, a double value of the center key is “□”, a successive value of the center key is “□”, a successive double value of the center key is “□”, a basic value of the distant center key is “□”, and a double value of the distant center key is “□”. Other values shown in the 18th key(180), e.g., “*, 8” are values feasible in numerical calculation mode.

In the character input device of the 2nd central type for Korean, when the device is in Korean-writing mode, a basic value of the 19th key(190) is “□”, a basic value of the center key is “□”, and a double value of the center key is “□”. Other values shown in the 19th key(190), e.g., “>, (, 9” are values feasible in numerical calculation mode.

In the character input device of the 2nd central type for Korean, when the device is in Korean-writing mode, a basic value of the 20th key(200) is “□”, a basic value of the center key is “□”, a double value of the center key is “□”, and a basic value of the distant center key is “−”. Other values shown in the 20th key(200), e.g., “0, =” are values feasible in numerical calculation mode.

FIG. 20 illustrates a character input device of the 2nd central type for Roman according to another embodiment of the present invention. The character input device of the 2nd central type for Roman of FIG. 20 is typically used when Japanese letters are typed.

The character input device of the 2nd central type for Roman of FIG. 20 has a 3×4 arrangement of the character input device of the 2nd central type as shown in FIG. 3, and consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220).

In the character input device of the 2nd central type for Roman of FIG. 20, when the device is in Roman-writing mode, a basic value of the 11th key(110) is “G”, a basic value of the center key is “K”, a double value of the center key is “X”, and a basic value of the distant center key is “_”. Other values shown in the 11th key(110), e.g., “<, 1, (” are values feasible in numerical calculation mode.

In the character input device of the 2nd central type for Roman, when the device is in Roman-writing mode, a basic value of the 12th key(120) is “N”, a basic value of the center key is “a”, a double value of the center key is “ya”, a successive value of the center key is “wa”, a triple value of the center key is “ay”, a successive double value of the center key is “aw”, a basic value of the distant center key is “M”, and a double value of the distant center key is “ [symbol] ”. Other values shown in the 12th key(120), e.g., “2, +, &” are values feasible in numerical calculation mode.

In the character input device of the 2nd central type for Roman, when the device is in Roman-writing mode, a basic value of the 13th key(130) is “R”, a basic value of the center key is “o”, a double value of the center key is “yo”, a successive value of the center key is “wo”, a triple value of the center key is “oy”, a successive double value of the center key is “ow”, a basic value of the distant center key is “L”, and a double value of the distant center key is “Q”. Other values shown in the 13th key(130), e.g., “3, −, %” are values feasible in numerical calculation mode.

In the character input device of the 2nd central type for Roman, when the device is in Roman-writing mode, a basic value of the 14th key(140) is “Space”, a basic value of the center key is “W/N”, a basic value of the distant center key is “,”, a double value of the distant center key is “;”, a successive value of the distant center key is “′”, and a successive double value of the distant center key is “″”. Other value shown in the 14th key(140), e.g., “4” is a value feasible in numerical calculation mode. “SPACE”, the basic value of the 14th key(140), is used to leave a space, in which a space is left whenever the key is pressed once. “W/N”, the basic value of the center key, is used to toggle between Roman-writing mode and numerical calculation mode, which changes Roman-writing mode into numerical calculation mode and vice versa.

In the character input device of the 2nd central type for Roman, when the device is in Roman-writing mode, a basic value of the 15th key(150) is “CAP”, a basic value of the center key is “I”, a double value of the center key is “yi”, a successive value of the center key is “wi”, a triple value of the center key is “iy”, a successive double value of the center key is “iw”, a basic value of the distant center key is “@”, a double value of the distant center key is “/”, a successive value of the distant center key is “□”, and a successive double value of the distant center key is “˜”. Other values shown in the 15th key(150), e.g., “5, ., ,” are values feasible in numerical calculation mode. “CAP”, the basic value of the 15th key(150), is used to set capital and small letters, in which, in small letter mode, the next one letter is changed into its capital letter by generating “CAP” once, all the next letters are changed into capital letters by generating “CAP” twice continuously, and the letters are returned to the original small letters by generating “CAP” once more.

In the character input device of the 2nd central type for Roman, when the device is in Roman-writing mode, a basic value of the 16th key(160) is “ENTER”, a basic value of the center key is “K/E”, a basic value of the distant center key is “.”, a double value of the distant center key is “:”, a successive value of the distant center key is “?”, a successive double value of the distant center key is “!”, a double successive value of the distant center key is “ [symbol] ”, and a double successive double value of the distant center key is “ [symbol] ”. Other value shown in the 16th key(160), e.g., “6” is a value feasible in numerical calculation mode. “ENTER”, the basic value of the 16th key(160), is used to make a new line, in which one line is made whenever the key is pressed once. “K/E”, the basic value of the center key, is used to toggle between Korean-writing mode and Roman-writing mode. Korean-writing mode is changed into Roman-writing mode by pressing “K/E” and vice versa. Moreover, it is also possible to toggle between Roman and another language beside Korean in language-writing mode.

In the character input device of the 2nd central type for Roman, when the device is in Roman-writing mode, a basic value of the 17th key(170) is “H”, a basic value of the center key is “u”, a double value of the center key is “yu”, a successive value of the center key is “wu”, a triple value of the center key is “uy”, a successive double value of the center key is “uw”, a basic value of the distant center key is “J”, a double value of the distant center key is “Z”, and a successive value of the distant center key is “ [symbol] ”. Other values shown in the 17th key(170), e.g., “/, 7, ÷” are values feasible in numerical calculation mode.

In the character input device of the 2nd central type for Roman, when the device is in Roman-writing mode, a basic value of the 18th key(180) is “S”, a basic value of the center key is “e”, a double value of the center key is “ye”, a successive value of the center key is “we”, a triple value of the center key is “ey”, a successive double value of the center key is “ew”, a basic value of the distant center key is “C”, a double value of the distant center key is “Y”, and a successive value of the distant center key is “β”. Other values shown in the 18th key(180), e.g., “*, 8, #” are values feasible in numerical calculation mode.

In the character input device of the 2nd central type for Roman, when the device is in Roman-writing mode, a basic value of the 19th key(190) is “B”, a basic value of the center key is “P”, a double value of the center key is “V”, and a basic value of the distant center key is “F”. Other values shown in the 19th key(190), e.g., “(, 9, >” are values feasible in numerical calculation mode.

In the character input device of the 2nd central type for Roman, when the device is in Roman-writing mode, a basic value of the 20th key(200) is “D”, a basic value of the center key is “T”, a double value of the center key is “W”, a successive value of the center key is “WH”, and a basic value of the distant center key is “−”. Other values shown in the 20th key(200), e.g., “=, 0, ̂” are values feasible in numerical calculation mode.

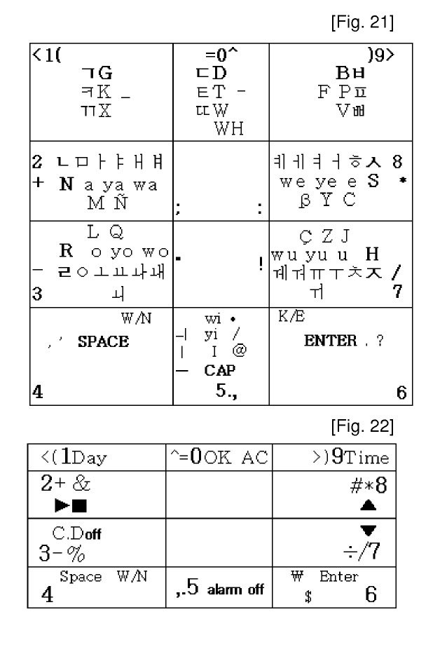

FIG. 21 illustrates a character input device for the integrated type of Korean and Roman characters according to another embodiment of the present invention, in which the functions and input methods are similar to those of the device of FIG. 19 and FIG. 20 except that values of the corresponding keys in FIG. 19 and FIG. 20 are combined into those in FIG. 21. The toggle between Korean-writing mode and Roman-writing mode can be performed by generating “K/E” of the basic value of the center key of the 16th key(160).

FIG. 22 illustrates a character input device of the 2nd central type for numerical calculation/clock according to another embodiment of the present invention.

The character input device of the 2nd central type for numerical calculation/clock of FIG. 22 has a 3×4 arrangement of the character input device(3) of the 2nd central type of FIG. 3, and consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220).

In the character input device of the 2nd central type for numerical calculation/clock of FIG. 22, a basic value of the 11th key(110) is “1”, a basic value of the center key is “(”, a double value of the center key is “<”, and a basic value of the distant center key is “Day”, a mode for setting a date.

In the character input device of the 2nd central type for numerical calculation/clock, a basic value of the 12th key(120) is “2”, a basic value of the center key is “+”, a double value of the center key is “&”, a basic value of the distant center key is [symbol] to start a stopwatch, and a double value of the distant center key is “▪” to stop a stopwatch.

In the character input device of the 2nd central type for numerical calculation/clock, a basic value of the 13th key(130) is “3”, a basic value of the center key is “−”, a double value of the center key is “%”, a basic value of the distant center key is “C.D” as a mode for setting a countdown-time, and a double value of the distant center key is “off” to cancel the setting of countdown-time.

In the character input device of the 2nd central type for numerical calculation/clock, a basic value of the 14th key(140) is “4” and a basic value of the center key is “W/N” to toggle between language-writing mode and numerical calculation mode, and a basic value of the distant center key is “Space” to leave a space.

In the character input device of the 2nd central type for numerical calculation/clock, a basic value of the 15th key(150) is “5”, a basic value of the center key is “.”, a double value of the center key is “,”, a basic value of the distant center key is “alarm” which is a mode for setting an alarm time, and a double value of the distant center key is “off” to cancel the alarm-time setting.

In the character input device of the 2nd central type for numerical calculation/clock, a basic value of the 16th key(160) is “6”, a basic value of the center key is “□” to indicate the won currency, a double value of the center key is “$” to indicate dollar, and a basic value of the distant center key is “Enter”.

In the character input device of the 2nd central type for numerical calculation/clock, a basic value of the 17th key(170) is “7”, a basic value of the center key is “/”, a double value of the center key is “÷”, and a basic value of the distant center key is “▾” to decrease the volume.

In the character input device of the 2nd central type for numerical calculation/clock, a basic value of the 18th key(180) is “8”, a basic value of the center key is “*”, a double value of the center key is “#”, and a basic value of the distant center key is “▴” to increase the volume.

In the character input device of the 2nd central type for numerical calculation/clock, a basic value of the 19th key(190) is “9”, a basic value of the center key is “)”, a double value of the center key is “>”, and a basic value of the distant center key is “Time” to display a time.

In the character input device of the 2nd central type for numerical calculation/clock, a basic value of the 20th key(200) is “0”, a basic value of the center key is “=”, a double value of the center key is “̂”, a basic value of the distant center key is “OK” to accept the inputted value for settings, and a double value of the distant center key is “AC” to delete all setting values to start any new inputting.

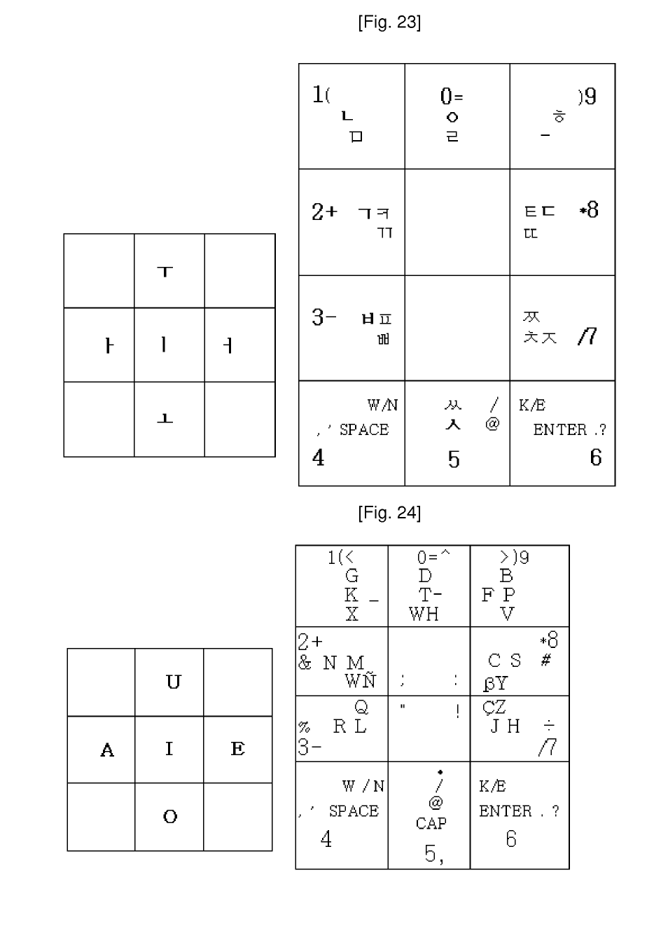

FIG. 23 illustrates a character input device of the separated type for Korean according to another embodiment of the present invention, wherein the device comprises a character input device for vowels, i.e. the device(1) of a 1st central type, and the character input device for consonants, i.e. the device(3) of a 2nd central type.

The character input device(1) of the 1st central type of the separated type for Korean is the device consisting of vowels, and consists of a 2nd key(20), a 4th key(40), a 5th key(50), a 6th key(60), and a 8th key(80).

In the character input device of the separated type for Korean, a basic value of the 2nd key(20) is “□”, and a double value of the basic key is “□”, and a basic value of the center key is “□”.

In the character input device of the separated type for Korean, a basic value of the 4th key(40) is “□”, a double value of the basic key is “□”, a basic value of the center key is “□”, and a double value of the center key is “□”.

In the character input device of the separated type for Korean, a basic value of the 5th key(50) is “□”, a double value of the basic key is “□”, and a triple value of the basic key is “□”.

In the character input device of the separated type for Korean, a basic value of the 6th key(60) is “□”, a double value of the basic key is “□”, a basic value of the center key is “□”, and a double value of the center key is “□”.

In the character input device of the separated type for Korean, a basic value of the 8th key(80) is “□”, a double value of the basic key is “□”, and a basic value of the center key is “□”.

“□” is generated by pressing the 8th key(80) and the 4th key(40) in order, and “□” is generated by then pressing the 5th key(50) in succession.

“□” is generated by pressing the 2nd key(20) and the 6th key(60) in order, and “□” is generated by then pressing the 5th key(50) in succession.

The character input device(3) of the 2nd central type of the separated type for Korean of FIG. 23 consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220) of FIG. 3.

The 14th key(140) and the 16th key(160) of the character input device of the separated type for Korean are similar in construction and input methods to those of the character input device(3) of the 2nd central type for Korean in FIG. 19.

In the character input device of the separated type for Korean characters of FIG. 23, when the device is in Korean-writing mode, a basic value of the 11th key(110) is “□”, and a basic value of the center key is “□”. Other values shown in the 11th key(110), e.g., “1, (” are values feasible in numerical calculation mode.

In the character input device of the separated type for Korean characters, when the device is in Korean-writing mode, a basic value of the 12th key(120) is “□”, a basic value of the center key is “□”, and a double value of the center key is “□”. Other values shown in the 12th key(120), e.g., “2, +” are values feasible in numerical calculation mode.

In the character input device of the separated type for Korean characters, when the device is in Korean-writing mode, a basic value of the 13th key(130) is “□”, a basic value of the center key is “□”, and a double value of the center key is “□”. Other values shown in the 13th key(130), e.g., “3, −” are values feasible in numerical calculation mode.

In the character input device of the separated type for Korean characters, when the device is in Korean-writing mode, a basic value of the 15th key(150) is “□”, a basic value of the center key is “□”, a basic value of the distant center key is “@”, and a double value of the distant center key is “/”. Other value shown in the 15th key(150), e.g., “5” is a value feasible in numerical calculation mode.

In the character input device of the separated type for Korean characters, when the device is in Korean-writing mode, a basic value of the 17th key(170) is “□”, a basic value of the center key is “□”, and a basic value of the distant center key is “□”. Other values shown in the 17th key(170), e.g., “/, 7” are values feasible in numerical calculation mode.

In the character input device of the separated type for Korean characters, when the device is in Korean-writing mode, a basic value of the 18th key(180) is “□”, a basic value of the center key is “□”, and a basic value of the distant center key is “□”. Other values shown in the 18th key(180), e.g., “*, 8” are values feasible in numerical calculation mode.

In the character input device of the separated type for Korean characters, when the device is in Korean-writing mode, a basic value of the 19th key(190) is “□”, and a basic value of the center key is “□”. Other values shown in the 19th key(190), e.g., “), 9” are values feasible in numerical calculation mode.

In the character input device of the separated type for Korean characters, when the device is in Korean-writing mode, a basic value of the 20th key(200) is “□”, and a basic value of the center key is “□”. Other values shown in the 20th key(200), e.g., “0, =” are values feasible in numerical calculation mode.

To sum up, the devices for vowels and for consonants in FIG. 23 are separated from each other, wherein, in the device for vowels, basic values of the basic keys are “□”, “□”, “□”, “□” and “□” vowels and the other vowels, e.g., compound vowels are indicated using double values of the basic keys, basic values of the center keys, and double values of the center keys, and wherein, in the devices for consonants, basic values of the basic keys are “□”, “□”, “□”, “□”, “□”, “□”, “□”, “□” and “□” consonants and the others, e.g., compound consonants, “□, □, □, □”, and double consonants, “□, □, □, □”, are indicated using basic values of the center keys, and basic values of the distant center keys and so on.

FIG. 24 illustrates a character input device of the separated type for Roman according to another embodiment of the present invention. The device of the separated type for Roman characters comprises a character input device of a 1st central type (1) and a character input device of a 2nd central type (3). That is, the device of the separated type for Roman of FIG. 24 comprises the device of the 1st central type for vowels (1) and the device of the 2nd central type for consonants (3).

The character input device(1) of the 1st central type in the device of the separated type for Roman characters of FIG. 24 is a device consisting of vowels, and consists of a 2nd key(20), a 4th key(40), a 5th key(50), a 6th key(60), and a 8th key(80).

In the character input device of the separated type for Roman, a basic value of the 2nd key(20) is “U”.

In the character input device of the separated type for Roman, a basic value of the 4th key(40) is “A”.

In the character input device of the separated type for Roman, a basic value of the 5th key(50) is “I”.

In the character input device of the separated type for Roman, a basic value of the 6th key(60) is “E”.

In the character input device of the separated type for Roman, a basic value of the 8th key(80) is “O”.

The character input device(3) of the 2nd central type in the device of the separated type for Roman characters of FIG. 24 consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220).

The 11th key(110), the 14th key(140), the 16th key(160), the 19th key(190), and the 20th key(200) of the character input device of the separated type for Roman are similar in construction and input methods to those of the device in FIG. 20.

In the character input device of the separated type for Roman characters, when the device is in Roman-writing mode, a basic value of the 12th key(120) is “N”, a basic value of the center key is “M”, a basic value of the distant center key is “W”, and a successive value of the distant key is “ [symbol] ”. Other values shown in the 12th key(120), e.g., “2, +, &” are values feasible in numerical calculation mode.

In the character input device of the separated type for Roman characters, when the device is in Romanwriting mode, a basic value of the a 13th key(130) is “R”, a basic value of the center key is “L”, and a basic value of the distant center key is “Q”. Other values shown in the 13th key(130), e.g., “3, −, %” are values feasible in numerical calculation mode.

In the character input device of the separated type for Roman characters, when the device is in Roman-writing mode, a basic value of the a 15th key(150) is “CAP”, a basic value of the center key is “@”, a double value of the center key is “/”, and a successive value of the center key is “□”. Other values shown in the 15th key(150), e.g., “5, ., ,” are values feasible in numerical calculation mode. The basic value of the 15th key(150), i.e., “CAP” is a key used to set capital or small letters.

In the character input device of the separated type for Roman characters, when the device is in Roman-writing mode, a basic value of the a 17th key(170) is “H”, a basic value of the center key is “J”, a basic value of the distant center key is “Z”, and a successive value of the distant center key is “ [symbol] ”. Other values shown in the 17th key(170), e.g., “/, 7, ÷” are values feasible in numerical calculation mode.

In the character input device of the separated type for Roman characters, when the device is in Roman-writing mode, a basic value of the a 18th key(180) is “S”, a basic value of the center key is “C”, a basic value of the distant center key is “Y”, and a successive value of the distant center key is “β”. Other values shown in the 18th key(180), e.g., “*, 8, #” are values feasible in numerical calculation mode.

To sum up, the devices for vowels and for consonants are separated from each other as shown in FIG. 24, wherein, in the device for vowels, basic values of the basic keys are indicated with “U”, “A”, “I”, “E” and “O” and wherein, in the device for consonants, basic values of the basic keys are indicated with “N”, “R”, “H”, “S”, “G”, “B” and “D” and the other alphabets are indicated using basic values of the center keys, basic values of the distant center keys, and so on.

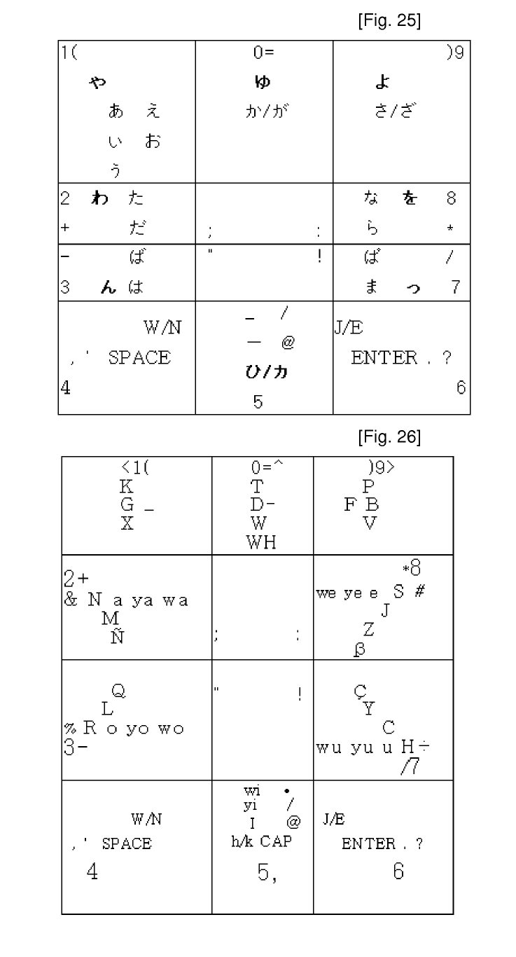

FIG. 25 illustrates a character input device for Japanese according to another embodiment of the present invention.

The character input device for Japanese of FIG. 25 has a 3×4 arrangement of the character input device(3) of the 2nd central type of FIG. 3, and consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220).

In the character input device for Japanese of FIG. 25, when the device is in Japanese-writing mode, a basic value of the 11th key(110) is [symbol] , a basic value of the center key is [symbol] , a double value of the center key is [symbol] , a triple value of the center key is [symbol] , a successive value of the center key is [symbol] , and a successive double value of the center key is [symbol] . Other values shown in the 11th key(110), e.g., “1, (” are values feasible in numerical calculation mode.

When the adjacent center key, i.e., the 1st center key(210) is pressed after generating any Japanese letters ended in the sounds of [symbol] of the double value of the center key, [symbol] of the triple value of the center key, [symbol] of the successive value of the center key, and [symbol] of the successive double value of the center key, the respective values are further generated. Moreover, [symbol] can be further generated by pressing the 2nd center key (220) once more, which is the center key pressed last, after generating any Japanese letters ended in the sound of [symbol] .

In the character input device for Japanese, when the device is in Japanese-writing mode, a basic value of the 12th key(120) is [symbol] , a basic value of the center key is [symbol] , a double value of the center key is [symbol] , a triple value of the center key is [symbol] , a successive value of the center key is [symbol] , a successive double value of the center key is [symbol] , a basic value of the distant center key is [symbol] , a double value of the distant center key is [symbol] , a triple value of the distant center key [symbol] , a successive value of the distant center key is [symbol] , and a successive double value of the distant center key is [symbol] . Other values shown in the 12th key(120), e.g., “2, +” are values feasible in numerical calculation mode.

In the character input device for Japanese, when the device is in Japanese-writing mode, a basic value of the 13th key(130) is [symbol] , a basic value of the center key is [symbol] , a double value of the center key is [symbol] , a triple value of the center key is [symbol] , a successive value of the center key is [symbol] , a successive double value of the center key is [symbol] , a basic value of the distant center key is [symbol] , a double value of the distant center key is [symbol] , a triple value of the distant center key is [symbol] , a successive value of the distant center key is [symbol] , a successive double value of the distant center key is [symbol] . Other values shown in the 13th key(130), e.g., “3, −” are values feasible in numerical calculation mode.

In the character input device for Japanese, when the device is in Japanese-writing mode, a basic value of the 14th key(140) is “SPACE”, a basic value of the center key is “W/N”, a basic value of the distant center key is “,”, a double value of the distant center key is “;”, a successive value of the distant center key is “′”, and a successive double value of the distant center key is “″”. Other value shown in the 14th key(140), e.g., “4” is a value feasible in numerical calculation mode. “SPACE”, the basic value of the 14th key(140), is used to leave a space, in which a space is left whenever the key is pressed once. “W/N”, the basic value of the center key, is used to toggle between Japanese-writing mode and numerical calculation mode, which changes Japanese-writing mode into numerical calculation mode and vice versa.

In the character input device for Japanese, when the device is in Japanese-writing mode, a basic value of the 15th key(150) is [symbol] to toggle between hiragana and katakana, a basic value of the center key is “−” of a long vowel character of katakana, a double value of the center key is “_”, a basic value of the distant center key is “@”, and a double value of the distant center key is “/”. Other value shown in the 15th key(150), e.g., “5” is a value feasible in numerical calculation mode. Moreover, [symbol] can be generated by exciting [symbol] two times in order to generate a double consonant.

In the character input device for Japanese, when the device is in Japanese-writing mode, a basic value of the 16th key(160) is “ENTER”, a basic value of the center key is “J/E”, a basic value of the distant center key is “.”, a double value of the distant center key is “:”, a successive value of the distant center key is “?”, a successive double value of the distant center key is “!”, a double successive value of the distant center key is “ [symbol] ”, and a double successive double value of the distant center key is “ [symbol] ”. Other value shown in the 16th key(160), e.g., “6” is a value feasible in numerical calculation mode. The basic value of the 16th key(160), “ENTER”, is used to make a line, in which one line is made whenever the key is pressed once. “J/E”, the basic value of the center key, is used to toggle between Japanese-writing mode and Roman-writing mode.

In the character input device for Japanese, when the device is in Japanese-writing mode, a basic value of the 17th key(170) is [symbol] , a basic value of the center key is [symbol] , a double value of the center key is [symbol] , a triple value of the center key is [symbol] , a successive value of the center key is [symbol] , a successive double value of the center key is [symbol] , a basic value of the distant center key is [symbol] , a double value of the distant center key is [symbol] , a triple value of the distant center key is [symbol] , a successive value of the distant center key is [symbol] , and a successive double value of the distant center key is [symbol] . Other values shown in the 17th key(170), e.g., “7, /” are values feasible in numerical calculation mode.

In the character input device for Japanese, when the device is in Japanese-writing mode, a basic value of the 18th key(180) is [symbol] , a basic value of the center key is [symbol] , a double value of the center key is [symbol] , a triple value of the center key is [symbol] , a successive value of the center key is [symbol] , a successive double value of the center key is [symbol] , a basic value of the distant center key is [symbol] , a double value of the distant center key is [symbol] , a triple value of the distant center key is [symbol] , a successive value of the distant center key is [symbol] , and a successive double value of the distant center key is [symbol] . Other values shown in the 18th key(180), e.g., “8, *” are values feasible in numerical calculation mode.

In the character input device for Japanese, when the device is in Japanese-writing mode, a basic value of the 19th key(190) is [symbol] , a basic value of the center key is [symbol] , a double value of the center key is [symbol] , a triple value of the center key is [symbol] , a successive value of the center key is [symbol] , a successive double value of the center key is [symbol] , a basic value of the distant center key is [symbol] , a double value of the distant center key is [symbol] , a triple value of the distant center key is [symbol] , a successive value of the distant center key is [symbol] , and a successive double value of the distant center key is [symbol] . Other values shown in the 19th key(190), e.g., “), 9” are values feasible in numerical calculation mode.

In the character input device for Japanese, when the device is in Japanese-writing mode, a basic value of the 20th key(200) is [symbol] , a basic value of the center key is [symbol] , a double value of the center key is [symbol] , a triple value of the center key is [symbol] , a successive value of the center key is [symbol] , a successive double value of the center key is [symbol] , a basic value of the distant center key is [symbol] , a double value of the distant center key is [symbol] , a triple value of the distant center key is [symbol] , a successive value of the distant center key is [symbol] , and a successive double value of the distant center key is [symbol] . Other values shown in the 20th key(200), e.g., “0, =” are values feasible in numerical calculation mode.

In the character input device for Japanese of FIG. 25, basic values of the basic keys are indicated with [symbol] , [symbol] , [symbol] , [symbol] , [symbol] , [symbol] , and [symbol] , elements of [symbol] -column having [symbol] are indicated as basic values of the center keys or basic values of the distant center keys, elements of [symbol] -column having [symbol] are indicated as double values of the center keys or double values of the distant center keys, elements of [symbol] -column having [symbol] are indicated as triple values of the center keys or triple values of the distant center keys, elements of [symbol] -column having [symbol] are indicated as successive values of the center keys or successive values of the distant center keys, and elements of [symbol] -column having [symbol] are indicated as successive double values of the center keys or successive double values of the distant center keys.

FIG. 26 illustrates a character input device for Roman and Japanese characters according to another embodiment of the present invention. The character input device for Roman and Japanese characters of FIG. 26 has a 3×4 arrangement of the character input device(3) of the 2nd central type of FIG. 3, and consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220).

In the character input device for Roman and Japanese characters of FIG. 26, when the device is in Japanese-writing mode, a basic value of the 11th key(110) is “K”, a basic value of the center key is “G”, a double value of the center key is “X”, and a basic value of the distant center key is “_”. Other values shown in the 11th key(110), e.g., “<, 1, (” are values feasible in numerical calculation mode.

In the character input device for Roman and Japanese characters, when the device is in Japanese-writing mode, a basic value of the 12th key(120) is “N”, a double value of the basic key is [symbol] , a basic value of the center key is “a”, a double value of the center key is “ya”, a successive value of the center key is “wa”, a basic value of the distant center key is “M”, and a double value of the distant center key is “ [symbol] ”. Other values shown in the 12th key(120), e.g., “2, +, &” are values feasible in numerical calculation mode.

In the character input device for Roman and Japanese characters, when the device is in Japanese-writing mode, a basic value of the 13th key(130) is “R”, a basic value of the center key is “o”, a double value of the center key is “yo”, a successive value of the center key is “wo”, a basic value of the distant center key is “L”, and a double value of the distant center key is “Q”. Other values shown in the 13th key(130), e.g., “3, −, %” are values feasible in numerical calculation mode.

The 14th key(140) of the character input device for Roman and Japanese characters is similar in construction and input methods to those of the device in FIG. 25, except that “SPACE”, the basic value of the 14th key(140), has a function to leave spaces, as well as a function to display the word list to be used in order to convert romanized Japanese into Japanese of hiragana and katakana.

In the character input device for Roman and Japanese characters, when the device is in Japanese-writing mode, a basic value of the 15th key(150) is “h/k” to toggle between hiragana and katakana, a basic value of the center key is “I”, a double value of the center key is “yi”, a successive value of the center key is “wi”, a basic value of the distant center key is “@”, a double value of the distant center key is “/”, and a successive value of the distant center key is “□”. Other values shown in the 15th key(150), e.g., “5, ,” are values feasible in numerical calculation mode. When the next letter is not a consonant, [symbol] can be generated by exciting “h/k” two times in order to generate a double consonant.

The 16th key(160) of the character input device for Roman and Japanese characters is similar in construction and input methods to that of the device in FIG. 25, except that “ENTER”, the basic value of the 16th key(160), has a function to make a line, as well as a function to finally select the word out of the word list when Japanese is romanized.

In the character input device for Roman and Japanese characters, when the device is in Japanese-writing mode, a basic value of the 17th key(170) is “H”, a basic value of the center key is “u”, a double value of the center key is “yu”, a successive value of the center key is “wu”, a basic value of the distant center key is “C”, a double value of the distant center key is “Y”, and a successive value of the distant center key is “ [symbol] ”. Other values shown in the 17th key(170), e.g., “/, 7, ÷” are values feasible in numerical calculation mode.

In the character input device for Roman and Japanese characters, when the device is in Japanese-writing mode, a basic value of the 18th key(180) is “S”, a basic value of the center key is “e”, a double value of the center key is “ye”, a successive value of the center key is “we”, a basic value of the distant center key is “J”, a double value of the distant center key is “Z”, and a successive value of the distant center key is “β”. Other values shown in the 18th key(180), e.g., “*, 8, #” are values feasible in numerical calculation mode.

In the character input device for Roman and Japanese characters, when the device is in Japanese-writing mode, a basic value of the 19th key(190) is “P”, a basic value of the center key is “B”, a double value of the center key is “V”, and a basic value of the distant center key is “F”. Other values shown in the 19th key(190), e.g., “(, 9, >” are values feasible in numerical calculation mode.

In the character input device for Roman and Japanese characters, when the device is in Japanese-writing mode, a basic value of the 20th key(200) is “T”, a basic value of the center key is “D”, a double value of the center key is “W”, a successive value of the center key is “WH”, and a basic value of the distant center key is “−”. Other values shown in the 20th key(200), e.g., “0, =, ̂” are values feasible in numerical calculation mode.

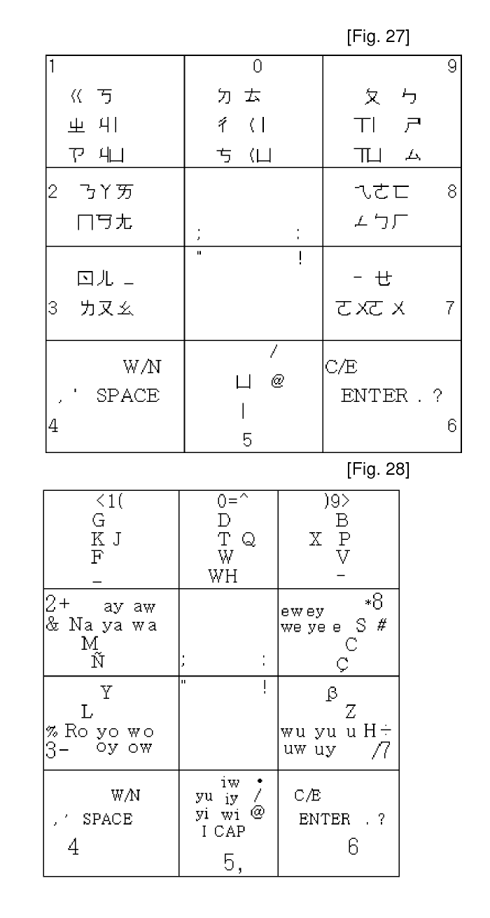

FIG. 27 illustrates a character input device for Chinese using Chinese phonetic symbols according to another embodiment of the present invention. The character input device for Chinese using Chinese phonetic symbols has a 3×4 arrangement as shown in FIG. 3, and consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220).

In the character input device for Chinese using Chinese phonetic symbols, when the device is in Chinese-writing mode, a basic value of the 11th key(110) is “ [symbol] ”, a double value of the basic key is “ [symbol] ”, a basic value of the center key is “ [symbol] ”, a double value of the center key is “ [symbol] ”, a basic value of the distant center key is “ [symbol] ”, and a double value of the distant center key is “ [symbol] ”. Other value shown in the 11th key(110), e.g., “1” is a value feasible in numerical calculation mode.

In the character input device for Chinese using Chinese phonetic symbols, when the device is in Chinese-writing mode, a basic value of the 12th key(120) is “ [symbol] ”, a double value of the basic key is “ [symbol] ”, a basic value of the center key is “ [symbol] ”, a double value of the center key is “ [symbol] ”, a basic value of the distant center key is “ [symbol] ”, and a double value of the distant center key is “ [symbol] ”. Other value shown in the 12th key(120), e.g., “2” is a value feasible in numerical calculation mode.

In the character input device for Chinese using Chinese phonetic symbols, when the device is in Chinese-writing mode, a basic value of the 13th key(130) is “ [symbol] ”, a double value of the basic key is “ [symbol] ”, a basic value of the center key is “ [symbol] ”, a double value of the center key is “ [symbol] ”, a basic value of the distant center key is “ [symbol] ”, and a double value of the distant center key is “_”. Other value shown in the 13th key(130), e.g., “3” is a value feasible in numerical calculation mode.

In the character input device for Chinese using Chinese phonetic symbols, when the device is in Chinese-writing mode, a basic value of the 14th key(140) is “SPACE” to move a cursor to leave a space, a basic value of the center key is “W/N” to toggle between Chinese-writing mode and numerical calculation mode, a basic value of the distant center key is “,”, a double value of the distant center key is “;”, a successive value of the distant center key is “′”, and a successive double value of the distant center key is “″”. Other value shown in the 14th key(140), e.g., “4” is a value feasible in numerical calculation mode.

In the character input device for Chinese using Chinese phonetic symbols, when the device is in Chinese-writing mode, a basic value of the 15th key(150) is “ [symbol] ”, a basic value of the center key is “ [symbol] ”, a basic value of the distant center key is “@”, a double value of the distant center key is “/”, and a successive value of the distant center key is “□”. Other value shown in the 15th key(150), e.g., “5” is a value feasible in numerical calculation mode.

In the character input device for Chinese using Chinese phonetic symbols, when the device is in Chinese-writing mode, a basic value of the 16th key(160) is “ENTER” to make a new line, a basic value of the center key is “C/E” to toggle between Roman-writing mode and Chinese-writing mode, a basic value of the distant center key is “.”, a double value of the distant center key is “:”, a successive value of the distant center key is “?”, a successive double value of the distant center key is “!”, a double successive value of the distant center key is “ [symbol] ”, and a double successive double value of the distant center key is “ [symbol] ”. Other value shown in the 16th key(160), e.g., “6” is a value feasible in numerical calculation mode.

In the character input device for Chinese using Chinese phonetic symbols, when the device is in Chinese-writing mode, a basic value of the 17th key(170) is “ [symbol] ”, a basic value of the center key is “ [symbol] ”, a double value of the center key is “ [symbol] ”, a basic value of the distant center key is “ [symbol] ”, and a double value of the distant center key is “−”. Other value shown in the 17th key(170), e.g., “7” is a value feasible in numerical calculation mode.

In the character input device for Chinese using Chinese phonetic symbols, when the device is in Chinese-writing mode, a basic value of the 18th key(180) is “ [symbol] ”, a double value of the basic key is “ [symbol] ”, a basic value of the center key is “ [symbol] ”, a double value of the center key is “ [symbol] ”, a basic value of the distant center key is “ [symbol] ”, and a double value of the distant center key is “ [symbol] ”. Other value shown in the 18th key(180), e.g., “8” is a value feasible in numerical calculation mode.

In the character input device for Chinese using Chinese phonetic symbols, when the device is in Chinese-writing mode, a basic value of the 19th key(190) is “ [symbol] ”, a double value of the basic key is “ [symbol] ”, a basic value of the center key is “ [symbol] ”, a double value of the center key is “ [symbol] ”, a basic value of the distant center key is “ [symbol] ”, and a double value of the distant center key is “ [symbol] ”. Other value shown in the 19th key(190), e.g., “9” is a value feasible in numerical calculation mode.

In the character input device for Chinese using Chinese phonetic symbols, when the device is in Chinese-writing mode, a basic value of the 20th key(200) is “ [symbol] ”, a double value of the basic key is “ [symbol] ”, a basic value of the center key is “ [symbol] ”, a double value of the center key is “ [symbol] ”, a basic value of the distant center key is “ [symbol] ”, and a double value of the distant center key is “ [symbol] ”. Other value shown in the 20th key(200), e.g., “0” is a value feasible in numerical calculation mode.

FIG. 28 illustrates a character input device for Roman and Chinese characters according to another embodiment of the present invention. The character input device for Roman and Chinese characters has a 3×4 arrangement as shown in FIG. 3, and consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220).

In the character input device for Roman and Chinese characters of FIG. 28, when the device is in Chinese-writing mode, a basic value of the 11th key(110) is “G”, a basic value of the center key is “K”, a double value of the center key is “F”, a successive value of the center key is “_”, and a basic value of the distant center key is “J”. Other values shown in the 11th key(110), e.g., “<, 1, (” are values feasible in numerical calculation mode.

In the character input device for Roman and Chinese characters, when the device is in Chinese-writing mode, a basic value of the 12th key(120) is “N”, a basic value of the center key is “a”, a double value of the center key is “ya”, a successive value of the center key is “wa”, a triple value of the center key is “ay”, a successive double value of the center key is “aw”, a basic value of the distant center key is “M”, and a double value of the distant center key is “ [symbol] ”. Other values shown in the 12th key(120), e.g., “2, +, &” are values feasible in numerical calculation mode.

In the character input device for Roman and Chinese characters, when the device is in Chinese-writing mode, a basic value of the 13th key(130) is “R”, a basic value of the center key is “o”, a double value of the center key is “yo”, a successive value of the center key is “wo”, a triple value of the center key is “oy”, a successive double value of the center key is “ow”, a basic value of the distant center key is “L”, and a double value of the distant center key is “Y”. Other values shown in the 13th key(130), e.g., “3, −,%” are values feasible in numerical calculation mode.

The 14th key(140) of the character input device for Roman and Chinese characters is similar in construction and input methods to that of the device in FIG. 27, except that “SPACE”, the basic value of the 14th key(140), has a function to leave spaces, as well as a function to display the word lists to be used in order to convert romanized Chinese into Chinese phonetic symbols.

In the Chinese phonetic symbols character input device for Roman and Chinese characters, when the device is in Chinese-writing mode, a basic value of the 15th key(150) is “I”, a basic value of the center key is “yi”, a double value of the center key is “yu”, a successive value of the center key is “wi”, a triple value of the center key is “iy”, a successive double value of the center key is “iw”, a basic value of the distant center key is “@”, a double value of the distant center key is “/”, and a successive value of the distant center key is “□”. Other values shown in the 15th key(150), e.g., “5, ,” are values feasible in numerical calculation mode. Meanwhile, when the device is in Roman-writing mode, a basic key of the 15th key(150) is “CAP” and a basic value of the center key is “I”.

The 16th key(160) of the character input device for Roman and Chinese characters is similar in construction and input methods to those of the character input device for Chinese in FIG. 27, except that “ENTER”, the basic value of the 16th key(160), has a function to make a new line, as well as a function to finally select the word out of the word lists when Chinese is romanized.

In the character input device for Roman and Chinese characters, when the device is in Chinese-writing mode, a basic value of the 17th key(170) is “H”, a basic value of the center key is “u”, a double value of the center key is “yu”, a successive value of the center key is “wu”, a triple value of the center key is “uy”, a successive double value of the center key is “uw”, a basic value of the distant center key is “Z”, and a double value of the distant center key is “β”. Other values shown in the 17th key(170), e.g., “/, 7, ÷” are values feasible in numerical calculation mode.

In the character input device for Roman and Chinese characters, when the device is in Chinese-writing mode, a basic value of the 18th key(180) is “S”, a basic value of the center key is “e”, a double value of the center key is “ye”, a successive value of the center key is “we”, a triple value of the center key is “ey”, a successive double value of the center key is “ew”, a basic value of the distant center key is “C”, and a double value of the distant center key is “ [symbol] ”. Other values shown in the 18th key(180), e.g., “*, 8, #” are values feasible in numerical calculation mode.

In the character input device for Roman and Chinese characters, when the device is in Chinese-writing mode, a basic value of the 19th key(190) is “B”, a basic value of the center key is “P”, a double value of the center key is “V”, a successive value of the center key is “−”, and a basic value of the distant center key is “X”. Other values shown in the 19th key(190), e.g., “(, 9, >” are values feasible in numerical calculation mode.

In the character input device for Roman and Chinese characters, when the device is in Chinese-writing mode, a basic value of the 20th key(200) is “D”, a basic value of the center key is “T”, a double value of the center key is “W”, a successive value of the center key is “WH”, and a basic value of the distant center key is “Q”. Other values shown in the 20th key(200), e.g., “0, =, ̂” are values feasible in numerical calculation mode.

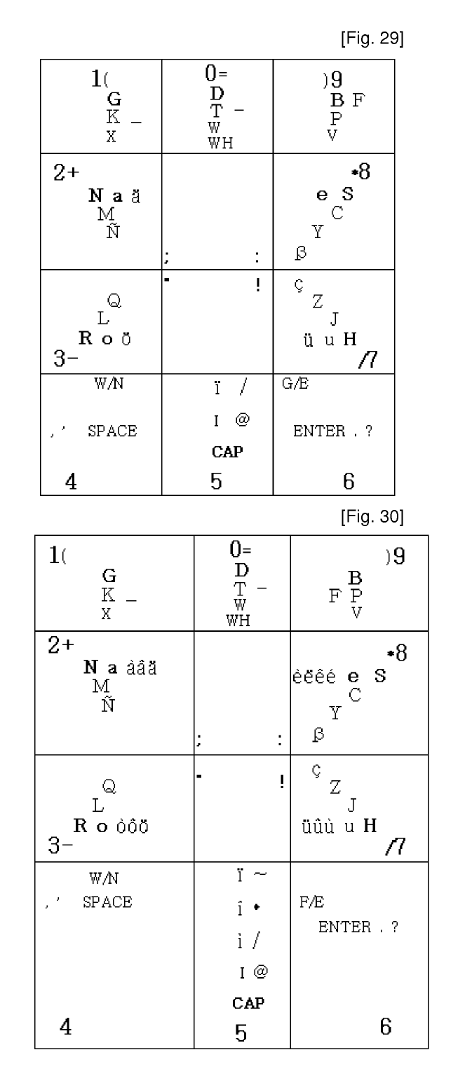

FIG. 29 illustrates a character input device for Roman and German characters according to another embodiment of the present invention. The character input device for Roman and German characters has a 3×4 arrangement as shown in FIG. 3, and consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220).

The 11th key(110), the 14th key(140), the 16th key(160), the 19th key(190), and the 20th key(200) of the character input device for Roman and German characters are similar in construction and input methods to those of the device for Roman in FIG. 20, except that “G/E”, a basic value of the center key of the 16th key(160) is to toggle between Roman-writing mode and German-writing mode.

In the character input device for Roman and German characters, when the device is in German-writing mode, a basic value of the 12th key(120) is “N”, a basic value of the center key is “a”, a double value of the center key is “ [symbol] ”, a basic value of the distant center key is “M”, and a double value of the distant center key is “ [symbol] ”. Other values shown in the 12th key(120), e.g., “2, +” are values feasible in numerical calculation mode.

In the character input device for Roman and German characters, when the device is in German-writing mode, a basic value of the 13th key(130) is “R”, a basic value of the center key is “o”, a double value of the center key is “ [symbol] ”, a basic value of the distant center key is “L”, and a double value of the distant center key is “Q”. Other values shown in the 13th key(130), e.g., “3, −” are values feasible in numerical calculation mode.

In the character input device for Roman and German characters, when the device is in German-writing mode, a basic value of the 15th key(150) is “CAP” to perform a conversion between capital and small letters, a basic value of the center key is “I”, a double value of the center key is “ [symbol] ”, a basic value of the distant center key is “@”, and a double value of the distant center key is “/”. Other value shown in the 15th key(150), e.g., “5” is a value feasible in numerical calculation mode.

In the character input device for Roman and German characters, when the device is in German-writing mode, a basic value of the 17th key(170) is “H”, a basic value of the center key is “u”, a double value of the center key is “ [symbol] ”, a basic value of the distant center key is “J”, a double value of the distant center key is “Z”, and a successive value of the distant center key is “ [symbol] ”. Other values shown in the 17th key(170), e.g., “/, 7” are values feasible in numerical calculation mode.

In the character input device for Roman and German characters, when the device is in German-writing mode, a basic value of the 18th key(180) is “S”, a basic value of the center key is “e”, a basic value of the distant center key is “C”, a double value of the distant center key is “Y”, and a successive value of the distant center key is “β”. Other values shown in the 18th key(180), e.g., “*, 8” are values feasible in numerical calculation mode.

FIG. 30 illustrates a character input device for Roman and French characters according to another embodiment of the present invention. The character input device for Roman and French characters has a 3×4 arrangement as shown in FIG. 3, and consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220).

The 11th key(110), the 14th key(140), the 16th key(160), the 19th key(190), and the 20th key(200) of the character input device for Roman and French characters are similar in construction and input methods to those of the device in FIG. 20, except that “F/E”, a basic value of the center key of the 16th key(160) is to toggle between Roman-writing mode and French-writing mode.

In the character input device for Roman and French characters, when the device is in French-writing mode, a basic value of the 12th key(120) is “N”, a basic value of the center key is “a”, a double value of the center key is “ [symbol] ”, a successive value of the center key is “ [symbol] ”, a successive double value of the center key is “ [symbol] ”, a basic value of the distant center key is “M”, and a double value of the distant center key is “ [symbol] ”. Other values shown in the 12th key(120), e.g., “2, +” are values feasible in numerical calculation mode.

In the character input device for Roman and French characters, when the device is in French-writing mode, a basic value of the 13th key(130) is “R”, a basic value of the center key is “o”, a double value of the center key is “ [symbol] ”, a successive value of the center key is “ [symbol] ”, a successive double value of the center key is “ [symbol] ”, a basic value of the distant center key is “L”, and a double value of the distant center key is “Q”. Other values shown in the 13th key(130), e.g., “3, −” are values feasible in numerical calculation mode.

In the character input device for Roman and French characters, when the device is in French-writing mode, a basic value of the 15th key(150) is “CAP”, a basic value of the center key is “I”, a double value of the center key is “ [symbol] ”, a successive value of the center key is “ [symbol] ”, a successive double value of the center key is “ [symbol] ”, a basic value of the distant center key is “@”, a double value of the distant center key is “/”, a successive value of the distant center key is “□”, and a successive double value of the distant center key is “˜”. Other value shown in the 15th key(150), e.g., “5” is a value feasible in numerical calculation mode.

In the character input device for Roman and French characters, when the device is in French-writing mode, a basic value of the 17th key(170) is “H”, a basic value of the center key is “u”, a double value of the center key is “ [symbol] ”, a successive value of the center key is “ [symbol] ”, a successive double value of the center key is “ [symbol] ”, a basic value of the distant center key is “J”, a double value of the distant center key is “Z”, and a successive value of the distant center key is “ [symbol] ”. Other values shown in the 17th key(170), e.g., “/, 7” are values feasible in numerical calculation mode.

In the character input device for Roman and French characters, when the device is in French-writing mode, a basic value of the 18th key(180) is “S”, a basic value of the center key is “e”, a double value of the center key is “ [symbol] ”, a successive value of the center key is “ [symbol] ”, a successive double value of the center key is “ [symbol] ”, a triple value of the center key is “ [symbol] ”, a basic value of the distant center key is “C”, a double value of the distant center key is “Y”, and a successive value of the distant center key is “β”. Other values shown in the 18th key(180), e.g., “*, 8” are values feasible in numerical calculation mode.

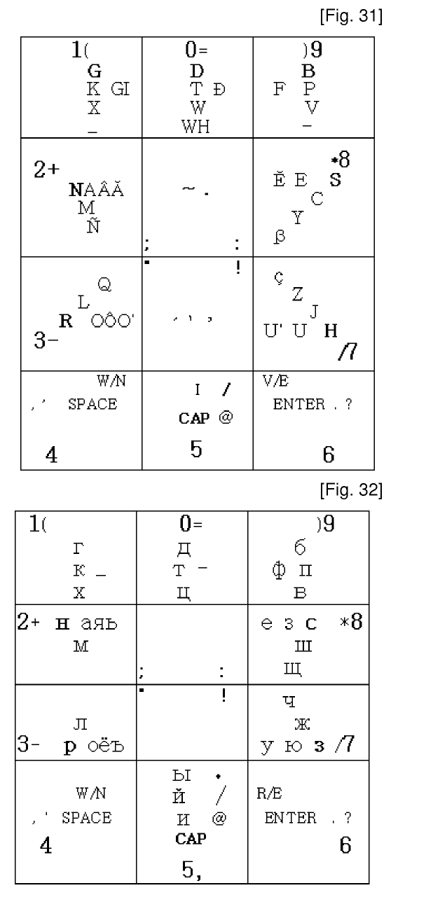

FIG. 31 illustrates a character input device for Roman and Vietnamese characters according to another embodiment of the present invention. The character input device for Roman and Vietnamese characters has a 3×4 arrangement as shown in FIG. 3, and consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220).

The 14th key(140) and the 16th key(160) of the character input device for Roman and Vietnamese characters are similar in construction and input methods to those of the device in FIG. 20, except that “V/E”, a basic value of the center key of the 16th key(160) is to toggle between Roman-writing mode and Vietnamese-writing mode.

In the character input device for Roman and Vietnamese characters, when the device is in Vietnamese-writing mode, a basic value of the 11th key(110) is “G”, a basic value of the center key is “K”, a double value of the center key is “X”, a successive value of the center key is “_”, and a basic value of the distant center key is “GI”. Other values shown in the 11th key(110), e.g., “1, (” are values feasible in numerical calculation mode.

In the character input device for Roman and Vietnamese characters, when the device is in Vietnamese-writing mode, a basic value of the 12th key(120) is “N”, a basic value of the center key is “A”, a double value of the center key is “ [symbol] ”, a successive value of the center key is “ [symbol] ”, a basic value of the distant center key is “M”, and a double value of the distant center key is “ [symbol] ”. Other values shown in the 12th key(120), e.g., “2, +” are values feasible in numerical calculation mode.

In the character input device for Roman and Vietnamese characters, when the device is in Vietnamese-writing mode, a basic value of the 13th key(130) is “R”, a basic value of the center key is “O”, a double value of the center key is “ [symbol] ”, a successive value of the center key is “O′”, a basic value of the distant center key is “L”, and a double value of the distant center key is “Q”. Other values shown in the 13th key(130), e.g., “3, −” are values feasible in numerical calculation mode.

In the character input device for Roman and Vietnamese characters, when the device is in Vietnamese-writing mode, a basic value of the 15th key(150) is “CAP”, a basic value of the center key is “I”, a basic value of the distant center key is “@”, and a double value of the distant center key is “/”. Other values shown in the 15th key(150), e.g., “5” are values feasible in numerical calculation mode.

In the character input device for Roman and Vietnamese characters, when the device is in Vietnamese-writing mode, a basic value of the 17th key(170) is “H”, a basic value of the center key is “U”, a double value of the center key is “U′”, a basic value of the distant center key is “J”, a double value of the distant center key is “Z”, and a successive value of the distant center key is “ [symbol] ”. Other values shown in the 17th key(170), e.g., “/, 7” are values feasible in numerical calculation mode.

In the character input device for Roman and Vietnamese characters, when the device is in Vietnamese-writing mode, a basic value of the 18th key(180) is “S”, a basic value of the center key is “E”, a double value of the center key is “ [symbol] ”, a basic value of the distant center key is “C”, a double value of the distant center key is “Y”, and a double value of the distant center key is “β”. Other values shown in the 18th key(180), e.g., “*, 8” are values feasible in numerical calculation mode.

In the character input device for Roman and Vietnamese characters, when the device is in Vietnamese-writing mode, a basic value of the 19th key(190) is “B”, a basic value of the center key is “P”, a double value of the center key is “V”, a successive value of the center key is “−” and a basic value of the distant center key is “F”. Other values shown in the 19th key(190), e.g., “), 9” are values feasible in numerical calculation mode.

In the character input device for Roman and Vietnamese characters, when the device is in Vietnamese-writing mode, a basic value of the 20th key(200) is “D”, a basic value of the center key is “T”, a double value of the center key is “W”, a successive value of the center key is “WH”, and a basic value of the distant center key is [symbol] . Other values shown in the 20th key(200), e.g., “0, =” are values feasible in numerical calculation mode.

Tone mark can be marked above the unmarked vowels of the 12th key(120), the 13th key(130), the 15th key(150), the 17th key(170) and the 18th key(180) in the character input device for Roman and Vietnamese characters.

In case of the 12th key(120) and the 18th key(180), after unmarked vowel is generated, “ [symbol] ” can be generated on the vowel by pressing the distant center key, i.e. the 2nd center key(220). After generating the “ [symbol] “,”′” can be generated by pressing the distant center key, i.e. the 2nd center key(220), and then “′” can be changed into “ [symbol] ” by pressing the distant center key, i.e. the 2nd center key(220) once more. Meanwhile, after generating the “ [symbol] “,” [symbol] ” can be generated by pressing the center key, i.e. the 1st center key(210), and then “ [symbol] ” can be changed into “.” by pressing the distant center key, i.e. the 1st center key(210) once more.

In case of the 13th key(130), the 15th key(150), and the 17th key(170), after no tone-marked vowel is generated, “ [symbol] ” can be generated on the vowel by pressing the distant center key, i.e. the 1st center key(210). After generating the “ [symbol] “,”′” can be generated by pressing the distant center key, i.e. the 1st center key(210), and then “′” can be changed into “ [symbol] ” by pressing the distant center key, i.e. the 1st center key(210) once more. Meanwhile, after generating the “ [symbol] “,” [symbol] ” can be generated by pressing the center key, i.e. the 2nd center key(220), and then “ [symbol] ” can be changed into “.” by pressing the distant center key, i.e. the 2nd center key(220) once more.

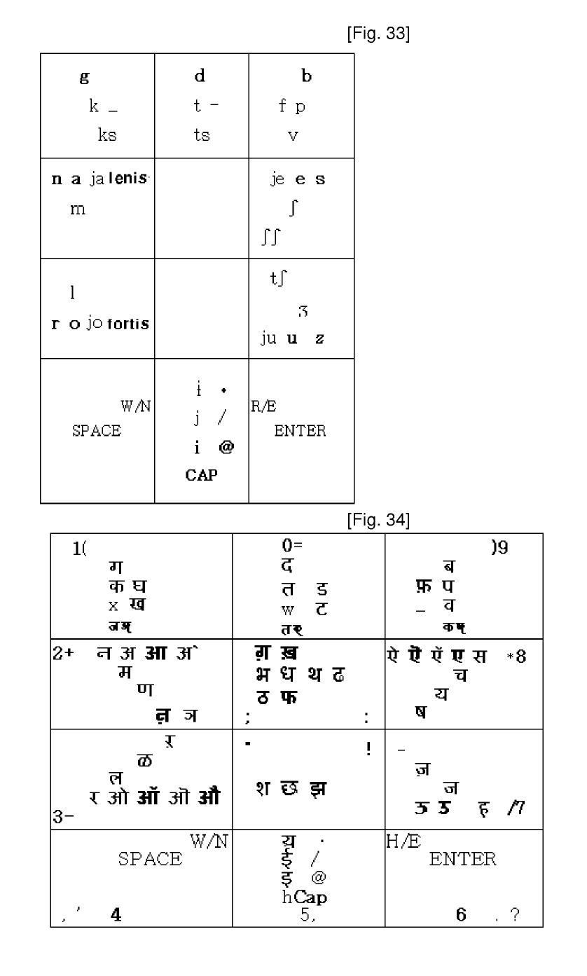

FIG. 32 illustrates a character input device for Russian according to another embodiment of the present invention, and FIG. 33 illustrates phonetic symbols corresponding to characters of FIG. 32. The character input device of the integrated type for Russian of FIG. 32 has a 3×4 arrangement as shown in FIG. 3, and consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220).

The 14th key(140) and the 16th key(160) of the character input device for Russian of FIG. 32, are similar in construction and input methods to those of the device in FIG. 20, except that “R/E”, a basic value of the center key of the 16th key(160) of the character input device for Russian of FIG. 32 is to toggle between Roman-writing mode and Russian-writing mode.

In the character input device of the integrated type for Russian, when the device is in Russian-writing mode, a basic value of the 11th key(110) is [symbol] , a basic value of the center key is “κ”, a double value of the center key is “x”, and a basic value of the distant center key is “_”. Other values shown in the 11th key(110), e.g., “1, (” are values feasible in numerical calculation mode.

In the character input device for Russian, when the device is in Russian-writing mode, a basic value of the 12th key(120) is “H”, a basic value of the center key is “a”, a double value of the center key is [symbol] , a successive value of the center key is [symbol] , and a basic value of the distant center key is “M”. Other values shown in the 12th key(120), e.g., “2, +” are values feasible in numerical calculation mode.

In the character input device for Russian, when the device is in Russian-writing mode, a basic value of the 13th key(130) is “p”, a basic value of the center key is “o”, a double value of the center key is “ [symbol] ”, a successive value of the center key is [symbol] , and a basic value of the distant center key is [symbol] . Other values shown in the 13th key(130), e.g., “3, −” are values feasible in numerical calculation mode.

In the character input device for Russian, when the device is in Russian-writing mode, a basic value of the 15th key(150) is “CAP”, a basic value of the center key is [symbol] , a double value of the center key is [symbol] , a successive value of the center key is [symbol] , a basic value of the distant center key is “@”, a double value of the distant center key is “/”, a successive of the distant center key is “˜”, and a successive double value of the distant center key is “□”. Other values shown in the 15th key(150), e.g., “5” are values feasible in numerical calculation mode.

In the character input device for Russian, when the device is in Russian-writing mode, a basic value of the 17th key(170) is [symbol] , a basic value of the center key is [symbol] , a double value of the center key is “y”, a basic value of the distant center key is [symbol] , and a double value of the distant center key is [symbol] . Other values shown in the 17th key(170), e.g., “7, /” are values feasible in numerical calculation mode.

In the character input device for Russian, when the device is in Russian-writing mode, a basic value of the 18th key(180) is “c”, a basic value of the center key is [symbol] , a double value of the center key is “e”, a basic value of the distant center key is [symbol] , and a double value of the distant center key is [symbol] . Other values shown in the 18th key(180), e.g., “8, *” are values feasible in numerical calculation mode.

In the character input device for Russian, when the device is in Russian-writing mode, a basic value of the 19th key(190) is [symbol] , a basic value of the center key is [symbol] , a double value of the center key is “B”, and a basic value of the distant center key is [symbol] . Other values shown in the 19th key(190), e.g., “), 9” are values feasible in numerical calculation mode.

In the character input device for Russian, when the device is in Russian-writing mode, a basic value of the 20th key(200) is [symbol] , a basic value of the center key is “T”, a double value of the center key is [symbol] , and a basic value of the distant center key is “−”. Other values shown in the 20th key(200), e.g., “0, =” are values feasible in numerical calculation mode.

FIG. 34 illustrates a character input device for Hindi according to another embodiment of the present invention. The character input device for Hindi has a 3×4 arrangement as shown in FIG. 3, and consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220).

Referring to FIG. 34, it should be noted that “ [symbol] “,” [symbol] “,” [symbol] “,” [symbol] “,” [symbol] ” described in the 1st center key(210) and the 2nd center key(220) of the character input device for Hindi refer to the characters which are generated by “hCAP” of the basic value of the 15th key(150), rather than to indicate values generated by pressing the 1st center key(210) and the 2nd center key(220).

The 14th key(140) and the 16th key(160) of the character input device for Hindi are similar in construction and input methods to those of the device in FIG. 20, except that “H/E”, a basic value of the center key of the 16th key(160) in the device, is to toggle between Roman-writing mode and Hindi-writing mode.

In the character input device for Hindi, when the device is in Hindi-writing mode, a basic value of the 11th key(110) is “ [symbol] ”, a basic value of the center key is “ [symbol] ”, a double value of the center key is “x”, a successive value of the center key is “ [symbol] ”, a basic value of the distant center key is “ [symbol] ”, and a double value of the distant center key is “ [symbol] ”. Other values shown in the 11th key(110), e.g., “1, (” are values feasible in numerical calculation mode.

In the character input device for Hindi, when the device is in Hindi-writing mode, a basic value of the 12th key(120) is “ [symbol] ”, a basic value of the center key is “ [symbol] ”, a double value of the center key is “ [symbol] ”, a successive value of the center key is “ [symbol] ”, a basic value of the distant center key is “ [symbol] ”, a double value of the distant center key is “ [symbol] ”, a successive value of the distant center key is “ [symbol] ”, and a successive double value of the distant center key is “ [symbol] ”. Other values shown in the 12th key(120), e.g., “2, +” are values feasible in numerical calculation mode.

In the character input device for Hindi, when the device is in Hindi-writing mode, a basic value of the 13th key(130) is “ [symbol] ”, a basic value of the center key is “ [symbol] ”, a double value of the center key is “ [symbol] ”, a successive value of the center key is “ [symbol] ”, a successive double value of the center key is “ [symbol] ”, a basic value of the distant center key is “ [symbol] ”, a double value of the distant center key is “ [symbol] ”, and a successive value of the distant center key is “ [symbol] ”. Other values shown in the 13th key(130), e.g., “3, −” are values feasible in numerical calculation mode.

In the character input device for Hindi, when the device is in Hindi-writing mode, a basic value of the 15th key(150) is “hCAP” to change a previously generated letter once more, a basic value of the center key is “ [symbol] ”, a double value of the center key is “ [symbol] ”, a successive value of the center key is “ [symbol] ”, basic value of the distant center key is “@”, a double value of the distant center key is “/”, and a successive value of the distant center key is “.”. Other values shown in the 15th key(150), e.g., “5” are values feasible in numerical calculation mode.

In the character input device for Hindi, when the device is in Hindi-writing mode, a basic value of the 17th key(170) is “ [symbol] ”, a basic value of the center key is “ [symbol] ”, a double value of the center key is “ [symbol] ”, a basic value of the distant center key is “ [symbol] ”, a double value of the distant center key is “ [symbol] ”, and a successive value of the distant center key is “−”. Other values shown in the 17th key(170), e.g., “/, 7” are values feasible in numerical calculation mode.

In the character input device for Hindi, when the device is in Hindi-writing mode, a basic value of the 18th key(180) is “ [symbol] ”, a basic value of the center key is “ [symbol] ”, a double value of the center key is “ [symbol] ”, a successive value of the center key is “ [symbol] ”, a successive double value of the center key is “ [symbol] ”, a basic value of the distant center key is “ [symbol] ”, a double value of the distant center key is “ [symbol] ”, and a successive value of the distant center key is “ [symbol] ”. Other values shown in the 18th key(180), e.g., “*, 8” are values feasible in numerical calculation mode.

In the character input device for Hindi, when the device is in Hindi-writing mode, a basic value of the 19th key(190) is “ [symbol] ”, a basic value of the center key is “ [symbol] ”, a double value of the center key is “ [symbol] ”, a successive value of the center key is “ [symbol] ”, a basic value of the distant center key is “ [symbol] ”, and a double value of the distant center key is “_”. Other values shown in the 19th key(190), e.g., “), 9” are values feasible in numerical calculation mode.

In the character input device for Hindi, when the device is in Hindi-writing mode, a basic value of the 20th key(200) is “ [symbol] ”, a basic value of the center key is “ [symbol] ”, a double value of the center key is “w”, a successive value of the center key is “ [symbol] ”, a basic value of the distant center key is “ [symbol] ”, and a double value of the distant center key is “ [symbol] [symbol] ”. Other values shown in the 20th key(200), e.g., “0, =” are values feasible in numerical calculation mode.

In the character input device for Hindi, “hCAP”, which is a basic value of the 15th key(150), is to change a previously generated letter. That is, it changes “ [symbol] ” of the 11th key(110) into “ [symbol] ” and “ [symbol] ” into “ [symbol] ”. Also, it changes “ [symbol] ” of the 17th key(170) into “ [symbol] ”, changes “ [symbol] ” of the 18th key(180) into “ [symbol] ” and “ [symbol] ” into “ [symbol] ”, changes “ [symbol] ” of the 19th key(190) into “ [symbol] ” and “ [symbol] ” into “ [symbol] ”, and changes “ [symbol] ” of the 20th key(200) into “ [symbol] ”, “ [symbol] ” into “ [symbol] ”, “ [symbol] ” into “ [symbol] ” and “ [symbol] ” into “ [symbol] ”.

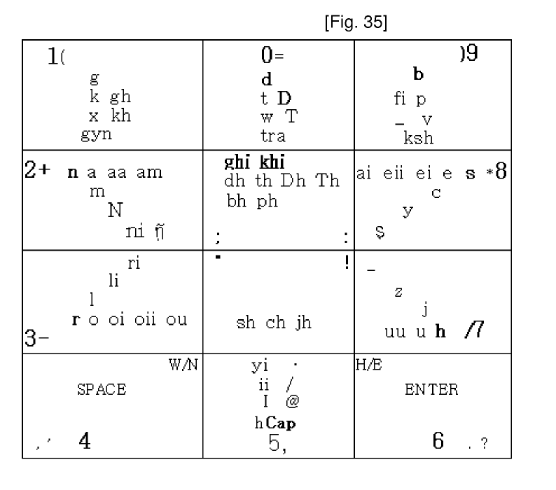

FIG. 35 illustrates a character input device for Roman and Hindi characters romanizing Hindi in the device of FIG. 34 according to another embodiment of the present invention. The character input device for Roman and Hindi characters has a 3×4 arrangement as shown in FIG. 3, and consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220).

Referring FIG. 35, it should be noted that “khi”, “ghi”, “jh”, “sh” and so on described in the 1st center key(210) and the 2nd center key(220) of the character input device for Roman and Hindi characters refer to the characters which are generated by “hCAP” of the basic value of the 15th key(150), rather than to indicate values generated by pressing the 1st center key(210) and the 2nd center key(220).

The 14th key(140) and the 16th key(160) of the character input device for Roman and Hindi characters are similar in construction and input methods to those of the device in FIG. 20, except that “H/E”, a basic value of the center key of the 16th key(160) in the device, is to toggle between Roman-writing mode and Hindi-writing mode.

In the character input device for Roman and Hindi characters, when the device is in Hindi-writing mode, a basic value of the 11th key(110) is “g”, a basic value of the center key is “k”, a double value of the center key is “x”, a successive value of the center key is “gyn”, a basic value of the distant center key is “gh”, and a double value of the distant center key is “kh”.

In the character input device for Roman and Hindi characters, when the device is in Hindi-writing mode, a basic value of the 12th key(120) is “n”, a basic value of the center key is “a”, a double value of the center key is “aa”, a successive value of the center key is “am”, a basic value of the distant center key is “m”, a double value of the distant center key is “N”, a successive value of the distant center key is “ni”, and a successive double value of the distant center key is “ [symbol] ”.

In the character input device for Roman and Hindi characters, when the device is in Hindi-writing mode, a basic value of the 13th key(130) is “r”, a basic value of the center key is “o”, a double value of the center key is “oi”, a successive value of the center key is “oii”, a successive double value of the center key is “ou”, a basic value of the distant center key is “1”, a double value of the distant center key is “li”, and a successive value of the distant center key is “ri”.

In the character input device for Roman and Hindi characters, when the device is in Hindi-writing mode, a basic value of the 15th key(150) is “hCAP” to change a previously generated letter once more, a basic value of the center key is “I”, a double value of the center key is “ii”, a successive value of the center key is “yi”, a basic value of the distant center key is “@”, a double value of the distant center key is “/”, and a successive value of the distant center key is “□”. Other values shown in the 15th key(150), e.g., “5” are values feasible in numerical calculation mode.

In the character input device for Roman and Hindi characters, when the device is in Hindi-writing mode, a basic value of the 17th key(170) is “h”, a basic value of the center key is “u”, a double value of the center key is “uu”, a basic value of the distant center key is “j”, a double value of the distant center key is “z”, and a double value of the distant center key is “−”. Other values shown in the 17th key(170), e.g., “/, 7” are values feasible in numerical calculation mode.

In the character input device for Roman and Hindi characters, when the device is in Hindi-writing mode, a basic value of the 18th key(180) is “s”, a basic value of the center key is “e”, a double value of the center key is “ei”, a successive value of the center key is “eii”, a successive double value of the center key is “ai”, a basic value of the distant center key is “c”, a double value of the distant center key is “y”, and a successive value of the distant center key is “ [symbol] ”. Other values shown in the 18th key(180), e.g., “*, 8” are values feasible in numerical calculation mode.

In the character input device for Roman and Hindi characters, when the device is in Hindi-writing mode, a basic value of the 19th key(190) is “b”, a basic value of the center key is “p”, a double value of the center key is “v”, a successive value of the center key is “ksh”, a basic value of the distant center key is “fi”, and a double value of the distant center key is “_”. Other values shown in the 19th key(190), e.g., “), 9” are values feasible in numerical calculation mode.

In the character input device for Roman and Hindi characters, when the device is in Hindi-writing mode, a basic value of the 20th key(200) is “d”, a basic value of the cen ter key is “D”, a double value of the center key is “w”, and a basic value of the distant center key is “t”, and a double value of the distant center key is “T”. Other values shown in the 20th key(200), e.g., “0, =” are values feasible in numerical calculation mode.

In the character input device for Roman and Hindi characters, “hCAP”, which is a basic value of the 15th key(150), is to change previously generated letters. That is, it changes “kh” of the 11th key(110) into “khi”, and “gh” into “ghi”. Also, it changes “j” of the 17th key(170) into “jh”, changes “s” of the 18th key(180) into “sh”, and “c” into “ch”, changes “b” of the 19th key(190) into “bh”, and “p” into “ph”, and changes “d” of the 20th key(200) into “dh”, “D” into “Dh”, “T” into “Th”, and “t” into “th”.

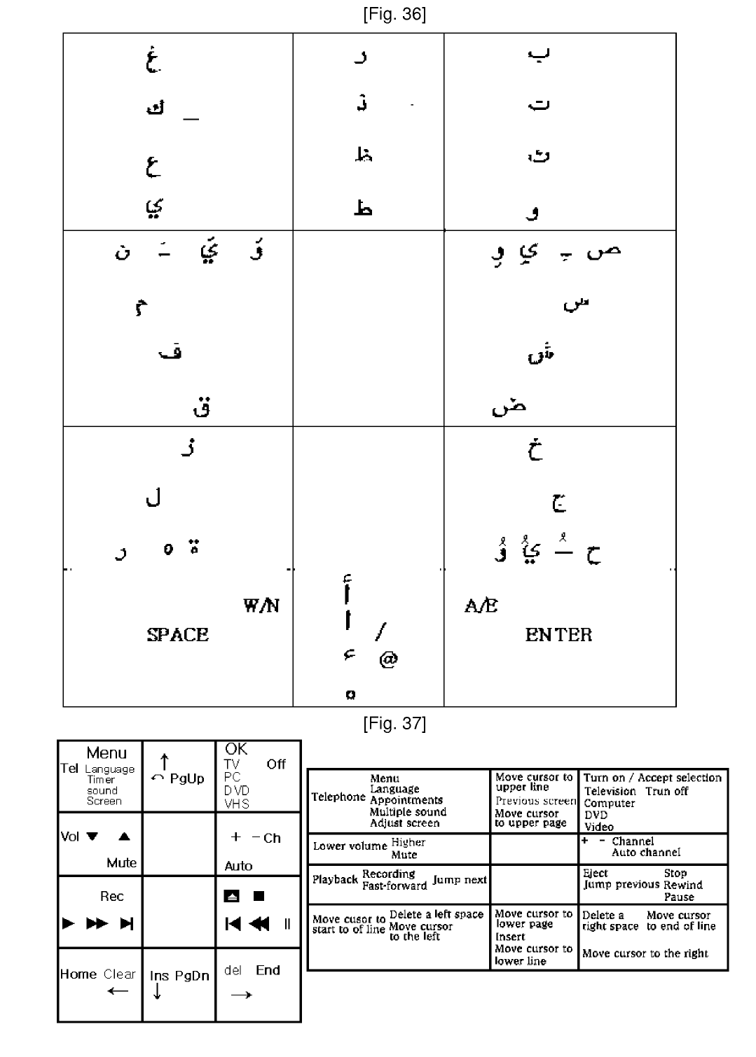

FIG. 36 illustrates a character input device for Arabic according to another embodiment of the present invention. The character input device for Arabic has a 3×4 arrangement as shown in FIG. 3, and consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220).

The 14th key(140) and the 16th key(160) of the character input device for Arabic are similar in construction and input methods to those of the device in FIG. 20, except that “A/E”, a basic value of the center key of the 16th key(160) in the device, is to toggle between Roman-writing mode and Arabic-writing mode.

In the character input device for Arabic, when the device is in Arabic-writing mode, a basic value of the 11th key(110) is “ [symbol] ”, a basic value of the center key is “ [symbol] ”, a double value of the center key is “ [symbol] ”, a successive value of the center key is “ [symbol] ”, and a basic value of the distant center key is “_”.

In the character input device for Arabic, when the device is in Arabic-writing mode, a basic value of the 12th key(120) is “ [symbol] ”, a basic value of the center key is “ [symbol] ”, a double value of the center key is “ [symbol] ”, a successive value of the center key is “ [symbol] ”, a basic value of the distant center key is “ [symbol] ”, a double value of the distant center key is “ [symbol] ”, and a successive value of the distant center key is “ [symbol] ”.

In the character input device for Arabic, when the device is in Arabic-writing mode, a basic value of the 13th key(130) is “ [symbol] ”, a basic value of the center key is “ [symbol] ”, a double value of the center key is “ [symbol] ”, a basic value of the distant center key is “ [symbol] ”, and a double value of the distant center key is “ [symbol] ”.

In the character input device for Arabic, when the device is in Arabic-writing mode, a basic value of the 15th key(150) is “∘” of a sukun symbol with “eu” sound, a basic value of the center key is “ [symbol] ”, a double value of the center key is “ [symbol] ”, a successive value of the center key is “ [symbol] ” combining “ [symbol] ” and “ [symbol] ” together, a basic value of the distant center key is “@”, a double value of the distant center key is “/”, a successive value of the distant center key is “˜”, and a successive double value of the distant center key is “□”.

In the character input device for Arabic, when the device is in Arabic-writing mode, a basic value of the 17th key(170) is “ [symbol] ”, a basic value of the center key is “ [symbol] ”, a double value of the center key is “ [symbol] ”, a successive value of the center key is “ [symbol] ”, a basic value of the distant center key is “ [symbol] ”, and a double value of the distant center key is “ [symbol] ”.

In the character input device for Arabic, when the device is in Arabic-writing mode, a basic value of the 18th key(180) is “ [symbol] ”, a basic value of the center key is “ [symbol] ”, a double value of the center key is “ [symbol] ”, a successive value of the center key is “ [symbol] ”, a basic value of the distant center key is “ [symbol] ”, a double value of the distant center key is “ [symbol] ”, and a successive value of the distant center key is “ [symbol] ”.

In the character input device for Arabic, when the device is in Arabic-writing mode, a basic value of the 19th key(190) is “ [symbol] ”, a basic value of the center key is “ [symbol] ”, a double value of the center key is “ [symbol] ”, and a successive value of the center key is “ [symbol] ”.

In the character input device for Arabic, when the device is in Arabic-writing mode, a basic value of the 20th key(200) is “ [symbol] ”, a basic value of the center key is “ [symbol] ”, a double value of the center key is “ [symbol] ”, a successive value of the center key is “ [symbol] ”, and a basic value of the distant center key is “−”.

In the character input device for Arabic, “ [symbol] ”, fathah marked above the letter corresponding to “a” sound, “ [symbol] ”, kasra marked below the letter corresponding to “i” sound, and “ [symbol] ” of dammah marked above the letter corresponding to “u” sound are vowels in Arabic. Fathah, kasra and dammah can add other marks above hamzah, alif, or other consonants.

Tanwin is indicated by joining two of fathah, kasra and dammah together, and pronounced with a “n” sound. After a vowel is generated, it can be converted into the long sound by pressing “∘” of sukun symbol. However, the sukun symbol can be used only after any consonant. It is characterized in that, after generating a consonant, “ [symbol] ”, i.e., shadda of the double sound, can be generated by further generating the same consonant.

FIG. 37 illustrates a character input device for adjustment according to another embodiment of the present invention. The character input device for adjustment of FIG. 37 has a 3×4 arrangement as shown in FIG. 3, and consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220).

In the character input device for adjustment of FIG. 37, a basic value of the 11th key(110) is “Menu” which is a menu function, a basic value of the center key is “Language” which is a function to toggle between languages, a double value of the center key is “Timer” which is a function to regulate a time, a successive value of the center key is “sound” which is a multiple sound function, a successive double value of the center key is “Screen” which is a function to regulate screen conditions, and a basic value of the distant center key is “Tel” which is a menu function for telephone.

In the character input device for adjustment, a basic value of the 12th key(120) is “vol▾” which is a function to decrease the volume level by one step, a basic value of the center key is “▴” which is a function to increase the volume level by one step, and a basic value of the distant center key is “Mute” which is a mute function.

In the character input device for adjustment, a basic value of the 13th key(130) is [symbol] which is a playback function, a basic value of the center key is [symbol] which is a fast-forward winding function, a double value of the center key is “ [symbol] ” which is a function to jump the cursor to the next section, and a basic value of the distant center key is “Rec” which is a recording function.

In the character input device for adjustment, a basic value of the 14th key(140) is “←” which is a function to move the cursor to the left, a basic value of the center key is “Clear” which is a function to delete a left space, and a basic value of the distant center key is “Home” which is a function to move the cursor to the front of the line on which the cursor is present.

In the character input device for adjustment, a basic value of the 15th key(150) is “↓” which is a function to move the cursor to the lower line, a basic value of the center key is “Ins” which is an inserting function, and a basic value of the distant center key is “PgDn” which is a function to move the cursor to the lower page.

In the character input device for adjustment, a basic value of the 16th key(160) is “→” which is a function to move the cursor to the right, a basic value of the center key is “del” which is a function to delete a right space, and a double value of the center key is “End” which is a function to move the cursor to the end of the line on which the cursor is present.

In the character input device for adjustment, a basic value of the 17th key(170) is “ [symbol] ” which is a function to make a pause, a basic value of the center key is [symbol] of a rewinding function, a double value of the center key is “ [symbol] ” which is a function to jump the cursor to the previous section, a basic value of the distant center key is “▪” which is a stopping function, and a double value of the distant center key is “ [symbol] ” which is an ejecting function.

In the character input device for adjustment, a basic value of the 18th key(180) is “−Ch” which is a function to decrease the channel number by a step, a basic value of the center key is “+” which is a function to increase the channel number by a step, and a basic value of the distant center key is “Auto” which is a function to regulate the channel automatically.

In the character input device for adjustment, a basic value of the 19th key(190) is “OK” which is a function to start a screen and to accept the selected item, a basic value of the center key is “TV” which is a function to switch to television, a double value of the center key is “PC” which is a function to switch to computer, a successive value of the center key is “DVD” which is a function to switch to DVD, a successive double value of the center key is “VHS” which is a function to switch to videotape, and a basic value of the distant center key is “off” which is a function to turn power off.

In the character input device for adjustment, a basic value of the 20th key(200) is “↑” which is a function to move the cursor to the upper line, a basic value of the center key is “ [symbol] ” which is a function to return to the previous screen, and a basic value of the distant center key is “PgUp” which is a function to move the cursor to the upper page.

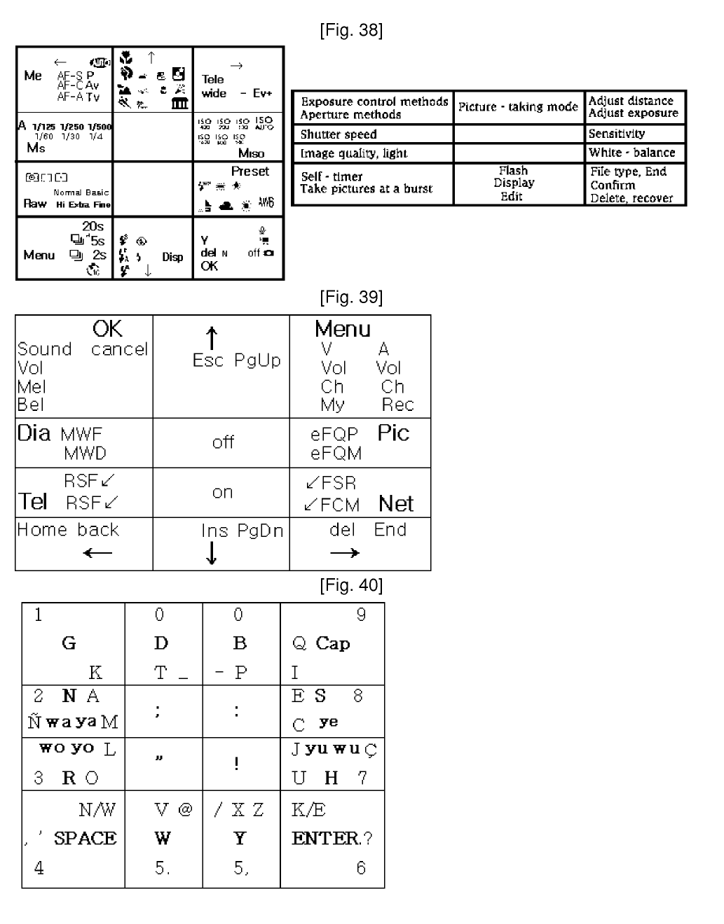

FIG. 38 illustrates a character input device for controlling a camera according to another embodiment of the present invention. The character input device for controlling a camera has a 3×4 arrangement as shown in FIG. 3, and consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220).

In the character input device for controlling a camera, a basic value of the 11th key(110) is “Auto” which is an automatic exposure control method, a basic value of the center key is “P” which is a programmed exposure control method, a double value of the center key is “Av” which is an aperture priority mode, a triple value of the center key is “Tv” which is a shutter speed priority mode, a successive value of the center key is “AF-S” which is an aperture method for static subjects, a successive double value of the center key is “AF-C” which is an aperture method for dynamic subjects, a successive triple value of the center key is “AF-A” which is an aperture method for mixed subjects, a basic value of the distant center key is “Me” which is a manual exposure control method, and a double value of the distant center key is “←” to return to the previous screen or setting. “←” of the 11th key(110) of the character input device for controlling a camera can become a basic value of the 11th key(110) after generating “Menu” of the basic value of the distant center key of the 14th key(140), which has a function to move the cursor to the left when the user sets the menu. On the other hand, it can become a basic value of the 11th key(110) after generating “Disp” of the basic value of the distant center key of the 15th key(150), which has a function to display the previous results to those displayed on the current screen.

In the character input device for controlling a camera, a basic value of the 12th key(120) is “A” which is a function to adjust shutter speed automatically, a basic value of the center key is “ 1/125” to set the shutter speed at 1/125 second, a double value of the center key is “ 1/250” to set the shutter speed at 1/250 second, a triple value of the center key is “ 1/500” to set the shutter speed at 1/500 second, a successive value of the center key is “ 1/60” to set the shutter speed at 1/60 second, a successive double value of the center key is “ 1/30” to set the shutter speed at 1/30 second, a successive triple value of the center key is “¼” to set the shutter speed at ¼ second, and a basic value of the distant center key is “Ms” which is a function to adjust shutter speed manually.

In the character input device for controlling a camera, a basic value of the 13th key(130) is “Raw” which is an image quality function that simultaneously stores the original image, a basic value of the center key is “Hi” which stores at the highest image quality, a double value of the center key is “Extra” which stores at an image quality that is lower than “Raw” and “Hi”, a triple value of the center key is “Fine” which stores at an image quality that is lower than “Extra”, a successive value of the center key is “Normal” which stores at an image quality that is lower than “Fine”, a successive double value of the center key is “Basic” which stores at an image quality that is lower than “Normal”, a basic value of the distant center key is “ [symbol] ” which is a multi-pattern light measuring method, a double value of the distant center key is “ [symbol] ” which is a center-weighted light measuring method, and a triple value of the distant center key is “ [symbol] ” which is a spot light measuring method.

In the character input device for controlling a camera, a basic value of the 14th key(140) is “ [symbol] ” which is a function to set a self-timer to 10 seconds, a basic value of the center key is “2s” which is a function to set a self-timer to 2 seconds, a double value of the center key is “5s” which is a function to set a self-timer to 5 seconds, a triple value of the center key is “20s” which is a function to set a self-timer to 20 seconds, a successive value of the center key is “ [symbol] ” which is a burst function to take pictures at a burst, a successive double value of the center key is “ [symbol] ” which is a rapid burst function, and a basic value of the distant center key is “Menu” which is a menu function for editing.

In the character input device for controlling a camera, a basic value of the 15th key(150) is “ [symbol] ” which is an auto flash function, a basic value of the center key is “ [symbol] ” which is an auto-flash function added to a red-eye reduction function, a double value of the center key is “ [symbol] ” which is a light-emitting function by slow synchro, a successive value of the center key is “ [symbol] ” which is a light-emitting function by forced flash, a successive double value of the center key is “ [symbol] ” which is a function to prevent light-emitting, and a basic value of the distant center key is “Disp” which is a function to display results on a screen. “1” of the 15th key(150) of the character input device for controlling a camera can become a basic value of the 15th key(150) after generating “Menu” of the basic value of the distant center key of the 14th key(140), which has a function to move the cursor down when the user sets the menu.

In the character input device for controlling a camera, a basic value of the 16th key(160) is “OK” which is a function to start a screen and to accept the selected item, a basic value of the center key is “del” which is a deleting function, a double value of the center key is “Y” for a positive selection to delete in answer to the question about whether to delete or not on screen after “del” is generated, a successive value of the center key is “N” for a negative selection not to delete in answer to the question about whether to delete or not on screen after “del” is generated, a basic value of the distant center key is “ [symbol] ” which is a function to store a picture in file type, a double value of the distant center key is “ [symbol] ” which is a function to store movies, a triple value of the distant center key is “ [symbol] ” which is a function to store movies and sounds together, and a successive value of the distant center key is “off” which is a function to turn off the scene.

In the character input device for controlling a camera, a basic value of the 17th key(170) is “AWB” which is a function for automatically adjusting white-balance, a basic value of the center key is “ [symbol] ” which is a daylight function to set a natural white-balance in daylight, a double value of the center key is “ [symbol] ” which is a cloudy function to adjust white-balance appropriately under cloudy condition, a triple value of the center key is “ [symbol] ” which is a shadow function to adjust white-balance appropriately in shadow condition, a successive value of the center key is “ [symbol] ” which is an incandescent function to adjust white-balance appropriately under incandescent lighting condition, a successive double value of the center key is “ [symbol] ” which is a fluorecent function to adjust white-balance appropriately under fluorecent lighting condition, a successive triple value of the center key is “ [symbol] ” which is a flash function to adjust white-balance appropriately when a picture is taken while flash fires, and a basic value of the distant center key is “Preset” which is a function to set white-balance manually.

In the character input device for controlling a camera, a basic value of the 18th key(180) is “ [symbol] ” which is a function to set the sensitivity automatically, a basic value of the center key is “ [symbol] ” which is a function to set the sensitivity at 100, a double value of the center key is “ [symbol] ” which is a function to set the sensitivity at 200, a triple value of the center key is “ [symbol] ” which is a function to set the sensitivity at 400, a successive value of the center key is “ [symbol] ” which is a function to set the sensitivity at 640, a successive double value of the center key is “ [symbol] ” which is a function to set the sensitivity at 800, a successive triple value of the center key is “ [symbol] ” which is a function to set the sensitivity at 1600, and a basic value of the distant center key is “ [symbol] ” which is a function to set the sensitivity manually.

In the character input device for controlling a camera, a basic value of the 19th key(190) is “Tele” which is a function to make a view angle narrow by a step, a basic value of the center key is “Wide” which is a function to make the view angle wider by a step, a basic value of the distant center key is “Ev+” which is a function to increase the exposure compensation by a step, and a successive value of the distant center key is “−” which is a function to decrease the exposure compensation by a step. “→” of the 19th key(190) of the character input device for controlling a camera can become a basic value of the 19th key(190) after generating “Menu” of the basic value of the distant center key of the 14th key(140), which has a function to move the cursor to the right when the user sets the menu. On the other hand, it can become a basic value of the 19th key(190) after generating “Disp” of the basic value of the distant center key of the 15th key(150), which has a function to display the next results that is after the results displayed on the current screen.

In the character input device for controlling a camera, a basic value of the 20th key(200) is “ [symbol] ” which is a picture-taking mode for close range, a basic value of the center key is “ [symbol] ” which is a picture-taking mode for a portrait, a double value of the center key is “ [symbol] ” which is a picture-taking mode for landscape, a triple value of the center key is “ [symbol] ” which is a picture-taking mode for subjects in motion, a successive value of the center key is “ [symbol] ” which is a picture-taking mode for a sunrise, a successive double value of the center key is “ [symbol] ” which is a picture-taking mode for a sunset, a successive triple value of the center key is “ [symbol] ” which is a picture-taking mode for a beach, a basic value of the distant center key is “ [symbol] ” which is a picture-taking mode for portraits at night, a double value of the distant center key is “ [symbol] ” which is a picture-taking mode for a party, a triple value of the distant center key is “ [symbol] ” which is a picture-taking mode for a museum, a successive value of the distant center key is “ [symbol] ” which is a picture-taking mode for landscape at night, a successive double value of the distant center key is “ [symbol] ” which is a picture-taking mode for a snowscape. “↑” of the 20th key(200) of the character input device for controlling a camera can become a basic value of the 20th key(200) after generating “Menu” of the basic value of the distant center key of the 14th key(140), which has a function to move the cursor down when the user sets the menu.

In the character input device for controlling a camera, “←” of the 11th key(110), “↓” of the 15th key(150), “OK” of the 16th key(160), “→” of the 19th key(190) and “↑” of the 20th key(200) become the basic values after “Menu” of the basic value of the distant center key of the 14th key(140) is generated, and after “Disp” of the basic value of the distant center key of the 15th key(150) is generated, and, although the other keys are pressed, their values cannot be generated. When “Menu” of the basic value of the distant center key of the 14th key(140) and “Disp” of the basic value of the distant center key of the 15th key(150) are generated and set, then the respective values are generated once again, the character input device can be returned to the picture-taking mode and thus the respective values of the keys can be generated.

FIG. 39 illustrates a character input device for inherent functions according to another embodiment of the present invention. The character input device for inherent functions has a 3×4 arrangement as shown in FIG. 3, and consists of an 11th key(110), a 12th key(120), a 13th key(130), a 14th key(140), a 15th key(150), a 16th key(160), a 17th key(170), a 18th key(180), a 19th key(190), a 20th key(200), a 1st center key(210), and a 2nd center key(220).

In the character input device for inherent functions, a basic value of the 11th key(110) is “OK” which is a function to accept the set items, a basic value of the center key is “cancel” which is a function to cancel the set items, a basic value of the distant center key is “Sound” to adjust sound, a double value of the distant center key is “Vol” to adjust the volume of melody and ringtone, a successive value of the distant center key is “Mel” to select a melody, and a successive double value of the distant center key is “Bel” to select a ringtone.

In the character input device for inherent functions, a basic value of the 12th key(120) is “Dia” which is a diary menu, a basic value of the center key is “M” which is a function to make a memo, a double value of the center key is “W” which is a function to edit a document and an abbreviation for “Word”, a successive value of the center key is “F” which is a function to find a document, a basic value of the distant center key is “M” which is a schedule list for a month, a double value of the distant center key is “W” which is a schedule list for a week, and a successive value of the distant center key is “D” which is a schedule list of a day.

In the character input device for inherent functions, a basic value of the 13th key(130) is “Tel” which is a menu for the telephone book, a basic value of the center key is “R” which is a menu for received numbers, a double value of the center key is “S” which is a menu for sent numbers, a successive value of the center key is “F” which is a menu function to find numbers, a successive double value of the center key is [symbol] which is a function to register numbers, a basic value of the distant center key is “R” which is a record of received messages, a double value of the distant center key is “S” which is a record of sent messages, a successive value of the distant center key is “F” which is a function to find messages, and a successive double value of the distant center key is [symbol] which is a function to create messages.

In the character input device for inherent functions, a basic value of the 14th key(140) is “←” which is a function to move the cursor to the left, a basic value of the center key is “back” which is a function to delete a left space, and a basic value of the distant center key is “Home” which is a function to move the cursor to the left end of the line.

In the character input device for inherent functions, a basic value of the 15th key(150) is “↓” which is a function to move the cursor down, a basic value of the center key is “Ins” which is a toggling function to toggle between correction and insertion, and a basic value of the distant center key is “PgDn” which is a function to move the cursor to the lower page.

In the character input device for inherent functions, a basic value of the 16th key(160) is “→” which is a function to move the cursor to the right, a basic value of the center key is “del” which is a function to delete a right space, and a double value of the center key is “End” which is a function to move the cursor to the right end of the line.

In the character input device for inherent functions, a basic value of the 17th key(170) is “Net” which is an internet menu, a basic value of the center key is “M” which is a main page of default setting, a double value of the center key is “C” which is for the control board, a successive value of the center key is “F” which is a function to find files and folders, a successive double value of the center key is [symbol] which is a function to write internet addresses, a basic value of the distant center key is “R” which is a menu function for receiving electronic mails, a double value of the distant center key is “S” which is a menu function for sending electronic mails, a successive value of the distant center key is “F” which is a function to find an electronic mail address, a successive double value of the distant center key is [symbol] which is a function to write an electronic mail message.

In the character input device for inherent functions, a basic value of the 18th key(180) is “Pic” which is a menu for video recording, a basic value of the center key is “P” which is a menu for taking photos, a double value of the center key is “Q” to function as an operating button to take a photo, a successive value of the center key is “F” which is a menu for a photo album, a successive double value of the center key is “e” which is a menu for editing photos, a basic value of the distant center key is “M” which is a menu for video recording, a double value of the distant center key is “Q” to function as a operating button for video recording, a successive value of the distant center key is “F” which is a menu for finding a videoclip, a successive double value of the distant center key is “e” which is a menu for editing a videoclip.

In the character input device for inherent functions, a basic value of the 19th key(190) is “Menu” which is a function to display the whole menu, a basic value of the center key is “V” which is a menu of videos, a double value of the center key is “Vol” which is a function to adjust the volume, a successive value of the center key is “Ch” which is a function to select a channel, a successive double value of the center key is “My” which is a function to adjust the environment of my computer, a basic value of the distant center key is “A” which is a menu of audios, a double value of the distant center key is “Vol” which is a function to adjust the volume, a successive value of the distant center key is “Ch” which is a function to select a channel, and a successive double value of the distant center key is “Rec” which is a menu for recording.

In the character input device for inherent functions, a basic value of the 20th key(200) is “↑” which is a function to move the cursor up, a basic value of the center key is “Esc” which is a function to return to the previous screen, and a basic value of the distant center key is “PgUp” which is a function to move the cursor to the upper page.

In the character input device for inherent functions, the 1st center key(210) has the function of switching off when the key is pressed for a long while, and on the other hand, has the function of hanging up the phone during a phone communication.

In the character input device for inherent functions, the 2nd center key(220) has the function of switching on when the key is pressed for a long while. On the other hand, when the key is pressed after inputting a phone number, it starts a call, and, when the key is pressed after inputting a message for sending, it has the function of finding the phone numbers to send the message to.

FIG. 40 illustrates a character input device for Roman character central-4-space type according to another embodiment of the present invention.

The character input device for Roman character central-4-space type has a 4×4 arrangement as shown in FIGS. 4 and 11, and consists of a 41st key(410), a 42nd key(420), a 43rd key(430), a 44th key(440), a 451st key(452), a 452nd key(455), a 46th key(460), a 47th key(470), a 48th key(480), a 49th key(490), a 401st key(502), a 402nd center key(505), a 41st center key(510), a 42nd center key(520), a 43rd center key(530), and a 44th center key(540). Hereinafter, the embodiment will be described with reference to the value 1 of the center key, the value 11 of the center key, the value 3 of the center key, the value 4 of the center key and so on mentioned through FIG. 11.

In the character input device for Roman character central-4-space type of FIG. 40, a basic value of the 41st key(410) is “G”, and a basic value of the center key is “K”. Other value shown in the 41st key(410), e.g., “1” is a value feasible in numerical calculation mode.

In the character input device for Roman character central-4-space type, a basic value of the 42nd key(420) is “N”, a value 1 of the center key is “A”, a value 11 of the center key is “ya”, a value 2 of the center key is “wa”, a value 3 of the center key is “M”, and a value 4 of the center key is “ [symbol] ”. Other value shown in the 42nd key(420), e.g., “2” is a value feasible in numerical calculation mode.

In the character input device for Roman character central-4-space type, a basic value of the 43rd key is “R”, a value 1 of the center key is “L”, a value 3 of the center key is “O”, a value 33 of the center key is “yo”, and a value 4 of the center key is “wo”. Other value shown in the 43rd key(430), e.g., “3” is a value feasible in numerical calculation mode.

In the character input device for Roman character central-4-space type, a basic value of the 44th key(440) is “SPACE” to move a cursor to leave a space, in which a space is left whenever the key is pressed once, a value 3 of the center key is “N/W” to toggle between Roman-writing mode and numerical calculation mode, a value 1 of the center key is “,”, a value 11 of the center key is “;”, a value 13 of the center key is “′”, and a value 133 of the center key is “″”. Other value shown in the 44th key(440), e.g., “4” is a value feasible in numerical calculation mode.

In the character input device for Roman character central-4-space type, a basic value of the 451st key(452) is “W”, a value 3 of the center key is “V”, and a value 4 of the center key is “@”. Other values shown in the 451st key(452), e.g., “5, .” are values feasible in numerical calculation mode.

In the character input device for Roman character central-4 space type, a basic value of the 452nd key(455) is “Y”, a value 4 of the center key is “X”, a value 2 of the center key is “Z”, and a value 3 of the center key is “/”. Other values shown in the 452nd key(455), e.g., “5, .” are values feasible in numerical calculation mode.

In the character input device for Roman character central-4-space type, a basic value of the 46th key(460) is “ENTER” to make a new line, a value 4 of the center key is “K/E” to toggle between Korean-writing mode and Roman-writing mode, a value 2 of the center key is “.”, a value 22 of the center key is “:”, a value 24 of the center key is “?”, and a value 244 of the center key is “!”. Other value shown in the 46th key(460), e.g., “6” is a value feasible in numerical calculation mode.

In the character input device for Roman character central-4-space type, a basic value of the 47th key(470) is “H”, a value 4 of the center key is “U”, a value 44 of the center key is “yu”, a value 3 of the center key is “wu”, a value 2 of the center key is “J”, and a value 1 of the center key is “ [symbol] ”. Other value shown in the 47th key(470), e.g., “7” is a value feasible in numerical calculation mode.

In the character input device for Roman character central-4-space type, a basic value of the 48th key(480) is “S”, a value 2 of the center key is “E”, a value 22 of the center key is “ye”, a value 4 of the center key is “C”, and a value 3 of the center key is “β”. Other value shown in the 48th key(480), e.g., “8” is a value feasible in numerical calculation mode.

In the character input device for Roman character central-4-space type, a basic value of the 49th key(490) is “CAP” to toggle between capital and small letters, a value 2 of the center key is “I”, and a value 4 of the center key is “Q”. Other value shown in the 49th key(490), e.g., “9” is a value feasible in numerical calculation mode.

In the character input device for Roman character central-4-space type, a basic value of the 401st key(502) is “D”, a value 1 of the center key is “T”, and a value 2 of the center key is “_”. Other value shown in the 401st key(502), e.g., “0” is a value feasible in numerical calculation mode.

In the character input device for Roman character central-4-space type, a basic value of the 402nd key(505) is “B”, a value 2 of the center key is “P”, and a value 1 of the center key is “−”. Other value shown in the 402nd key(505), e.g., “0” is a value feasible in numerical calculation mode.

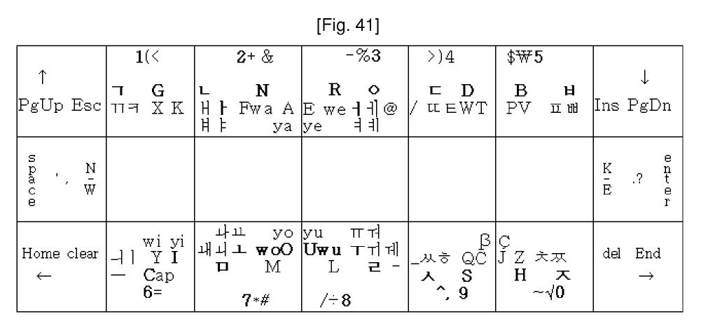

FIG. 41 illustrates a character input device for Korean-Roman central-5-space type according to another embodiment of the present invention.

The character input device for Korean-Roman central-5-space type of FIG. 41 has a 3×7 arrangement as shown in FIGS. 5 and 12, and consists of a 51st key(610), a 52nd key(620), a 53rd key(630), a 54th key(640), a 55th key(650), a 56th key(660), a 57th key(670), a 58th key(680), a 59th key(690), a 60th key(700), a 501st key(710), a 502nd key(720), a 503rd key(730), a 504th key(740), a 505th key(750), a 506th key(760), a 51st center key(810), a 52nd center key(820), a 53rd center key(830), a 54th center key(840) and a 55th center key(850). Hereinafter, the embodiment will be described with reference to the value 1 of the center key, the value 11 of the center key, the value 3 of the center key, the value 4 of the center key and so on mentioned through FIG. 12.

In the character input device for Korean-Roman central-5-space type of FIG. 41, when the device is in Roman-writing mode, a basic value of the 51st key(610) is “G”, a value 1 of the center key is “X”, and a value 2 of the center key is “K”.

In the character input device for Korean-Roman central-5-space type, when the device is in Roman-writing mode, a basic value of the 52nd key(620) is “N”, a value 2 of the center key is “wa”, a value 3 of the center key is “A”, a value 33 of the center key is “ya”, a value 1 of the center key is “F”, and a value 11 of the center key is “ [symbol] ”.

In the character input device for Korean-Roman central-5-space type, when the device is in Roman-writing mode, a basic value of the 53rd key(630) is “R”, a value 3 of the center key is “we”, a value 2 of the center key is “E”, a value 22 of the center key is “ye”, and a value 4 of the center key is “@”.

In the character input device for Korean-Roman central-5-space type, when the device is in Roman-writing mode, a basic value of the 54th key(640) is “D”, a value 4 of the center key is “W”, a value 3 of the center key is “/”, and a value 5 of the center key is “T”.

In the character input device for Korean-Roman central-5-space type, when the device is in Roman-writing mode, a basic value of the 55th key(650) is “B”, a value 5 of the center key is “V”, and a value 4 of the center key is “P”.

In the character input device for Korean-Roman central-5-space type, when the device is in Roman-writing mode, a basic value of the 56th key(660) is “Cap” to toggle between capital and small letters, a value 1 of the center key is “Y”, a value 2 of the center key is “I”, a value 22 of the center key is “yi”, and a value 33 of the center key is “wi”.

In the character input device for Korean-Roman central-5-space type, when the device is in Roman-writing mode, a basic value of the 57th key(670) is “M”, a value 2 of the center key is “wo”, a value 3 of the center key is “0”, and a value 33 of the center key is “yo”.

In the character input device for Korean-Roman central-5-space type, when the device is in Roman-writing mode, a basic value of the 58th key(680) is “L”, a value 3 of the center key is “wu”, a value 2 of the center key is “U”, a value 22 of the center key is “yu”, and a value 4 of the center key is “_”.

In the character input device for Korean-Roman central-5-space type, when the device is in Roman-writing mode, a basic value of the 59th key(690) is “S”, a value 4 of the center key is “Q”, a value 3 of the center key is “−”, a value 5 of the center key is “C”, and a value 54 of the center key is “_”.

In the character input device for Korean-Roman central-5-space type, when the device is in Roman-writing mode, a basic value of the 60th key(700) is “H”, a value 5 of the center key is “Z”, a value 4 of the center key is “J”, and a value 45 of the center key is “ [symbol] ”.

In the character input device for Korean-Roman central-5-space type, when the device is in Roman-writing mode, a basic value of the 501st key(710) is “↑” to move the cursor to the upper line, a value 1 of the center key is “PgUp” to move the cursor to the upper page, and a value 2 of the center key is “Esc” which is a function to cancel.

In the character input device for Korean-Roman central-5-space type, when the device is in Roman-writing mode, a basic value of the 502nd key(720) is “↓” to move the cursor to the lower line, a value 5 of the center key is “PgDn” to move the cursor to the lower page, and a value 4 of the center key is “Ins” which is an inserting function of a cursor.

In the character input device for Korean-Roman central-5-space type, when the device is in Roman-writing mode, a basic value of the 503rd key(730) is “SPACE” to move a cursor to leave a space, a value 1 of the center key is “N/W” to toggle between numerical calculation mode and writing mode, a value 2 of the center key is “,”, a value 22 of the center key is “;”, a value 21 of the center key is “′”, and a value 211 of the center key is “″”.

In the character input device for Korean-Roman central-5-space type, when the device is in Roman-writing mode, a basic value of the 504th key(740) is “enter” to send the cursor to the next line, a value 5 of the center key is “K/E” to toggle between Korean-writing mode and English-writing mode, a value 4 of the center key is “.”, a value 44 of the center key is “:”, a value 45 of the center key is “?”, and a value 455 of the center key is “!”, a value 445 of the center key is “ [symbol] ”, and a value 4455 of the center key is “ [symbol] ”.

In the character input device for Korean-Roman central-5-space type, when the device is in Roman-writing mode, a basic value of the 505th key(750) is “←” to move the cursor to the left, a value 1 of the center key is “Home” to move the cursor to the left end of the line on which the cursor is present, and a value 2 of the center key is “clear” to delete the left space of the cursor.

In the character input device for Korean-Roman central-5-space type, when the device is in Roman-writing mode, a basic value of the 506th key(760) is “→” to move the cursor to the right, a value 5 of the center key is “End” to move the cursor to the right end of the line on which the cursor is present, and a value 4 of the center key is “del” to delete the right space of the cursor.

In the character input device for Korean-Roman central-5-space type, when the device is in Korean-writing mode, a basic value of the 51st key(610) is “□”, a value 1 of the center key is “□”, and a value 2 of the center key is “□”.

In the character input device for Korean-Roman central-5-space type, when the device is in Korean-writing mode, a basic value of the 52nd key(620) is “□”, a value 2 of the center key is “□”, a value 3 of the center key is “□”, a value 33 of the center key is “□”, and a value 32 of the center key is “□”.

In the character input device for Korean-Roman central-5-space type, when the device is in Korean-writing mode, a basic value of the 53rd key(630) is “□”, a value 3 of the center key is “□”, a value 2 of the center key is “□”, a value 22 of the center key is “□”, and a value 23 of the center key is “□”.

In the character input device for Korean-Roman central-5-space type, when the device is in Korean-writing mode, a basic value of the 54th key(640) is “□”, a value 4 of the center key is “□”, a value 5 of the center key is “□”, and a value 3 of the center key is “/”.

In the character input device for Korean-Roman central-5-space type, when the device is in Korean-writing mode, a basic value of the 55th key(650) is “□”, a value 5 of the center key is “□”, and a value 4 of the center key is “□”.

In the character input device for Korean-Roman central-5-space type, when the device is in Korean-writing mode, a basic value of the 56th key(660) is “□”, a value 1 of the center key is “□”, and a value 2 of the center key is “□”.

In the character input device for Korean-Roman central-5-space type, when the device is in Korean-writing mode, a basic value of the 57th key(670) is “□”, a value 2 of the center key is “□”, a value 3 of the center key is “□”, a value 33 of the center key is “□”, a value 32 of the center key is “□”, and a value 23 of the center key is “□”.

In the character input device for Korean-Roman central-5-space type, when the device is in Korean-writing mode, a basic value of the 58th key(680) is “□”, a value 3 of the center key is “□”, a value 2 of the center key is “□”, a value 22 of the center key is “□”, a value 23 of the center key is “□”, a value 32 of the center key is “□”, and a value 4 of the center key is “_{—”.}

In the character input device for Korean-Roman central-5-space type, when the device is in Korean-writing mode, a basic value of the 59th key(690) is “□”, a value 4 of the center key is “□”, a value 3 of the center key is “−”, and a value 5 of the center key is “□”

In the character input device for Korean-Roman central-5-space type, when the device is in Korean-writing mode, a basic value of the 60th key(700) is “□”, a value 5 of the center key is “□”, and a value 4 of the center key is “□”.

In the character input device for Korean-Roman central-5-space type, when the device is in Korean-writing mode, the method for inputting the input values of the keys, e.g., the 501st key(710), the 502nd key(720), the 503rd key(730), the 504th key(740), the 505th key(750), the 506th key(760), is similar to that in English-writing mode.

In the character input device for Korean-Roman central-5-space type, when the device is in numerical calculation mode, a basic value of the 51st key(610) is “1”, a value 1 of the center key is “(”, and a value 2 of the center key is “<”.

In the character input device for Korean-Roman central-5-space type, when the device is in numerical calculation mode, a basic value of the 52nd key(620) is “2”, a value 2 of the center key is “+”, and a value 3 of the center key is “&”.

In the character input device for Korean-Roman central-5-space type, when the device is in numerical calculation mode, a basic value of the 53rd key(630) is “3”, a value 3 of the center key is “−”, and a value 2 of the center key is “%”.

In the character input device for Korean-Roman central-5-space type, when the device is in numerical calculation mode, a basic value of the 54th key(640) is “4”, a value 4 of the center key is “)”, and a value 3 of the center key is “>”.

In the character input device for Korean-Roman central-5-space type, when the device is in numerical calculation mode, a basic value of the 55th key(650) is “5”, a value 5 of the center key is “□”, and a value 4 of the center key is “$”.

In the character input device for Korean-Roman central-5-space type, when the device is in numerical calculation mode, a basic value of the 56th key(660) is “6”, and a value 1 of the center key is “=”.

In the character input device for Korean-Roman central-5-space type, when the device is in numerical calculation mode, a basic value of the 57th key(670) is “7”, a value 2 of the center key is “*”, and a value 3 of the center key is “#”.

In the character input device for Korean-Roman central-5-space type, when the device is in numerical calculation mode, a basic value of the 58th key(680) is “8”, a value 3 of the center key is “/”, and a value 2 of the center key is “÷”.

In the character input device for Korean-Roman central-5-space type, when the device is in numerical calculation mode, a basic value of the 59th key(690) is “9”, a value 4 of the center key is “,”, and a value 5 of the center key is “̂”.

In the character input device for Korean-Roman central-5-space type, when the device is in numerical calculation mode, a basic value of the 60th key(700) is “0”, a value 5 of the center key is “√”, and a value 4 of the center key is “˜”.

The present invention is not limited to the above-mentioned disclosure and the drawings. Instead, it will be apparent to those of skill in the art that variations or other uses may be applied to the devices and methods of the invention described herein within the scope of the following claims.

### INDUSTRIAL APPLICABILITY

The present invention relates to a character input device and method having a plurality of center keys and a plurality of space keys, which is easy to handle so that it is possible to input characters more rapidly while using fewer keys. In case that the device may be applied to portable electronic devices, for example cellular phones, PNPs(Plug and Play) or PMPs(Portable Multimedia Player), the characters can be generated in the device with less movement of the user's fingers, and thus the device can be manipulated at higher speed. Moreover, fewer keys are used so that the keys can become larger relatively in size, which is good for miniaturization of portable electric devices.

It should be noted that the invention can be applied to character input devices and methods for various languages, e.g., English, German, French, Japanese, Hindi, Vietnamese, Russian and so on as well as Korean.

1. A character-input method for a character board having a center key located at its central part and a plurality of peripheral keys located at a peripheral part of the center key, comprising a basic value of a basic key generated by pressing the peripheral key one time, a double-value of the basic key generated by pressing the peripheral key two times, a basic value of a center key generated by pressing the center key one time after pressing the peripheral key, and a double-value of the center key generated by pressing the center key two times after pressing the peripheral key.

2. The method of claim 1, further comprising a triple-value of the center key generated by pressing the center key three times after pressing the peripheral key.

3. The method of claim 1, further comprising a triple-value of the basic key generated by pressing the peripheral key three times.

4. The method of claim 1, further comprising a distant center key located around the center key so that both a distant center key and the center key are surrounded by the peripheral keys.

5. The method of claim 4, further comprising a successive value of the center key generated by pressing the peripheral key, the center key and the distant center key in order, a successive double value of the center key generated by pressing the distant center key two times after pressing the peripheral key and the center key in order, a successive triple value of the center key generated by pressing the distant center key three times after pressing the peripheral key and the center key in order.

6. The method of claim 4, further comprising a double-successive value of the center key generated by pressing the center key two times and the distant center key one time in order after pressing the peripheral key, and a double-successive double value of the center key generated by pressing the center key two times and the distant center key two times in order after pressing the peripheral key.

7. The method of claim 4, further comprising a basic value of a distant center key generated by pressing the distant center key one time after pressing the peripheral key, and a double-value of the distant center key generated by pressing the distant center key two times after pressing the peripheral key, and a successive value of the distant center key generated by pressing the peripheral key, the distant center key and the center key in order.

8. The method of claim 7, further comprising a successive double value of the distant center key generated by pressing the center key two times after pressing the peripheral key and the distant center key in order, a successive triple value of the distant center key generated by pressing the center key three times after pressing the peripheral key and the distant center key in order, a triple-value of the distant center key generated by pressing the distant center key three times after pressing the peripheral key, a double-successive value of the distant center key generated by pressing the center key one time after pressing the peripheral key and the distant center key two times in order, and a double-successive double value of the distant center key generated by pressing the center key two times after pressing the peripheral key and the distant center key two times in order.

9. The method of claim 1, wherein the center key comprises a 1st center key, a 2nd center key, a 3rd center key, and a 4th center key.

10. The method of claim 9, further comprising a value 1 of the center key generated by pressing the peripheral key and the 1st center key in order; a value 2 of the center key generated by pressing the peripheral key and the 2nd center key in order; a value 3 of the center key generated by pressing the peripheral key and the 3rd center key in order; and a value 4 of the center key generated by pressing the peripheral key and the 4th center key in order.

11. The method of claim 10, further comprising a value 11 of the center key generated by pressing the peripheral key, and the 1st center key two times in order; a value 12 of the center key generated by pressing the peripheral key, the 1st center key, and the 2nd center key in order; a value 123 of the center key generated by pressing the peripheral key, the 1st center key, the 2nd center key, and 3rd center key in order; a value 1234 of the center key generated by pressing the peripheral key, the 1st center key, the 2nd center key, the 3rd center key, and the 4th center key in order; a value 13 of the center key generated by pressing the peripheral key, the 1st center key, and the 3rd center key in order; a value 133 of the center key generated by pressing the peripheral key, the 1st center key, and the 3rd center key two times in order; a value 22 of the center key generated by pressing the peripheral key and the 2nd center key two times in order; a value 24 of the center key generated by pressing the peripheral key, the 2nd center key, and the 4th center key in order; a value 244 of the center key generated by pressing the peripheral key, the 2nd center key, and the 4th center key two times in order; and a value 44 of the center key generated by pressing the peripheral key and the 4th center key two times in order.

12. The method of claim 11, further comprising a value 21 of the center key generated by pressing the peripheral key, the 2nd center key and the 1st center key in order; a value 211 of the center key generated by pressing the peripheral key, the 2nd center key, and the 1st center key two times in order.

13. The method of claim 11 or claim 12, wherein the center key further comprises a 5th center key.

14. The method of claim 13, further comprising a value 5 of the center key generated by pressing the peripheral key and the 5th center key in order; a value 12345 of the center key generated by pressing the peripheral key, the 1st center key, the 2nd center key, the 3rd center key, the 4th center key, and the 5th center key in order; a value 23 of the center key generated by pressing the peripheral key, the 2nd center key, and 3rd center key in order; a value 32 of the center key generated by pressing the peripheral key, the 3rd center key, and the 2nd center key in order; a value 33 of the center key generated by pressing the peripheral key, and the 3rd center key two times in order; a value 45 of the center key generated by pressing the peripheral key, the 4th center key, and the 5th center key in order; a value 445 of the center key generated by pressing the peripheral key, the 4th center key two times and the 5th center key in order; a value 455 of the center key generated by pressing the peripheral key, the 4th center key, and the 5th center key two times in order; a value 4455 of the center key generated by pressing the peripheral key, the 4th center key two times and the 5th center key two times in order; and a value 54 of the center key generated by pressing the peripheral key, the 5th center key and the 4th center key in order.

15. The method of claim 1, further comprising a space key located at a central part of four keys wherein the four keys consist of two upper keys and two lower keys and the space key adjoins all of the four keys.

16. The method of claim 15, wherein exciting the space key after exciting one of two keys located on a diagonal line with respect to the space key reaches the same result as exciting the excited key and the other key located on the diagonal line in order.

17. The method of claim 1, wherein the character board consists of a 3×3 arrangement, which comprises a 1st key located on 1st row and 1st column of the arrangement, a 2nd key located on 1st row and 2nd column of the arrangement, a 3rd key located on 1st row and 3rd column of the arrangement, a 4th key located on 2nd row and 1st column of the arrangement, a 5th key as the center key located on 2nd row and 2nd column, a 6th key located on 2nd row and 3rd column of the arrangement, a 7th key located on 3rd row and 1st column of the arrangement, a 8th key located on 3rd row and 2nd column of the arrangement, and a 9th key located on 3rd row and 3rd column of the arrangement.

18. The method of claim 17, wherein, in case of the 2nd key, a basic value of the basic key is “↓” to move a cursor down, and a basic value of the center key is “PgDn” to move the cursor to the bottom of the page on which the cursor is present,
in case of the 4th key, a basic value of the basic key is “→” to move the cursor to the right, and a basic value of the center key is “End” to move the cursor to the end of the line on which the cursor is present,
in case of the 6th key, a basic value of the basic key is “←” to move the cursor to the left, and a basic value of the center key is “Home” to move the cursor to the front of the line on which the cursor is present, and
in case of the 8th key, a basic value of the basic key is “↑” to move the cursor up, and a basic value of the center key is “PgUp” to move the cursor to the top of the page on which the cursor is present.

19. The method of claim 17, wherein, in case of the 2nd key, a basic value of the basic key is “▪” to function as a stop of a record player, and a basic value of the center key is “ [symbol] ” to eject a playback medium from the player to its outside,
in case of the 4th key, a basic value of the basic key is [symbol] to play the record player, a basic value of the center key is [symbol] to perform a fast-forward winding operation, a double value of the center key is “ [symbol] ” to jump to the next section,
in case of the 6th key, a basic value of the basic key is “ [symbol] ” to make a pause, a basic value of the center key is [symbol] to perform a rewinding, a double value of the center key is “ [symbol] ” to jump to the previous section, and
in case of the 8th key, a basic value of the basic key is “” to perform a recording operation.

20. The method of claim 1 or claim 17, wherein the method is applied to a character board for cursor movement or a character board for a record player.

21. The method of claim 17, wherein the 4th key consists of a 4ath key and 4bth key, the 4ath key is located at an upper part in the 4th key, the 4bth key is located below the 4ath key, and wherein the 6th key consists of a 6ath key and 6bth key, the 6ath key is located at an upper part in the 6th key, and the 6bth key is located below the 6ath key.

22. The method of claim 21, wherein, the method is implemented in numerical calculation mode, and wherein
in case of the 1st key, a basic value of the basic key is “1”, and a basic value of
the center key is “(”,
in case of the 2nd key, a basic value of the basic key is “0”, a basic value of the center key is “=” to display a value resulting from a desired calculation, and a double value of the center key is “AC” to delete all values to start any calculation,
in case of the 3rd key, a basic value of the basic key is “9” and a basic value of the center key is “)”,
in case of the 4ath key, a basic value of the basic key is “2” and a basic value of the center key is “+”,
in case of the 4bth key, a basic value of the basic key is “3” and a basic value of the center key is “−”,
in case of the 5th key, a basic value of the basic key is “on” to power on, in case of the 6ath key, a basic value of the basic key is “8” and a basic value of the center key is “*”,
in case of the 6bth key, a basic value of the basic key is “7” and a basic value of the center key is “/”,
in case of the 7th key, a basic value of the basic key is “4” and a basic value of the center key is “off” to power off,
in case of the 8th key, a basic value of the basic key is “5” and a basic value of the center key is “.”, and
in case of the 9th key, a basic value of the basic key is “6”, and a basic value of the center key is “ [symbol] ” with a function to delete a previous character.

23. The method of claim 21, implemented in numerical calculation/clock mode of the character input device, wherein
in case of the 1st key, a basic value of the basic key is “1”, and a basic value of the center key is “Day” as a mode for setting a date,
in case of the 2nd key, a basic value of the basic key is “0”, a basic value of the center key is “OK” to accept the inputted value, and a double value of the center key is “AC” to delete setting values to start any new input operation,
in case of the 3rd key, a basic value of the basic key is “9” and a basic value of the center key is “Time” to display a time,
in case of the 4ath key, a basic value of the basic key is “2” and a basic value of the center key is [symbol] to start a stopwatch, a double value of the center key is “▪” to stop a stopwatch,
in case of the 4bth key, a basic value of the basic key is “3” and a basic value of the center key is “C.D” as a mode for setting a countdown-time and a double value of the center key is “off” to cancel the setting of countdown-time,
in case of the 5th key, a basic value of the basic key is “on” to turn power on,
in case of the 6ath key, a basic value of the basic key is “8” and a basic value of the center key is “▴” to raise a volume,
in case of the 6bth key, a basic value of the basic key is “7” and a basic value of the center key is “▾” to lower the volume,
in case of the 7th key, a basic value of the basic key is “4” and a basic value of the center key is “N/W” to toggle between the numerical calculation mode and the clock mode,
in case of the 8th key, a basic value of the basic key is “5”, a basic value of the center key is “alarm” as a mode for setting an alarm time and a double value of the center key is “off” to cancel the alarm-time setting,
in case of the 9th key, a basic value of the basic key is “6”, and a basic value of the center key is “ [symbol] ” to return to the previous input state.

24. The method of one of claim 1 to claim 8, wherein, the device consists of a 3×4 arrangement, which comprises
an 11th key located on 1st row and 1st column of the arrangement;
a 12th key located on 2nd row and 1st column of the arrangement;
a 13th key located on 3rd row and 1st column of the arrangement;
a 14th key located on 4th row and 1st column of the arrangement;
a 15th key located on 4th row and 2nd column of the arrangement;
a 16th key located on 4th row and 3rd column of the arrangement;
a 17th key located on 3rd row and 3rd column of the arrangement;
an 18th key located on 2nd row and 3rd column of the arrangement;
a 19th key located on 1st row and 3rd column of the arrangement;
a 20th key located on 1st row and 2nd column of the arrangement;
a 1st center key located on 2nd row and 2nd column of the arrangement; and
a 2nd center key located on 3rd row and 2nd column of the arrangement.

25. The method of claim 24, performed by the character input device for numerical calculation, wherein
in case of the 11th key, a basic value of the basic key is “1”, a basic value of the center key is “(”, and a basic value of the distant center key is “<”,
in case of the 12th key, a basic value of the basic key is “2”, a basic value of the center key is “+”, and a basic value of the distant center key is “&”,
in case of the 13th key, a basic value of the basic key is “3”, a basic value of the center key is “−”, and a basic value of the distant center key is “%”,
in case of the 14th key, a basic value of the basic key is “4” and a basic value of the center key is “W/N” to toggle between language-writing mode and numerical calculation mode, and a basic value of the distant center key is “Space” to leave a space,
in case of the 15th key, a basic value of the basic key is “5”, a basic value of the center key is “.”, a basic value of the distant center key is “,”, and a double value of the distant center key is “$”,
in case of the 16th key, a basic value of the basic key is “6”, a basic value of the center key is “K/E” to toggle between each language mode and an English mode, and a basic value of the distant center key is “Enter”,
in case of the 17th key, a basic value of the basic key is “7”, a basic value of the center key is “/”, and a basic value of the distant center key is “÷”,
in case of the 18th key, a basic value of the basic key is “8”, a basic value of the center key is “*”, and a basic value of the distant center key is “#”,
in case of the 19th key, a basic value of the basic key is “9”, a basic value of the center key is “)”, and a basic value of the distant center key is “>”, and
in case of the 20th key, a basic value of the basic key is “0”, a basic value of the center key is “=”, and a basic value of the distant center key is “̂”.

26. The method of claim 24, performed by the character input device for Korean, wherein
in case of the 11th key, a basic value of the basic key is “□”, a basic value of the center key is “□”, and a double value of the center key is “□”,
in case of the 12th key, a basic value of the basic key is “□”, a basic value of the center key is “□”, a double value of the center key is “□”, a successive value of the center key is “□”, a successive double value of the center key is “□”, and a basic value of the distant center key is “□”,
in case of the 13th key, a basic value of the basic key is “□”, a basic value of the center key is “□”, a double value of the center key is “□”, a successive value of the center key is “□”, a successive double value of the center key is “□”, and a basic value of the distant center key is “□”,
in case of the 14th key, a basic value of the basic key is “Space”, a basic value of the center key is “W/N”, a basic value of the distant center key is “,”, a double value of the distant center key is “;”, a successive value of the distant center key is “′”, and a successive double value of the distant center key is “″”,
in case of the 15th key, a basic value of the basic key is “□”, a double value of the basic key is “□”, a basic value of the center key is “□”, a basic value of the distant center key is “@”, a double value of the distant center key is “/”, a successive value of the distant center key is “˜”, and a successive double value of the distant center key is “□”,
in case of the 16th key, a basic value of the basic key is “ENTER”, a basic value of the center key is “K/E”, a basic value of the distant center key is “.”, a double value of the distant center key is “:”, a successive value of the distant center key is “?”, and a successive double value of the distant center key is “!”,
in case of the 17th key, a basic value of the basic key is “□”, a basic value of the center key is “□”, a double value of the center key is “□”, a successive value of the center key is “□”, a successive double value of the center key is “□”, a basic value of the distant center key is “□”, and a double value of the distant center key is “□”,
in case of the 18th key, a basic value of the basic key is “□”, a basic value of the center key is “□”, a double value of the center key is “□”, a successive value of the center key is “□”, a successive double value of the center key is “□”, a basic value of the distant center key is “□”, and a double value of the distant center key is “□”,
in case of the 19th key, a basic value of the basic key is “□”, a basic value of the center key is “□”, and a double value of the center key is “□”, and
in case of the 20th key, a basic value of the basic key is “□”, a basic value of the center key is “□”, and a double value of the center key is “□”.

27. The method of claim 24, performed by the character input device for Roman characters, wherein
in case of the 11th key, a basic value of the basic key is “G”, a basic value of the center key is “K”, and a double value of the center key is “X”, and a basic value of the distant center key is “_”,
in case of the 12th key, a basic value of the basic key is “N”, a basic value of the center key is “a”, a double value of the center key is “ya”, a successive value of the center key is “wa”, a triple value of the center key is “ay”, a successive double value of the center key is “aw”, a basic value of the distant center key is “M”, and a double value of the distant center key is “ [symbol] ”,
in case of the 13th key, a basic value of the basic key is “R”, a basic value of the center key is “o”, a double value of the center key is “yo”, a successive value of the center key is “wo”, a triple value of the center key is “oy”, a successive double value of the center key is “ow”, a basic value of the distant center key is “L”, and a double value of the distant center key is “Q”,
in case of the 14th key, a basic value of the basic key is “Space”, a basic value of the center key is “W/N”, a basic value of the distant center key is “,”, a double value of the distant center key is “;”, a successive value of the distant center key is “′”, and a successive double value of the distant center key is “″”,
in case of the 15th key, a basic value of the basic key is “CAP”, a basic value of the center key is “I”, a double value of the center key is “yi”, a successive value of the center key is “wi”, a triple value of the center key is “iy”, a successive double value of the center key is “iw”, a basic value of the distant center key is “@”, a double value of the distant center key is “/”, a successive value of the distant center key is “□”, and a successive double value of the distant center key is “˜”,
in case of the 16th key, a basic value of the basic key is “ENTER”, a basic value of the center key is “K/E”, a basic value of the distant center key is “.”, a double value of the distant center key is “:”, a successive value of the distant center key is “?”, a successive double value of the distant center key is “!”, a double successive value of the distant center key is “ [symbol] ”, and a double successive double value of the distant center key is “ [symbol] ”.
in case of the 17th key, a basic value of the basic key is “H”, a basic value of the center key is “u”, a double value of the center key is “yu”, a successive value of the center key is “wu”, a triple value of the center key is “uy”, a successive double value of the center key is “uw”, a basic value of the distant center key is “J”, a double value of the distant center key is “Z”, and a successive value of the distant center key is “ [symbol] ”,
in case of the 18th key, a basic value of the basic key is “S”, a basic value of the center key is “e”, a double value of the center key is “ye”, a successive value of the center key is “we”, a triple value of the center key is “ey”, a successive double value of the center key is “ew”, a basic value of the distant center key is “C”, a double value of the distant center key is “Y”, and a successive value of the distant center key is “β”,
in case of the 19th key, a basic value of the basic key is “B”, a basic value of the center key is “P”, a double value of the center key is “V”, and a basic value of the distant center key is “F”, and
in case of the 20th key, a basic value of the basic key is “D”, a basic value of the center key is “T”, a double value of the center key is “W”, a successive value of the center key is “WH”, and a basic value of the distant center key is “−”.

28. The method of claim 24, performed by the character input device for integrated Korean and Roman characters, wherein
in case of the 11th key, a basic value of the basic key is “1”, a basic value of the center key is “(”, a double value of the center key is “<”, and a basic value of the distant center key is “Day” of a mode for setting a date,
in case of the 12th key, a basic value of the basic key is “2”, a basic value of the center key is “+”, a double value of the center key is “&”, a basic value of the distant center key is [symbol] to start a stopwatch, and a double value of the distant center key is “▪” to stop a stopwatch,
in case of the 13th key, a basic value of the basic key is “3”, a basic value of the center key is “−”, a double value of the center key is “%”, a basic value of the distant center key is “C.D” as a mode for setting a countdown-time, and a double value of the distant center key is “off” to cancel the setting of countdown-time,
in case of the 14th key, a basic value of the basic key is “4” and a basic value of the center key is “W/N” to toggle between language-writing mode and numerical calculation mode, and a basic value of the distant center key is “Space” to leave a space,
in case of the 15th key, a basic value of the basic key is “5”, a basic value of the center key is “.”, a double value of the center key is “,”, a basic value of the distant center key is “alarm” of a mode for setting an alarm time, and a double value of the distant center key is “off” to cancel the alarm-time setting,
in case of the 16th key, a basic value of the basic key is “6”, a basic value of the center key is “□” to indicate the won currency, a double value of the center key is “$” to indicate dollar, and a basic value of the distant center key is “Enter”,
in case of the 17th key, a basic value of the basic key is “7”, a basic value of the center key is “/”, a double value of the center key is “÷”, and a basic value of the distant center key is “▾” to decrease the volume,
in case of the 18th key, a basic value of the basic key is “8”, a basic value of the center key is “*”, a double value of the center key is “#”, and a basic value of the distant center key is “▴” to increase the volume,
in case of the 19th key, a basic value of the basic key is “9”, a basic value of the center key is “)”, a double value of the center key is “>”, and a basic value of the distant center key is “Time” to display a time, and
in case of the 20th key, a basic value of the basic key is “0”, a basic value of the center key is “=”, a double value of the center key is “̂”, a basic value of the distant center key is “OK” to accept the inputted value for settings, and a double value of the distant center key is “AC” to delete all set values to start any new inputting.

29. The method of claim 24, wherein, the character input device is adapted for numerical calculation, or for Korean characters, or for Roman characters.

30. The method of one of claim 1 to claim 8, wherein, the device consists of a 1st character input device having a 3×3 arrangement and a 2nd character input device having a 3×4 arrangement;
wherein the 1st character input device comprises a 1st key located on 1st row and 1st column of the 3×3 arrangement, a 2nd key located on 1st row and 2nd column, a 3rd key located on 1st row and 3rd column, a 4th key located on 2nd row and 1st column, a 5th key located on 2nd row and 2nd column, a 6th key located on 2nd row and 3rd column, a 7th key located on 3rd row and 1st column, a 8th key located on 3rd row and 2nd column, a 9th key located on 3rd row and 3rd column; and
wherein the 2nd character input device comprises an 11th key located on 1st row and 1st column of the 3×4 arrangement, a 12th key located on 2nd row and 1st column, a 13th key located on 3rd row and 1st column, a 14th key located on 4th row and 1st column, a 15th key located on 4th row and 2nd column, a 16th key located on 4th row and 3rd column, a 17th key located on 3rd row and 3rd column, an 18th key located on 2nd row and 3rd column, a 19th key located on 1st row and 3rd column, a 20th key located on 1st row and 2nd column, a 1st center key located on 2nd row and 2nd column, and a 2nd center key located on 3rd row and 2nd column.

31. The method of claim 30, wherein, the character input device comprises the 1st character input device which is for vowels and the 2nd character input device which is for consonants.

32. The method of claim 31, performed by the character input device for Korean, wherein the 1st character input device is provided with
the 2nd key, in which a basic value of the basic key is “□”, a double value of the basic key is “□”, and a basic value of the center key is “□”,
the 4th key, in which a basic value of the basic key is “□”, a double value of the basic key is “□”, a basic value of the center key is “□”, and a double value of the center key is “□”,
the 5th key, in which a basic value of the basic key is “□”, a double value of the basic key is “□”, and a triple value of the basic key is “□”,
the 6th key, in which a basic value of the basic key is “□”, a double value of the basic key is “□”, a basic value of the center key is “□”, and a double value of the center key is “□”, and
the 8th key, in which a basic value of the basic key is “□”, a double value of the basic key is “□”, and a basic value of the center key is “□”,
and wherein
“□” is generated by pressing the 8th key and 4th key in order, and “□” is generated by then pressing the 5th key in succession, and
“□” is generated by pressing the 2nd key and 6th key in order, and “□” is generated by then pressing the 5th key in succession.

33. The method of claim 32, performed by the character input device for Korean characters, wherein the 2nd character input device is provided with
the 11th key, in which a basic value of the basic key is “□”, and a basic value of the center key is “□”,
the 12th key, in which a basic value of the basic key is “□”, a basic value of the center key is “□”, and a double value of the center key is “□”,
the 13th key, in which a basic value of the basic key is “□”, a basic value of the center key is “□”, and a double value of the center key is “□”,
the 15th key, in which a basic value of the basic key is “□”, a basic value of the center key is “□”, a basic value of the distant center key is “@”, and a double value of the distant center key is “/”,
the 17th key, in which a basic value of the basic key is “□”, a double value of the basic key is “□”, and a basic value of the distant center key is “□”,
the 18th key, in which a basic value of the basic key is “□”, a basic value of the center key is “□”, and a basic value of the distant center key is “□”,
the 19th key, in which a basic value of the basic key is “□”, and a basic value of the center key is “□”, and
the 20th key, in which a basic value of the basic key is “□”, and a basic value of the center key is “□”.

34. The method of claim 31, performed by the character input device for Korean characters, wherein, in the 1st character input device, basic values of the basic keys are indicated with “□”, “□”, “□”, “□” and “□” among vowels and the other vowels are indicated using double values of the basic keys, basic values of the center keys, and double values of the center keys, and wherein, in the 2nd character input device, basic values of the basic keys are indicated with “□”, “□”, “□”, “□”, “□”, “□”, “□”, “□” and “□” among consonants and the other consonants are indicated using basic values of the center keys, double values of the center keys, and basic values of the distant center keys.

35. The method of claim 31, performed by the character input device of a separated type for Roman characters, wherein, the 1st character input device is provided with
a basic value of the basic key of the 2nd key which is “U”,
a basic value of the basic key of the 4th key which is “A”,
a basic value of the basic key of the 5th key which is “I”,
a basic value of the basic key of the 6th key which is “E”, and
a basic value of the basic key of the 8th key which is “O”.

36. The method of claim 35, performed by the character input device of the separated type for Roman characters, wherein the 2nd character input device is provided with
the 12th key, in which a basic value of the basic key is “N”, a basic value of the center key is “M”, a basic value of the distant center key is “W”, and a successive value of the distant center key is “ [symbol] ”,
the 13th key, in which a basic value of the basic key is “R”, a basic value of the center key is “L”, and a basic value of the distant center key is “Q”, the 15th key, in which a basic value of the basic key is “CAP”, a basic value of the center key is “@”, a double value of the center key is “/”, and a successive value of the center key is “□”,
the 17th key, in which a basic value of the basic key is “H”, a basic value of the center key is “J”, a basic value of the distant center key is “Z”, and a successive value of the distant center key is “ [symbol] ”, and
the 18th key, in which a basic value of the basic key is “S”, a basic value of the center key is “C”, a basic value of the distant center key is “Y”, and a successive value of the distant center key is “β”.

37. The method of claim 31, performed by the character input device of the separated type for Roman characters, wherein, in the 1st character input device, basic values of the basic keys are indicated with “U”, “A”, “I”, “E” and “O” and wherein, in the 2nd character input device, basic values of the basic keys are indicated with “N”, “R”, “H”, “S”, “G”, “B” and “D” among consonants and the other alphabets are indicated using basic values of the center keys, double values of the center keys, successive values of the center keys, basic values of the distant center keys, and successive values of the distant center keys.

38. The method of claim 24, performed by the character input device for Japanese, wherein
in case of the 11th key, a basic value of the basic key is [symbol] , a basic value of the center key is [symbol] , a double value of the center key is [symbol] , a triple value of the center key is [symbol] , a successive value of the center key is [symbol] , and a successive double value of the center key is [symbol] ,
in case of the 12th key, a basic value of the basic key is [symbol] , a basic value of the center key is [symbol] , a double value of the center key is [symbol] , a triple value of the center key is [symbol] , a successive value of the center key is [symbol] , a successive double value of the center key is [symbol] , a basic value of the distant center key is [symbol] , a double value of the distant center key is [symbol] , a triple value of the distant center key is [symbol] , a successive value of the distant center key is [symbol] , and a successive double value of the distant center key is [symbol] ,
in case of the 13th key, a basic value of the basic key is [symbol] , a basic value of the center key is [symbol] , a double value of the center key is [symbol] a triple value of the center key is [symbol] , a successive value of the center key is [symbol] , a successive double value of the center key is [symbol] , a basic value of the distant center key is [symbol] , a double value of the distant center key is [symbol] , a triple value of the distant center key is [symbol] , a successive value of the distant center key is [symbol] , a successive double value of the distant center key is [symbol] ,
in case of the 14th key, a basic value of the basic key is “SPACE”, a basic value of the center key is “W/N”, a basic value of the distant center key is “,”, a double value of the distant center key is “;”, a successive value of the distant center key is “′”, and a successive double value of the distant center key is “″”,
in case of the 15th key, a basic value of the basic key is [symbol] to toggle between hiragana and katakana, a basic value of the center key is “−” a long vowel character of katakana, a double value of the center key is “_”, a basic value of the distant center key is “@”, and a double value of the distant center key is “/”,
in case of the 16th key, a basic value of the basic key is “ENTER”, a basic value of the center key is “J/E”, a basic value of the distant center key is “.”, a double value of the distant center key is “:”, a successive value of the distant center key is “?”, and a successive double value of the distant center key is “!”,
in case of the 17th key, a basic value of the basic key is [symbol] , a basic value of the center key is [symbol] , a double value of the center key is [symbol] , a triple value of the center key is [symbol] , a successive value of the center key is [symbol] , a successive double value of the center key is [symbol] , a basic value of the distant center key is [symbol] , a double value of the distant center key is [symbol] , a triple value of the distant center key is [symbol] , a successive value of the distant center key is [symbol] , and a successive double value of the distant center key is [symbol] ,
in case of the 18th key, a basic value of the basic key is [symbol] , a basic value of the center key is [symbol] , a double value of the center key is [symbol] , a triple value of the center key is [symbol] , a successive value of the center key is [symbol] , a successive double value of the center key is [symbol] , a basic value of the distant center key is [symbol] a double value of the distant center key is [symbol] , a triple value of the distant center key is [symbol] , a successive value of the distant center key is [symbol] , and a successive double value of the distant center key is [symbol] ,
in case of the 19th key, a basic value of the basic key is [symbol] , a basic value of the center key is [symbol] , a double value of the center key is [symbol] , a triple value of the center key is [symbol] a successive value of the center key is [symbol] , a successive double value of the center key is [symbol] , a basic value of the distant center key is [symbol] a double value of the distant center key is [symbol] , a triple value of the distant center key is [symbol] , a successive value of the distant center key is [symbol] , and a successive double value of the distant center key is [symbol] , and
in case of the 20th key, a basic value of the basic key is [symbol] , a basic value of the center key is [symbol] , a double value of the center key is [symbol] , a triple value of the center key is [symbol] , a successive value of the center key is [symbol] , a successive double value of the center key is [symbol] , a basic value of the distant center key is [symbol] , a double value of the distant center key is [symbol] , a triple value of the distant center key is [symbol] , a successive value of the distant center key is [symbol] , and a successive double value of the distant center key is [symbol] .

39. The method of claim 24, performed by the character input device for Japanese,
wherein, in the character input device, basic values of the basic keys are [symbol] , [symbol] , [symbol] , [symbol] , [symbol] , [symbol] , and [symbol] ,
wherein elements of [symbol] -column having [symbol] are indicated as basic values of the center keys or basic values of the distant center keys,
wherein elements of [symbol] -column having [symbol] are indicated as double values of the center keys or double values of the distant center keys,
wherein elements of [symbol] -column having [symbol] are indicated as triple values of the center keys or triple values of the distant center keys,
wherein elements of [symbol] -column having [symbol] are indicated as successive values of the center keys or successive values of the distant center keys, and
wherein elements of [symbol] -column having [symbol] are indicated as successive double values of the center keys or successive double values of the distant center keys.

40. The method of claim 24, performed by the character input device for Roman and Japanese characters, wherein
in case of the 11th key, a basic value of the basic key is “K”, a basic value of the center key is “G”, a double value of the center key is “X”, and a basic value of the distant center key is “_”,
in case of the 12th key, a basic value of the basic key is “N”, a double value of the basic key is [symbol] , a basic value of the center key is “a”, a double value of the center key is “ya”, a successive value of the center key is “wa”, a basic value of the distant center key is “M”, and a double value of the distant center key is “ [symbol] ”,
in case of the 13th key, a basic value of the basic key is “R”, a basic value of the center key is “o”, a double value of the center key is “yo”, a successive value of the center key is “wo”, a basic value of the distant center key is “L”, and a double value of the distant center key is “Q”,
in case of the 15th key, a basic value of the basic key is “h/k” to toggle between hiragana and katakana, a basic value of the center key is “I”, a double value of the center key is “yi”, a successive value of the center key is “wi”, a basic value of the distant center key is “@”, a double value of the distant center key is “/”, and a successive value of the distant center key is “□”,
in case of the 17th key, a basic value of the basic key is “H”, a basic value of the center key is “u”, a double value of the center key is “yu”, a successive value of the center key is “wu”, a basic value of the distant center key is “C”, a double value of the distant center key is “Y”, and a successive value of the distant center key is “ [symbol] ”,
in case of the
18th key, a basic value of the basic key is “S”, a basic value of the center key is “e”, a double value of the center key is “ye”, a successive value of the center key is “we”, a basic value of the distant center key is “J”, a double value of the distant center key is “Z”, and a successive value of the distant center key is “β”,
in case of the 19th key, a basic value of the basic key is “P”, a basic value of the center key is “B”, a double value of the center key is “V”, and a basic value of the distant center key is “F”,
in case of the 20th key, a basic value of the basic key is “T”, a basic value of the center key is “D”, a double value of the center key is “W”, a successive value of the center key is “WH”, and a basic value of the distant center key is “−”.

41. The method of claim 24, performed by the character input device for Chinese characters using Chinese phonetic symbols, wherein
in case of the 11th key, a basic value of the basic key is “ [symbol] ”, a double value of the basic key is “ [symbol] ”, a basic value of the center key is “ [symbol] ”, a double value of the center key is “ [symbol] ”, a basic value of the distant center key is “ [symbol] ”, and a double value of the distant center key is “ [symbol]
in case of the 12th key, a basic value of the basic key is “ [symbol] ”, a double value of the basic key is “ [symbol] ”, a basic value of the center key is “ [symbol] ”, a double value of the center key is “ [symbol] ”, a basic value of the distant center key is “ [symbol] ”, and a double value of the distant center key is “ [symbol] ”,
in case of the 13th key, a basic value of the basic key is “ [symbol] ”, a double value of the basic key is “ [symbol] ”, a basic value of the center key is “ [symbol] ”, a double value of the center key is “ [symbol] ”, a basic value of the distant center key is “ [symbol] ”, and a double value of the distant center key is “_”,
in case of the 14th key, a basic value of the basic key is “SPACE” to move a cursor to leave a space, a basic value of the center key is “W/N” to toggle between Chinese-writing mode and numerical calculation mode, a basic value of the distant center key is “,”, a double value of the distant center key is “;”, a successive value of the distant center key is “′”, and a successive double value of the distant center key is “″”,
in case of the 15th key, a basic value of the basic key is “ [symbol] ”, a basic value of the center key is “ [symbol] ”, a basic value of the distant center key is “@”, a double value of the distant center key is “/”, and a successive value of the distant center key is “□”,
in case of the 16th key, a basic value of the basic key is “ENTER” to make a new line, a basic value of the center key is “C/E” to toggle between Roman-writing mode and Chinese-writing mode, a basic value of the distant center key is “.”, a double value of the distant center key is “:”, a successive value of the distant center key is “?”, a successive double value of the distant center key is “!”, a double successive value of the distant center key is “ [symbol] ”, and a double successive double value of the distant center key is “ [symbol]
in case of the 17th key, a basic value of the basic key is “ [symbol] ”, a basic value of the center key is “ [symbol] ”, a double value of the center key is “ [symbol] ”, a basic value of the distant center key is “ [symbol] ”, and a double value of the distant center key is “−”,
in case of the 18th key, a basic value of the basic key is “ [symbol] ”, a double value of the basic key is “ [symbol] ”, a basic value of the center key is “ [symbol] ”, a double value of the center key is “ [symbol] ”, a basic value of the distant center key is “ [symbol] ”, and a double value of the distant center key is “ [symbol]
in case of the 19th key, a basic value of the basic key is “ [symbol] ”, a double value of the basic key is “ [symbol] ”, a basic value of the center key is “ [symbol] ”, a double value of the center key is “ [symbol] ”, a basic value of the distant center key is “ [symbol] ”, and a double value of the distant center key is “ [symbol]
in case of the 20th key, a basic value of the basic key is “ [symbol] ”, a double value of the basic key is “ [symbol] ”, a basic value of the center key is “ [symbol] ”, a double value of the center key is “ [symbol] ”, a basic value of the distant center key is “ [symbol] ”, and a double value of the distant center key is “ [symbol] ”.

42. The method of claim 24, performed by the character input device for Chinese characters, wherein, in the character input device, basic values of the basic keys are “ [symbol] ”, 37 [symbol] ”, “ [symbol] ”, “ [symbol] ”, “ [symbol] ”, “ [symbol] ”, “ [symbol] ”, “ [symbol] ” and the other characters are indicated using double values of the basic keys, basic values of the center keys, double values of the center keys, basic values of the distant center keys, double values of the distant center keys and successive values of the distant center keys.

43. The method of claim 24, performed by the character input device for Roman and Chinese characters, wherein
in case of the 11th key, a basic value of the basic key is “G”, a basic value of the center key is “K”, a double value of the center key is “F”, a successive value of the center key is “_”, and a basic value of the distant center key is “J”,
in case of the 12th key, a basic value of the basic key is “N”, a basic value of the center key is “a”, a double value of the center key is “ya”, a successive value of the center key is “wa”, a triple value of the center key is “ay”, a successive double value of the center key is “aw”, a basic value of the distant center key is “M”, and a double value of the distant center key is “ [symbol] ”,
in case of the 13th key, a basic value of the basic key is “R”, a basic value of the center key is “o”, a double value of the center key is “yo”, a successive value of the center key is “wo”, a triple value of the center key is “oy”, a successive double value of the center key is “ow”, a basic value of the distant center key is “L”, and a double value of the distant center key is “Y”,
in case of the 15th key, a basic value of the basic key is “I”, a basic value of the center key is “yi”, a double value of the center key is “yu”, a successive value of the center key is “wi”, a triple value of the center key is “iy”, a successive double value of the center key is “iw”, a basic value of the distant center key is “@”, a double value of the distant center key is “/”, and a successive value of the distant center key is “□”,
in case of the 17th key, a basic value of the basic key is “H”, a basic value of the center key is “u”, a double value of the center key is “yu”, a successive value of the center key is “wu”, a triple value of the center key is “uy”, a successive double value of the center key is “uw”, a basic value of the distant center key is “Z”, and a double value of the distant center key is “β”,
in case of the 18th key, a basic value of the basic key is “S”, a basic value of the center key is “e”, a double value of the center key is “ye”, a successive value of the center key is “we”, a triple value of the center key is “ey”, a successive double value of the center key is “ew”, a basic value of the distant center key is “C”, and a double value of the distant center key is “ [symbol] ”,
in case of the 19th key, a basic value of the basic key is “B”, a basic value of the center key is “P”, a double value of the center key is “V”, a successive value of the center key is “−”, and a basic value of the distant center key is “X”,
in case of the 20th key, a basic value of the basic key is “D”, a basic value of the center key is “T”, a double value of the center key is “W”, a successive value of the center key is “WH”, and a basic value of the distant center key is “Q”.

44. The method of claim 24, performed by the character input device for Roman and German characters, wherein
in case of the 11th key, a basic value of the basic key is “G”, a basic value of the center key is “K”, a double value of the center key is “X”, and a basic value of the distant center key is “_”,
in case of the 12th key, a basic value of the basic key is “N”, a basic value of the center key is “a”, a double value of the center key is “ [symbol] ”, a basic value of the distant center key is “M”, and a double value of the distant center key is “ [symbol] ”,
in case of the 13th key, a basic value of the basic key is “R”, a basic value of the center key is “o”, a double value of the center key is “ [symbol] ”, a basic value of the distant center key is “L”, and a double value of the distant center key is “Q”,
in case of the 15th key, a basic value of the basic key is “CAP” to perform a conversion between capital and small letters, a basic value of the center key is “I”, a double value of the center key is “ [symbol] ”, a basic value of the distant center key is “@”, and a double value of the distant center key is “/”,
in case of the 17th key, a basic value of the basic key is “H”, a basic value of the center key is “u”, a double value of the center key is “ [symbol] ”, a basic value of the distant center key is “J”, a double value of the distant center key is “Z”, and a successive value of the distant center key is “ [symbol] ”,
in case of the 18th key, a basic value of the basic key is “S”, a basic value of the center key is “e”, a basic value of the distant center key is “C”, a double value of the distant center key is “Y”, and a successive value of the distant center key is “β”,
in case of the 19th key, a basic value of the basic key is “B”, a basic value of the center key is “P”, a double value of the center key is “V”, and a basic value of the distant center key is “F”, and
in case of the 20th key, a basic value of the basic key is “D”, a basic value of the center key is “T”, a double value of the center key is “W”, a successive value of the center key is “WH”, and a basic value of the distant center key is “−”.

45. The method of claim 24, performed by the character input device for Roman and French characters, wherein
in case of the 11th key, a basic value of the basic key is “G”, a basic value of the center key is “K”, a double value of the center key is “X”, and a basic value of the distant center key is “_”,
in case of the 12th key, a basic value of the basic key is “N”, a basic value of the center key is “a”, a double value of the center key is “ [symbol] ”, a successive value of the center key is “ [symbol] ”, a successive double value of the center key is “ [symbol] ”, a basic value of the distant center key is “M”, and a double value of the distant center key is “ [symbol] ”,
in case of the 13th key, a basic value of the basic key is “R”, a basic value of the center key is “o”, a double value of the center key is “ [symbol] ”, a successive value of the center key is “ [symbol] ”, a successive double value of the center key is “ [symbol] ”, a basic value of the distant center key is “L”, and a double value of the distant center key is “Q”,
in case of the 15th key, a basic value of the basic key is “CAP”, a basic value of the center key is “I”, a double value of the center key is “ [symbol] ”, a successive value of the center key is “ [symbol] ”, a successive double value of the center key is “ [symbol] ”, a basic value of the distant center key is “@”, a double value of the distant center key is “/”, a successive value of the distant center key is “□”, and a successive double value of the distant center key is “˜”,
in case of the 17th key, a basic value of the basic key is “H”, a basic value of the center key is “u”, a double value of the center key is “ [symbol] ”, a successive value of the center key is “ [symbol] ”, a successive double value of the center key is “ [symbol] ”, a basic value of the distant center key is “J”, a double value of the distant center key is “Z”, and a successive value of the distant center key is “ [symbol] ”,
in case of the 18th key, a basic value of the basic key is “S”, a basic value of the center key is “e”, a double value of the center key is “ [symbol] ”, a successive value of the center key is “ [symbol] ”, a successive double value of the center key is “ [symbol] ”, a triple value of the center key is “ [symbol] ”, a basic value of the distant center key is “C”, a double value of the distant center key is “Y”, and a successive value of the distant center key is “β”,
in case of the 19th key, a basic value of the basic key is “B”, a basic value of the center key is “P”, a double value of the center key is “V”, and a basic value of the distant center key is “F”, and
in case of the 20th key, a basic value of the basic key is “D”, a basic value of the center key is “T”, a double value of the center key is “W”, a successive value of the center key is “WH”, and a basic value of the distant center key is “−”.

46. The method of claim 24, performed by the character input device for Roman and Vietnamese characters, wherein
in case of the 11th key, a basic value of the basic key is “G”, a basic value of the center key is “K”, a double value of the center key is “X”, a successive value of the center key is “_”, and a basic value of the distant center key is “GI”,
in case of the 12th key, a basic value of the basic key is “N”, a basic value of the center key is “A”, a double value of the center key is “ [symbol] ”, a successive value of the center key is “ [symbol] ”, a basic value of the distant center key is “M”, and a double value of the distant center key is “ [symbol] ”,
in case of the 13th key, a basic value of the basic key is “R”, a basic value of the center key is “O”, a double value of the center key is “ [symbol] ”, a successive value of the center key is “O′”, a basic value of the distant center key is “L”, and a double value of the distant center key is “Q”,
in case of the 15th key, a basic value of the basic key is “CAP”, a basic value of the center key is “I”, a basic value of the distant center key is “@”, and a double value of the distant center key is “/”,
in case of the 17th key, a basic value of the basic key is “H”, a basic value of the center key is “U”, a double value of the center key is “U′”, a basic value of the distant center key is “J”, a double value of the distant center key is “Z”, and a successive value of the distant center key is “ [symbol] ”,
in case of the 18th key, a basic value of the basic key is “S”, a basic value of the center key is “E”, a double value of the center key is “ [symbol] ”, a basic value of the distant center key is “C”, a double value of the distant center key is “Y”, and a double value of the distant center key is “β”,
in case of the 19th key, a basic value of the basic key is “B”, a basic value of the center key is “P”, a double value of the center key is “V”, a successive value of the center key is “−”, and a basic value of the distant center key is “F”, and
in case of the 20th key, a basic value of the basic key is “D”, a basic value of the center key is “T”, a double value of the center key is “W”, a successive value of the center key is “WH”, and a basic value of the distant center key is “D”.

47. The method of claim 24, performed by the character input device for Russian, wherein
in case of the 11th key, a basic value of the basic key is [symbol] a basic value of the center key is “κ”, a double value of the center key is “X”, and a basic value of the distant center key is “_”,
in case of the 12th key, a basic value of the basic key is “H”, a basic value of the center key is “a”, a double value of the center key is [symbol] a successive value of the center key is [symbol] , and a basic value of the distant center key is “M”,
in case of the 13th key, a basic value of the basic key is “p”, a basic value of the center key is “o”, a double value of the center key is “ [symbol] ”, a successive value of the center key is [symbol] , and a basic value of the distant center key is [symbol] ,
in case of the 15th key, a basic value of the basic key is “CAP”, a basic value of the center key is [symbol] , a double value of the center key is [symbol] , a successive value of the center key is [symbol] , a basic value of the distant center key is “@”, a double value of the distant center key is “/”, a successive of the distant center key is “˜”, and a successive double value of the distant center key is “□”,
in case of the 17th key, a basic value of the basic key is [symbol] , a basic value of the center key is [symbol] , a double value of the center key is “y”, a basic value of the distant center key is [symbol] , and a double value of the distant center key is [symbol] ,
in case of the 18th key, a basic value of the basic key is “c”, a basic value of the center key is [symbol] , a double value of the center key is “e”, a basic value of the distant center key is [symbol] , and a double value of the distant center key is [symbol] ,
in case of the 19th key, a basic value of the basic key is [symbol] , a basic value of the center key is [symbol] , a double value of the center key is “B”, and a basic value of the distant center key is [symbol] , and
in case of the 20th key, a basic value of the basic key is [symbol] , a basic value of the center key is “T”, a double value of the center key is [symbol] , and a basic value of the distant center key is “−”.

48. The method of claim 24, performed by the character input device for Hindi, wherein
in case of the 11th key, a basic value of the basic key is “ [symbol] ”, a basic value of the center key is “ [symbol] ”, a double value of the center key is “x”, a successive value of the center key is “ [symbol] ”, a basic value of the distant center key is “ [symbol] ”, and a double value of the distant center key is “ [symbol] ”,
in case of the 12th key, a basic value of the basic key is “ [symbol] ”, a basic value of the center key is “ [symbol] ”, a double value of the center key is “ [symbol] ”, a successive value of the center key is “ [symbol] ”, a basic value of the distant center key is “ [symbol] ”, a double value of the distant center key is “ [symbol] ”, a successive value of the distant center key is “ [symbol] ”, and a successive double value of the distant center key is “ [symbol]
in case of the 13th key, a basic value of the basic key is “ [symbol] ”, a basic value of the center key is “ [symbol] ”, a double value of the center key is “ [symbol] ”, a successive value of the center key is “ [symbol] ”, a successive double value of the center key is “ [symbol] ”, a basic value of the distant center key is “ [symbol] ”, a double value of the distant center key is “ [symbol] ”, and a successive value of the distant center key is “ [symbol] ”,
in case of the 15th key, a basic value of the basic key is “hCap” to change a previously generated letter once more, a basic value of the center key is “ [symbol] ”, a double value of the center key is “ [symbol] ”, a successive value of the center key is “ [symbol] ”, a basic value of the distant center key is “@”, a double value of the distant center key is “/”, and a successive value of the distant center key is “.”,
in case of the 17th key, a basic value of the basic key is “ [symbol] ”, a basic value of the center key is “ [symbol] ”, a double value of the center key is “ [symbol] ”, a basic value of the distant center key is “ [symbol] ”, a double value of the distant center key is “ [symbol] ”, and a successive value of the distant center key is “−”,
in case of the 18th key, a basic value of the basic key is “ [symbol] ”, a basic value of the center key is “ [symbol] ”, a double value of the center key is “ [symbol] ”, a successive value of the center key is “ [symbol] ”, a successive double value of the center key is “ [symbol] ”, a basic value of the distant center key is “ [symbol] ”, a double value of the distant center key is “ [symbol] ”, and a successive value of the distant center key is “ [symbol] ”,
in case of the 19th key, a basic value of the basic key is “ [symbol] ”, a basic value of the center key is “ [symbol] ”, a double value of the center key is “ [symbol] ”, a successive value of the center key is “ [symbol] ”, a basic value of the distant center key is “ [symbol] ”, and a double value of the distant center key is “_”, and
in case of the 20th key, a basic value of the basic key is “ [symbol] ”, a basic value of the center key is “ [symbol] ”, a double value of the center key is “W”, a successive value of the center key is “ [symbol] ”, a basic value of the distant center key is “ [symbol] ”, and a double value of the distant center key is “ [symbol] ”.

49. The method of claim 24, performed by the character input device for Roman and Hindi characters, wherein
in case of the 11th key, a basic value of the basic key is “g”, a basic value of the center key is “k”, a double value of the center key is “x”, a successive value of the center key is “gyn”, a basic value of the distant center key is “gh”, and a double value of the distant center key is “kh”,
in case of the 12th key, a basic value of the basic key is “n”, a basic value of the center key is “a”, a double value of the center key is “aa”, a successive value of the center key is “am”, a basic value of the distant center key is “m”, a double value of the distant center key is “N”, a successive value of the distant center key is “ni”, and a successive double value of the distant center key is “ [symbol] ”,
in case of the 13th key, a basic value of the basic key is “r”, a basic value of the center key is “o”, a double value of the center key is “oi”, a successive value of the center key is “oii”, a successive double value of the center key is “ou”, a basic value of the distant center key is “1”, a double value of the distant center key is “li”, and a successive value of the distant center key is “ri”,
in case of the 15th key, a basic value of the basic key is “hCAP” to change a previously generated letter once more, a basic value of the center key is “I”, a double value of the center key is “ii”, a successive value of the center key is “yi”, a basic value of the distant center key is “@”, a double value of the distant center key is “/”, and a successive value of the distant center key is “□”,
in case of the 17th key, a basic value of the basic key is “h”, a basic value of the center key is “u”, a double value of the center key is “uu”, a basic value of the distant center key is “j”, a double value of the distant center key is “z”, and a double value of the distant center key is “−”,
in case of the 18th key, a basic value of the basic key is “s”, a basic value of the center key is “e”, a double value of the center key is “ei”, a successive value of the center key is “eii”, a successive double value of the center key is “ai”, a basic value of the distant center key is “c”, a double value of the distant center key is “y”, and a successive value of the distant center key is “ [symbol] ”,
in case of the 19th key, a basic value of the basic key is “b”, a basic value of the center key is “p”, a double value of the center key is “v”, a successive value of the center key is “ksh”, a basic value of the distant center key is “fi”, and a double value of the distant center key is “_”, and
in case of the 20th key, a basic value of the basic key is “d”, a basic value of the center key is “D”, a double value of the center key is “w”, and a basic value of the distant center key is “t”, and a double value of the distant center key is “T”.

50. The method of claim 24, performed by the character input device for Arabic, wherein
in case of the 11th key, a basic value of the basic key is “ [symbol] ”, a basic value of the center key is “ [symbol] ”, a double value of the center key is “ [symbol] ”, a successive value of the center key is “ [symbol] ”, and a basic value of the distant center key is “_”,
in case of the 12th key, a basic value of the basic key is “ [symbol] ”, a basic value of the center key is “ [symbol] ”, a double value of the center key is “ [symbol] ”, a successive value of the center key is “ [symbol] ”, a basic value of the distant center key is “ [symbol] ”, a double value of the distant center key is “ [symbol] ”, and a successive value of the distant center key is “ [symbol]
in case of the 13th key, a basic value of the basic key is “ [symbol] ”, a basic value of the center key is “ [symbol] ”, a double value of the center key is “ [symbol] ”, a basic value of the distant center key is “ [symbol] ”, and a double value of the distant center key is “ [symbol] ”,
in case of the 15th key, a basic value of the basic key is “∘” of a Sukun symbol with “eu” sound, a basic value of the center key is “ [symbol] ”, a double value of the center key is “ [symbol] ”, a successive value of the center key is “ [symbol] ” combining “ [symbol] ” and “ [symbol] ” together, a basic value of the distant center key is “@”, a double value of the distant center key is “/”, a successive value of the distant center key is “˜”, and a successive double value of the distant center key is “□”,
in case of the 17th key, a basic value of the basic key is “ [symbol] ”, a basic value of the center key is “ [symbol] ”, a double value of the center key is “ [symbol] ”, a successive value of the center key is “ [symbol] ”, a basic value of the distant center key is “ [symbol] ”, and a double value of the distant center key is “ [symbol]
in case of the 18th key, a basic value of the basic key is “ [symbol] ”, a basic value of the center key is “ [symbol] ”, a double value of the center key is “ [symbol] ”, a successive value of the center key is “ [symbol] ”, a basic value of the distant center key is “ [symbol] ”, a double value of the distant center key is “ [symbol] ”, and a successive value of the distant center key is “ [symbol] ”,
in case of the 19th key, a basic value of the basic key is “ [symbol] ”, a basic value of the center key is “ [symbol] ”, a double value of the center key is “ [symbol] ”, and a successive value of the center key is “ [symbol] ”, and
in case of the 20th key, a basic value of the basic key is “ [symbol] ”, a basic value of the center key is “ [symbol] ”, a double value of the center key is “ [symbol] ”, a successive value of the center key is “ [symbol] ”, and a basic value of the distant center key is “−”.

51. The method of claim 24, performed by the character input device for adjustment, wherein
in case of the 11th key, a basic value of the basic key is “Menu” which is a menu function, a basic value of the center key is “Language” which is a function to toggle between languages, a double value of the center key is “Timer” which is a function to regulate a time, a successive value of the center key is “sound” which is a multiple sound function, a successive double value of the center key is “Screen” which is a function to regulate screen conditions, and a basic value of the distant center key is “Tel” which is a menu function for telephone;
in case of the 12th key, a basic value of the basic key is “vol▾” which is a function to decrease the volume level by one step, a basic value of the center key is “▴” which is a function to increase the volume level by one step, and a basic value of the distant center key is “Mute” which is a mute function,
in case of the 13th key, a basic value of the basic key is [symbol] which is a playback function, a basic value of the center key is [symbol] which is a fast-forward winding function, a double value of the center key is “ [symbol] ” which is a function to jump to the next section, and a basic value of the distant center key is “Rec” which is a recording function,
in case of the 14th key, a basic value of the basic key is “←” which is a function to move the cursor to the left, a basic value of the center key is “Clear” which is a function to delete a left space, and a basic value of the distant center key is “Home” which is a function to move the cursor to the front of the line on which the cursor is present,
in case of the 15th key, a basic value of the basic key is “↓” which is a function to move the cursor to the lower line, a basic value of the center key is “Ins” which is an inserting function, and a basic value of the distant center key is “PgDn” which is a function to move the cursor to the lower page,
in case of the 16th key, a basic value of the basic key is “→” which is a function to move the cursor to the right, a basic value of the center key is “del” which is a function to delete a right space, and a double value of the center key is “End” which is a function to move the cursor to the end of the line on which the cursor is present,
in case of the 17th key, a basic value of the basic key is “ [symbol] ” which is a function to make a pause, a basic value of the center key is [symbol] which is a rewinding function, a double value of the center key is “ [symbol] ” which is a function to jump to the previous section, a basic value of the distant center key is “▪” which is a stopping function, and a double value of the distant center key is “ [symbol] ” which is an ejecting function,
in case of the 18th key, a basic value of the basic key is “−Ch” which is a function to decrease the channel number by a step, a basic value of the center key is “+” which is a function to increase the channel number by a step, and a basic value of the distant center key is “Auto” which is a function to regulate the channel automatically,
in case of the 19th key, a basic value of the basic key is “OK” which is a function to start a screen and to accept the selected item, a basic value of the center key is “TV” which is a function to switch to television, a double value of the center key is “PC” which is a function to switch to the computer, a successive value of the center key is “DVD” which is a function to turn switch to DVD, a successive double value of the center key is “VHS” which is a function to switch to videotape, and a basic value of the distant center key is “off” which is a function to turn power off, and
in case of the 20th key, a basic value of the basic key is “↑” which is a function to move the cursor to the upper line, a basic value of the center key is “ [symbol] ” which is a function to return to the previous screen, and a basic value of the distant center key is “PgUp” which is a function to move the cursor to the upper page.

52. The method of claim 24, performed by the character input device for controlling a camera, wherein
in case of the 11th key, a basic value of the basic key is “Auto” which is an automatic exposure control method, a basic value of the center key is “P” which is a programmed exposure control method, a double value of the center key is “Av” which is an aperture priority mode, a triple value of the center key is “Tv” which is a shutter speed priority mode, a successive value of the center key is “AF-S” which is an aperture method for static subjects, a successive double value of the center key is “AF-C” which is an aperture method for dynamic subjects, a successive triple value of the center key is “AF-A” which is an aperture method for mixed subjects, a basic value of the distant center key is “Me” which is a manual exposure control method, and a double value of the distant center key is “←” to return to the previous screen or setting,
in case of the 12th key, a basic value of the basic key is “A” which is a function to adjust shutter speed automatically, a basic value of the center key is “ 1/125” to set the shutter speed at 1/125 second, a double value of the center key is “ 1/250” to set the shutter speed at 1/250 second, a triple value of the center key is “ 1/500” to set the shutter speed at 1/500 second, a successive value of the center key is “ 1/60” to set the shutter speed at 1/60 second, a successive double value of the center key is “ 1/30” to set the shutter speed at 1/30 second, a successive triple value of the center key is “¼” to set the shutter speed at ¼ second, and a basic value of the distant center key is “Ms” which is a function to adjust shutter speed manually,
in case of the 13th key, a basic value of the basic key is “Raw” which is an image quality function that simultaneously stores the original image, a basic value of the center key is “Hi” which stores at the highest image quality, a double value of the center key is “Extra” which stores at an image quality that is lower than “Raw” and “Hi”, a triple value of the center key is “Fine” which stores at an image quality that is lower than “Extra”, a successive value of the center key is “Normal” which stores at an image quality that is lower than “Fine”, a successive double value of the center key is “Basic” which stores at an image quality that is lower than “Normal”, a basic value of the distant center key is “ [symbol] ” which is a multi-pattern light measuring method, a double value of the distant center key is “ [symbol] ” which is a center-weighted light measuring method, and a triple value of the distant center key is “ [symbol] ” which is a spot light measuring method,
in case of the 14th key, a basic value of the basic key is “ [symbol] ” which is a function to set a self-timer to 10 seconds, a basic value of the center key is “2s” which is a function to set a self-timer to 2 seconds, a double value of the center key is “5s” which is a function to set a self-timer to 5 seconds, a triple value of the center key is “20s” which is a function to set a self-timer to 20 seconds, a successive value of the center key is “ [symbol] ” which is a burst function to take pictures at a burst, a successive double value of the center key is “ [symbol] ” which is a rapid burst function, and a basic value of the distant center key is “Menu” which is a menu function for editing,
in case of the 15th key, a basic value of the basic key is “ [symbol] ” which is an auto flash function, a basic value of the center key is “ [symbol] ” which is an auto-flash function added to a red-eye reduction function, a double value of the center key is “ [symbol] ” which is a light-emitting function by slow synchro, a successive value of the center key is “ [symbol] ” which is a light-emitting function by forced flash, a successive double value of the center key is “ [symbol] ” which is a function to prevent light-emitting of the flash, and a basic value of the distant center key is “Disp” which is a function to display results on a screen,
in case of the 16th key, a basic value of the basic key is “OK” which is a function to start a screen and to accept the selected item, a basic value of the center key is “del” which is a deleting function, a double value of the center key is “Y” for a positive selection to delete in answer to the question about whether to delete or not on screen after “del” is generated, a successive value of the center key is “N” for a negative selection not to delete in answer to the question about whether to delete or not on screen after “del” is generated, a basic value of the distant center key is “ [symbol] ” which is a function to store a picture as a file, a double value of the distant center key is “ [symbol] ” which is a function to store movies, a triple value of the distant center key is “ [symbol] ” which is a function to store movies and sounds together, and a successive value of the distant center key is “off” which is a function to turn off the screen,
in case of the 17th key, a basic value of the basic key is “AWB” which is a function for automatically adjusting white-balance, a basic value of the center key is “ [symbol] ” which is a daylight function to set a natural white-balance in daylight, a double value of the center key is “ [symbol] ” which is a cloudy function to adjust white-balance appropriately under cloudy conditions, a triple value of the center key is “ [symbol] ” which is a shadow function to adjust white-balance appropriately in shadow conditions, a successive value of the center key is “ [symbol] ” which is an incandescent function to adjust white-balance appropriately under incandes [symbol] cent lighting conditions, a successive double value of the center key is “ ” which is a fluorecent function to adjust white-balance appropriately under fluorecent lighting conditions, a successive triple value of the center key is “ [symbol] ” which is a flash function to adjust white-balance appropriately when a picture is taken while flash fires, and a basic value of the distant center key is “Preset” which is a function to set white-balance manually,
in case of the 18th key, a basic value of the basic key is “ [symbol] ” which is a function to set sensitivity automatically, a basic value of the center key is “ [symbol] ” which is a function to set sensitivity at 100, a double value of the center key is “ [symbol] ” which is a function to set sensitivity at 200, a triple value of the center key is “ [symbol] ” which is a function to set sensitivity at 400, a successive value of the center key is “ [symbol] ” which is a function to set sensitivity at 640, a successive double value of the center key is “ [symbol] ” which is a function to set sensitivity at 800, a successive triple value of the center key is “ [symbol] ” which is a function to set sensitivity at 1600, and a basic value of the distant center key is “ [symbol] ” which is a function to set sensitivity manually,
in case of the 19th key, a basic value of the basic key is “Tele” which is a function to make a view angle narrower by a step, a basic value of the center key is “Wide” which is a function to make the view angle wider by a step, a basic value of the distant center key is “Ev+” which is a function to increase an exposure compensation by a step, and a successive value of the distant center key is “−” which is a function to decrease the exposure compensation by a step,
in case of the 20th key, a basic value of the basic key is “ [symbol] ” which is a picture-taking mode for close range, a basic value of the center key is “ [symbol] ” which is a picture-taking mode for a portrait, a double value of the center key is “ [symbol] ” which is a picture-taking mode for landscape, a triple value of the center key is “ [symbol] ” which is a picture-taking mode for subjects in motion, a successive value of the center key is “ [symbol] ” which is a picture-taking mode for a sunrise, a successive double value of the center key is “ [symbol] ” which is a picture-taking mode for a sunset, a successive triple value of the center key is “ [symbol] ” which is a picture-taking mode for a beach, a basic value of the distant center key is “ [symbol] ” which is a picture-taking mode for portraits at night, a double value of the distant center key is “ [symbol] ” which is a picture-taking mode for a party, a triple value of the distant center key is “ [symbol] ” which is a picture-taking mode for a museum, a successive value of the distant center key is “ [symbol] ” which is a picture-taking mode for landscape at night, a successive double value of the distant center key is “ [symbol] ” which is a picture-taking mode for a snowscape.

53. The method of claim 24, performed by the character input device for inherent functions, wherein
in case of the 12th key, a basic value of the basic key is “Dia” which is a diary menu, a basic value of the center key is “M” which is a function to make a memo, a double value of the center key is “W” which is a function to edit a document and an abbreviation of Word, a successive value of the center key is “F” which is a function to find a document, a basic value of the distant center key is “M” which is a schedule list for a month, a double value of the distant center key is “W” which is a schedule list for a week, and a successive value of the distant center key is “D” which is a schedule list for a day;
in case of the 13th key, a basic value of the basic key is “Tel” which is a menu for the telephone book, a basic value of the center key is “R” which is a menu for received numbers, a double value of the center key is “S” which is a menu for sent numbers, a successive value of the center key is “F” which is a menu function to find numbers, a successive double value of the center key is [symbol] which is a function to register telephone numbers, a basic value of the distant center key is “R” which is a record of received messages, a double value of the distant center key is “S” which is a record of sent messages, a successive value of the distant center key is “F” which is a function to find messages, and a successive double value of the distant center key is [symbol] which is a function to make messages,
in case of the 14th key, a basic value of the basic key of is “←” which is a function to move the cursor to the left, a basic value of the center key is “back” which is a function to delete a left space, and a basic value of the distant center key is “Home” which is a function to move the cursor to the left end of the line,
in case of the 15th key, a basic value of the basic key is “↓” which is a function to move the cursor down, a basic value of the center key is “Ins” which is a toggling function to toggle between correction and insertion, and a basic value of the distant center key is “PgDn” which is a function to move the cursor to the lower page,
in case of the 16th key, a basic value of the basic key is “→” which is a function to move the cursor to the right, a basic value of the center key is “del” which is a function to delete a right space, and a double value of the center key is “End” which is a function to move the cursor to the right end of the line,
in case of the 17th key, a basic value of the basic key is “Net” which is an internet menu, a basic value of the center key is “M” which is a main page of default setting, a double value of the center key is “C” which is for the control board, a successive value of the center key is “F” which is a function to find files and folders, a successive double value of the center key is [symbol] which is a function to write internet addresses, a basic value of the distant center key is “R” which is a menu function for receiving electronic mails, a double value of the distant center key is “S” which is a menu function for sending electronic mails, a successive value of the distant center key is “F” which is a function to find an electronic mail address, a successive double value of the distant center key is [symbol] which is a function to write an electronic mail message;
in case of the 18th key, a basic value of the basic key is “Pic” which is a menu for video recording, a basic value of the center key is “P” which is a menu for taking a photo, a double value of the center key is “Q” to function as an operating button to take a photo, a successive value of the center key is “F” which is a menu for a photo album, a successive double value of the center key is “e” which is a menu for editing photos, a basic value of the distant center key is “M” which is a menu for video recording, a double value of the distant center key is “Q” to function as an operating button for video recording, a successive value of the distant center key is “F” which is an album menu for finding a video clip, a successive double value of the distant center key is “e” which is a menu for editing a video clip,
in case of the 19th key, a basic value of the basic key is “Menu” which is a function to display the whole menu, a basic value of the center key is “V” which is a menu of videos, a double value of the center key is “Vol” which is a function to adjust the volume, a successive value of the center key is “Ch” which is a function to select a channel, a successive double value of the center key is “My” which is a function to adjust the environment of my computer, a basic value of the distant center key is “A” which is a menu of audios, a double value of the distant center key is “Vol” which is a function to adjust the volume, a successive value of the distant center key is “Ch” which is a function to select a channel, and a successive double value of the distant center key is “Rec” which is a menu for recording, and
in case of the 20th key, a basic value of the basic key is “↑” which is a function to move the cursor up, a basic value of the center key is “Esc” which is a function to return to the previous screen, and a basic value of the distant center key is “PgUp” which is a function to move the cursor to the upper page.

54. The method of claim 11, performed by a character input device for Roman character central-4-space type, wherein the character input device consists of a 4×4 arrangement, which comprises
a 401st key located on 1st row and 2nd column of the arrangement;
a 402nd key located on 1st row and 3rd column of the arrangement;
a 49th key located on 1st row and 4th column of the arrangement;
a 42nd key located on 2nd row and 1st column of the arrangement;
a 48th key located on 2nd row and 4th column of the arrangement;
a 43rd key located on 3rd row and 1st column of the arrangement;
a 47th key located on 3rd row and 4th column of the arrangement;
a 44th key located on 4th row and 1st column of the arrangement;
a 451st key located on 4th row and 2nd column of the arrangement;
a 452nd key located on 4th row and 3rd column of the arrangement;
a 46th key located on 4th row and 4th column of the arrangement;
a 41st center key located on 2nd row and 2nd column of the arrangement;
a 42nd center key located on 2nd row and 3rd column of the arrangement;
a 43rd center key located on 3rd row and 2nd column of the arrangement;
a 44th center key located on 3rd row and 3rd column of the arrangement,
in case of the 41st key(410), a basic value of the basic key is “G”, and a basic value of the center key is “K”,
in case of the 42nd key(420), a basic value of the basic key is “N”, a value 1 of the center key is “A”, a value 11 of the center key is “ya”, a value 2 of the center key is “wa”, a value 3 of the center key is “M”, and a value 4 of the center key is “ [symbol] ”,
in case of the 43rd key(430), a basic value of the basic key is “R”, a value 1 of the center key is “L”, a value 3 of the center key is “O”, a value 33 of the center key is “yo”, and a value 4 of the center key is “wo”,
in case of the 44th key(440), a basic value of the basic key is “SPACE” to move a cursor to leave a space, in which a space is left whenever the key is pressed once, a value 3 of the center key is “N/W” to toggle between Roman-writing mode and numerical calculation mode, a value 1 of the center key is “,”, a value 11 of the center key is “;”, a value 13 of the center key is “′”, and a value 133 of the center key is “″”,
in case of the 451st key(452), a basic value of the basic key is “W”, a value 3 of the center key is “V”, and a value 4 of the center key is “@”,
in case of the 452nd key(455), a basic value of the basic key is “Y”, a value 4 of the center key is “X”, a value 2 of the center key is “Z”, and a value 3 of the center key is “/”,
in case of the 46th key(460), a basic value of the basic key is “ENTER” to make a new line, a value 4 of the center key is “K/E” to toggle between Korean-writing mode and Roman-writing mode, a value 2 of the center key is “.”, a value 22 of the center key is “:”, a value 24 of the center key is “?”, and a value 244 of the center key is “!”,
in case of the 47th key(470), a basic value of the basic key is “H”, a value 4 of the center key is “U”, a value 44 of the center key is “yu”, a value 3 of the center key is “wu”, a value 2 of the center key is “J”, and a value 1 of the center key is “ [symbol] ”,
in case of the 48th key(480), a basic value of the basic key is “S”, a value 2 of the center key is “E”, a value 22 of the center key is “ye”, a value 4 of the center key is “C”, and a value 3 of the center key is “β”,
in case of the 49th key(490), a basic value of the basic key is “CAP” to toggle between capital and small letters, a value 2 of the center key is “I”, and a value 4 of the center key is “Q”,
in case of the 401st key(502), a basic value of the basic key is “D”, a value 1 of the center key is “T”, and a value 2 of the center key is “_”, and
in case of the 402nd key(505), a basic value of the basic key is “B”, a value 2 of the center key is “P”, and a value 1 of the center key is “−”.

55. The method of claim 14, wherein the character input device consists of a 3×7 arrangement, which comprises
a 51st key located on 1st row and 2nd column of the arrangement,
a 52nd key located on 1st row and 3rd column of the arrangement,
a 53rd key located on 1st row and 4th column of the arrangement,
a 54th key located on 1st row and 5th column of the arrangement,
a 55th key located on 1st row and 6th column of the arrangement,
a 56th key located on 3rd row and 2nd column of the arrangement,
a 57th key located on 3rd row and 3rd column of the arrangement,
a 58th key located on 3rd row and 4th column of the arrangement,
a 59th key located on 3rd row and 5th column of the arrangement,
a 60th key located on 3rd row and 6th column of the arrangement,
a 501st key located on 1st row and 1st column of the arrangement,
a 502nd key located on 1st row and 7th column of the arrangement,
a 503rd key located on 2nd row and 1st column of the arrangement,
a 504th key located on 2nd row and 7th column of the arrangement,
a 505th key located on 3rd row and 1st column of the arrangement,
a 506th key located on 3rd row and 7th column of the arrangement,
a 51st center key located on 2nd row and 2nd column of the arrangement,
a 52nd center key located on 2nd row and 3rd column of the arrangement,
a 53rd center key located on 2nd row and 4th column of the arrangement,
a 54th center key located on 2nd row and 5th column of the arrangement,
a 55th center key located on 2nd row and 6th column of the arrangement.

56. The method of claim 55, performed by a character input device for Korean-Roman central-5-space type, wherein, when the device is in the Roman-writing mode,
in case of the 51st key, a basic value of the basic key is “G”, a value 1 of the center key is “X”, and a value 2 of the center key is “K”,
in case of the 52nd key, a basic value of the basic key is “N”, a value 2 of the center key is “wa”, a value 3 of the center key is “A”, a value 33 of the center key is “ya”, a value 1 of the center key is “F”, and a value 11 of the center key is “ [symbol] ”,
in case of the 53rd key, a basic value of the basic key is “R”, a value 3 of the center key is “we”, a value 2 of the center key is “E”, a value 22 of the center key is “ye”, and a value 4 of the center key is “@”,
in case of the 54th key, a basic value of the basic key is “D”, a value 4 of the center key is “W”, a value 3 of the center key is “/”, and a value 5 of the center key is “T”,
in case of the 55th key, a basic value of the basic key is “B”, a value 5 of the center key is “V”, and a value 4 of the center key is “P”,
in case of the 56th key, a basic value of the basic key is “Cap” to toggle between capital and small letters, a value 1 of the center key is “Y”, a value 2 of the center key is “I”, a value 22 of the center key is “yi”, and a value 33 of the center key is “wi”,
in case of the 57th key, a basic value of the basic key is “M”, a value 2 of the center key is “wo”, a value 3 of the center key is “0”, and a value 33 of the center key is “yo”,
in case of the 58th key, a basic value of the basic key is “L”, a value 3 of the center key is “wu”, a value 2 of the center key is “U”, a value 22 of the center key is “yu”, and a value 4 of the center key is “_”,
in case of the 59th key, a basic value of the basic key is “S”, a value 4 of the center key is “Q”, a value 3 of the center key is “−”, a value 5 of the center key is “C”, and a value 54 of the center key is “β”,
in case of the 60th key, a basic value of the basic key is “H”, a value 5 of the center key is “Z”, a value 4 of the center key is “J”, and a value 45 of the center key is “ [symbol] ”,
in case of the 501st key, a basic value of the basic key is “↑” to move the cursor to the upper line, a value 1 of the center key is “PgUp” to move the cursor to the upper page, and a value 2 of the center key is “Esc” which is a function to cancel,
in case of the 502nd key, a basic value of the basic key is “↓” to move the cursor to the lower line, a value 5 of the center key is “PgDn” to move the cursor to the next page, and a value 4 of the center key is “Ins” which is an inserting function of a cursor,
in case of the 503rd key, a basic value of the basic key is “SPACE” to move a cursor to leave a space, a value 1 of the center key is “N/W” to toggle between numerical calculation mode and writing mode, a value 2 of the center key is “,”, a value 22 of the center key is “;”, a value 21 of the center key is “′”, and a value 211 of the center key is “″”,
in case of the 504th key, a basic value of the basic key is “enter” to send the cursor to the next line, a value 5 of the center key is “K/E” to toggle between Korean-writing mode and English-writing mode, a value 4 of the center key is “.”, a value 44 of the center key is “:”, a value 45 of the center key is “?”, and a value 455 of the center key is “!”, a value 445 of the center key is “ [symbol] ”, and a value 4455 of the center key is “ [symbol] ”,
in case of the 505th key, a basic value of the basic key is “←” to move the cursor to the left, a value 1 of the center key is “Home” to move the cursor to the left end of the line on which the cursor is present, and a value 2 of the center key is “Clear” to delete the left space of the cursor, and
in case of the 506th key, a basic value of the basic key is “→” to move the cursor to the right, a value 5 of the center key is “End” to move the cursor to the right end of the line on which the cursor is present, and a value 4 of the center key is “del” to delete the right space of the cursor.

57. The method of claim 56, performed by a character input device for Korean-Roman central-5-space type, wherein, when the device is in the Korean-writing mode,
in case of the 51st key, a basic value of the basic key is “□”, a value 1 of the center key is “□”, and a value 2 of the center key is “□”,
in case of the 52nd key, a basic value of the basic key is “□”, a value 2 of the center key is “□”, a value 3 of the center key is “□”, a value 33 of the center key is “□”, and a value 32 of the center key is “□”,
in case of the 53rd key, a basic value of the basic key is “□”, a value 3 of the center key is “□”, a value 2 of the center key is “□”, a value 22 of the center key is “□”, and a value 23 of the center key is “□”,
in case of the 54th key, a basic value of the basic key is “□”, a value 4 of the center key is “□”, a value 5 of the center key is “□”, and a value 3 of the center key is “/”,
in case of the 55th key, a basic value of the basic key is “□”, a value 5 of the center key is “□”, and a value 4 of the center key is “□”,
in case of the 56th key, a basic value of the basic key is “□”, a value 1 of the center key is “□”, and a value 2 of the center key is “□”,
in case of the 57th key, a basic value of the basic key is “□”, a value 2 of the center key is “□”, a value 3 of the center key is “□”, a value 33 of the center key is “□”, a value 32 of the center key is “□”, and a value 23 of the center key is “□”,
in case of the 58th key, a basic value of the basic key is “□”, a value 3 of the center key is “□”, a value 2 of the center key is “□”, a value 22 of the center key is “□”, a value 23 of the center key is “□”, a value 32 of the center key is “□”, and a value 4 of the center key is “_”,
in case of the 59th key, a basic value of the basic key is “□”, a value 4 of the center key is “□”, a value 3 of the center key is “−”, and a value 5 of the center key is “□”, and
in case of the 60th key, a basic value of the basic key is “□”, a value 5 of the center key is “□”, and a value 4 of the center key is “□”.
